(19) United States
(12) Patent Application Publication
(10) Pub. No.: US 2010/0314644 A1
(43) Pub. Date: Dec. 16, 2010

(54) ORGANIC ELECTROLUMINESCENT DEVICE

(75) Inventors: Kazuki Nishimura, Sodegaura-shi (JP); Yuichiro Kawamura, Sodegaura-shi (JP); Toshinari Ogiwara, Sodegaura-shi (JP); Hitoshi Kuma, Sodegaura-shi (JP); Kenichi Fukuoka, Sodegaura-shi (JP); Chishio Hosokawa, Sodegaura-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IDEMITSU KOSAN CO., LTD., Chiyoda-ku (JP)

(21) Appl. No.: 12/486,894

(22) Filed: Jun. 18, 2009

(30) Foreign Application Priority Data
Jun. 12, 2009 (JP) 2009-141347

(51) Int. Cl. H01L 51/52

(52) U.S. Cl. 257/98; 257/40; 257/E51.022

(57) ABSTRACT

An organic electroluminescence device including opposite anode and cathode, and a hole-transporting region, an emitting layer and an electron-transporting region in sequential order from the anode between the anode and the cathode, wherein the emitting layer is formed of a red emitting layer, a green emitting layer, and blue emitting layer; the blue emitting layer contains a host BH and a fluorescent dopant FBD; the triplet energy E^{T}_{fbd} of the fluorescent dopant FBD is larger than the triplet energy E^{T}_{bh} of the host BH; the green emitting layer contains a host GH and a phosphorescent dopant PGD; a common electron-transporting layer is provided adjacent to the red emitting layer, the green emitting layer and the blue emitting layer within the electron-transporting region; the triplet energy E^{T}ₑₗ of a material constituting the electron-transporting layer is larger than E^{T}_{bh}; and the difference between the affinity of the host GH and the affinity of the material constituting the electron-transporting layer is 0.4 eV or less.

### TECHNICAL FIELD

The invention relates to an organic electroluminescence (EL) device. More particularly, the invention relates to a highly efficient organic EL device.

### BACKGROUND ART

An organic EL device can be classified into two types, i.e. a fluorescent EL device and a phosphorescent EL device according to its emission principle. When a voltage is applied to an organic EL device, holes are injected from an anode, and electrons are injected from a cathode, and holes and electrons recombine in an emitting layer to form excitons. As for the resulting excitons, according to the electron spin statistics theory, they become singlet excitons and triplet excitons in an amount ratio of 25%:75%. Therefore, in a fluorescent EL device which uses emission caused by singlet excitons, the limited value of the internal quantum efficiency is believed to be 25%. Atechnology for prolonging the lifetime of a fluorescent EL device utilizing a fluorescent material has been recently improved. This technology is being applied to a full-color display of portable phones, TVs, or the like. However, a fluorescent EL device is required to be improved in efficiency.

In association with the technology of improving the efficiency of a fluorescent EL device, several technologies are disclosed in which emission is obtained from triplet excitons, which have heretofore been not utilized effectively. For example, in Non-Patent Document 1, a non-doped device in which an anthracene-based compound is used as a host material is analyzed. A mechanism is found that singlet excitons are formed by collision and fusion of two triplet excitons, whereby fluorescent emission is increased. However, Non-Patent Document 1 discloses only that fluorescent emission is increased by collision and fusion of triplet excitons in a non-doped device in which only a host material is used. In this technology, an increase in efficiency by triplet excitons is as low as 3 to 6%.

Non-Patent Document 2 reports that a blue fluorescent device exhibits an internal quantum efficiency of 28.5%, exceeding 25%, which is the conventional theoretical limit value. However, no technical means for attaining an efficiency exceeding 25% is disclosed. In respect of putting a full-color organic EL TV into practical use, a further increase in efficiency has been required.

In Patent Document 1, another example is disclosed in which triplet excitons are used in a fluorescent device. In normal organic molecules, the lowest excited triplet state (T1) is lower than the lowest excited singlet state (S1). However, in some organic molecules, the triplet excited state (T2) is higher than S1. In such a case, it is believed that emission from the singlet excited state can be obtained due to the occurrence of transition from T2 to S1. However, actually, the external quantum efficiency is about 6% (the internal quantum efficiency is 24% when the outcoupling efficiency is taken as 25%), which does not exceed the value of 25% which has conventionally been believed to be the limit value. The mechanism disclosed in this document is that emission is obtained due to the intersystem crossing from the triplet excited state to the singlet excited state in a single molecule. Generation of single excitons by collision of two triplet excitons as disclosed in Non-Patent Document 1 is not occurred in this mechanism.

Patent Documents 2 and 3 each disclose a technology in which a phenanthroline derivative such as BCP (bathocuproin) and BPhen is used in a hole-blocking layer in a fluorescent device to increase the density of holes at the interface between a hole-blocking layer and an emitting layer, enabling recombination to occur efficiently. However, a phenanthroline derivative such as BCP (bathocuproin) and BPhen is vulnerable to holes and poor in resistance to oxidation, and the performance thereof is insufficient in respect of prolonging the lifetime of a device.

In Patent Documents 4 and 5, a fluorescent device is disclosed in which an aromatic compound such as an anthracene derivative is used as a material for an electron-transporting layer which is in contact with an emitting layer. However, this is a device which is designed based on the mechanism that generated singlet excitons emit fluorescence within a short period of time. Therefore, no consideration is made on the relationship with the triplet energy of an electron-transporting layer which is normally designed in a phosphorescent device. Actually, since the triplet energy of an electron-transporting layer is smaller than the triplet energy of an emitting layer, triplet excitons generated in an emitting layer are diffused to an electron-transporting layer, and then, thermally deactivated. Therefore, it is difficult to exceed the theoretical limit value of 25% of the conventional fluorescent device. Furthermore, since the affinity of an electron-transporting layer is too large, electrons are not injected satisfactorily to an emitting layer of which the affinity is small, and hence, improvement in efficiency cannot necessarily be attained. In addition, Patent Document 6 discloses a device in which a blue-emitting fluoranthene-based dopant which has a long life and a high efficiency. This device is not necessarily highly efficient.

Meanwhile, a phosphorescent device directly utilizes emission from triplet excitons. Since the singlet exciton energy is converted to triplet excitons by the spin conversion within an emitting molecule, it is expected that an internal quantum efficiency of nearly 100% can be attained, in principle. For the above-mentioned reason, since a phosphorescent device using an Ir complex was reported by Forrest et al. in 2000, a phosphorescent device has attracted attention as a technology of improving efficiency of an organic EL device. Although a red phosphorescent device has reached the level of practical use, green and blue phosphorescent devices have a lifetime shorter than that of a fluorescent device. In particular, as for a blue phosphorescent device, there still remains a problem that not only lifetime is short but also color purity or luminous efficiency is insufficient. For these reasons, phosphorescent devices have not yet been put into practical use.

As a method for obtaining a full-color organic EL device, an emitting layer is patterned to provide a blue-emitting fluorescent layer, a green-emitting phosphorescent layer and a red-emitting phosphorescent layer. If peripheral layers other than an emitting layer are used as the common layer for the three emitting layers, the production steps are reduced, thereby to facilitate mass production. However, the blue-emitting fluorescent layer, the green-emitting phosphorescent layer and the red-emitting phosphorescent layer largely differ in physical value of constituent materials, for example, affinity, ionization potential, energy gap or the like. When peripheral layers are used as the common layer, a configuration is made in which optimum carrier injection performance can be attained in the green-emitting phosphorescent layer of which the energy gap is the largest. Therefore, other emitting layers (in particular, blue-emitting fluorescent layer) have deteriorated performance.

Patent Document 9 discloses a device comprising a blue emitting layer containing a fluorescent dopant, a green emitting layer containing a phosphorescent dopant and a red emitting layer containing a phosphorescent dopant, in which a hole-blocking layer is provided as the common layer.

In this device, by using a hole-blocking layer as the common layer, the production steps are reduced. However, use of a hole-blocking layer as the common layer, electron injection from the hole-blocking layer to each emitting layer has become a problem to be solved. Actually, difference in affinity level between a blue emitting layer and a hole-blocking layer is as small as about 0.2 eV. Since a material having a small affinity such as CBP is used in a green emitting layer, difference in affinity between the green emitting layer and the hole-blocking layer is as large as about 0.6 eV. Therefore, electron-injection properties are lowered in the green emitting layer, whereby a driving voltage is increased. Furthermore, since a recombination region is concentrated in the interface between a green phosphorescent emitting layer and a hole-blocking layer, excitons are significantly diffused, thereby inhibiting improvement in luminous efficiency of a green emitting layer.

Patent Document 10 discloses an organic EL device in which difference in affinity ΔAf between an emitting layer containing a phosphorescent-emitting dopant and an electron-transporting layer satisfies the relationship 0.2<ΔAf≦0.65 eV. However, in this technology, no disclosure is made on improvement in efficiency of the emitting layer when patterning of a blue emitting layer, a green emitting layer and a red emitting layer is performed.

### RELATED ART DOCUMENTS

### Patent Documents

Patent Document 1: JP-A-2004-214180

Patent Document 2: JP-A-H10-79297

Patent Document 3: JP-A-2002-100478

Patent Document 4: JP-A-2003-338377

Patent Document 5: WO2008/062773

Patent Document 6: WO2007/100010

Patent Document 7: JP-T-2002-525808

Patent Document 8: U.S. Pat. No. 7,018,723

Patent Document 9: JP-A-2005-158676

Patent Document 10: WO2005/076668

### Non-Patent Documents

Non-Patent Document 1: Journal of Applied Physics, 102, 114504 (2007)

Non-Patent Document 2: SID 2008 DIGEST, 709 (2008)

### SUMMARY OF THE INVENTION

In view of the above-mentioned circumstances, the inventors noticed a phenomenon stated in Non-Patent Document 1, i.e. a phenomenon in which singlet excitons are generated by collision and fusion of two triplet excitons (hereinafter referred to as Triplet-Triplet Fusion=TTF phenomenon), and made studies in an attempt to improve efficiency of a fluorescent device by allowing the TTF phenomenon to occur efficiently. Specifically, the inventors made studies on various combinations of a host material (hereinafter often referred to simply as a “host”) and a fluorescent dopant material (hereinafter often referred to simply as a “dopant”). As a result of the studies, the inventors have found that when the triplet energy of a host and that of a dopant satisfies a specific relationship, and a material having large triplet energy is used in a layer which is adjacent to the interface on the cathode side of an emitting layer, triplet excitons are confined within the emitting layer to allow the TTF phenomenon to occur efficiently, whereby improvement in efficiency and lifetime of a fluorescent device can be realized.

In addition, the inventors noticed the relationship between the affinity of the host of each of the blue-emitting fluorescent layer, the green-emitting phosphorescent layer and the red-emitting phosphorescent layer in a full-color device to improve the electron-injection properties thereof, and also found the relationship of a material constituting an electron-transporting layer which is provided as a common layer for the blue-emitting fluorescent layer, the green-emitting phosphorescent layer and the red-emitting phosphorescent layer, whereby improvement in efficiency of a full-color device has been realized.

It is known that, in a phosphorescent device, a high efficiency can be attained by using a material having large triplet energy in a layer which is adjacent to the interface on the cathode side of an emitting layer in order to prevent diffusion of triplet excitons outside the emitting layer, of which the exciton lifetime is longer than that of singlet excitons. JP-T-2002-525808 discloses a technology in which a blocking layer formed of BCP (bathocuproin), which is a phenanthroline derivative, is provided in such a manner that it is adjacent to an emitting layer, whereby holes or excitons are confined to achieve a high efficiency. U.S. Pat. No. 7,018,723 discloses use of a specific aromatic ring compound in a hole-blocking layer in an attempt to improve efficiency and prolonging lifetime. However, in these documents, for a phosphorescent device, the above-mentioned TTF phenomenon is called TTA (Triplet-Triplet Annihilation: triplet pair annihilation). That is, the TTA phenomenon is known as a phenomenon which deteriorates emission from triplet excitons which is the characteristics of phosphorescence. In a phosphorescent device, efficient confinement of triplet excitons within an emitting layer does not necessarily result in improvement in efficiency.

The object of the invention is to improve efficiency and lifetime without increasing the production cost in an organic EL device having a blue emitting layer, a green emitting layer and a red emitting layer.

The invention provides the following organic electroluminescence device.
1. An organic electroluminescence device comprising opposite anode and cathode, and a hole-transporting region, an emitting layer and an electron-transporting region in sequential order from the anode between the anode and the cathode,

wherein the emitting layer is formed of a red emitting layer, a green emitting layer, and blue emitting layer;

the blue emitting layer contains a host BH and a fluorescent dopant FBD;

the triplet energy E^{T}_{fbd} of the fluorescent dopant FBD is larger than the triplet energy E^{T}_{bh} of the host BH;

the green emitting layer contains a host GH and a phosphorescent dopant PGD;

a common electron-transporting layer is provided adjacent to the red emitting layer, the green emitting layer and the blue emitting layer within the electron-transporting region;

the triplet energy E^{T}ₑₗ of a material constituting the electron-transporting layer is larger than E^{T}_{bh}; and

the difference between the affinity of the host GH and the affinity of the material constituting the electron-transporting layer is 0.4 eV or less.
2. The organic electroluminescence device according to 1, wherein the red emitting layer contains a host RH and a phosphorescent dopant PRD; and

the difference between the affinity of the host RH and the affinity of the material constituting the electron-transporting layer is 0.4 eV or less.
3. The organic electroluminescence device according to 1 or 2, wherein the difference between the affinity of the host BH and the affinity of the material constituting the electron-transporting layer is 0.4 eV or less.
4. The organic electroluminescence device according to any one of 1 to 3, wherein the electron mobility of the material constituting the electron-transporting layer is 10⁻⁶ cm²/Vs or more in an electric field intensity of 0.04 to 0.5 MV/cm.
5. The organic electroluminescence device according to any one of 1 to 4, wherein an electron-injecting layer is provided between the electron-transporting layer and the cathode within the electron-transporting region.
6. The organic electroluminescence device according to any one of 1 to 5, wherein the affinity Af_{gh} of the host GH is 2.6 eV or more.
7. The organic electroluminescence device according to any one of 1 to 6, wherein the ionization potential Ip_{gd} of the dopant GD is 5.2 eV or more.
8. The organic electroluminescence device according to any one of 1 to 7, wherein at least one of the blue emitting layer, the green emitting layer and the red emitting layer contains a second dopant.
9. The organic electroluminescence device according to 8, wherein the green emitting layer contains a second dopant GD2.
10. The organic electroluminescence device according to 9, wherein the different between the affinity Af_{gd2} of the second dopant GD2 and the affinity Af_{gh} of the host GH is 0.4 eV or less.
11. The organic electroluminescence device according to any one of 1 to 10, wherein the electron-transporting region is consists of the electron-transporting layer, and the electron-transporting layer is doped with a donor.

According to the invention, in an organic EL device having a blue emitting layer, a green emitting layer and a red emitting layer, it is possible to improve efficiency and lifetime without increasing production cost.

### BRIEF DESCRIPTION OF THE DRAWINGS

FIG. 1 is a view showing an organic EL device according to one embodiment of the invention;

FIG. 2 is a view showing the energy state of the blue emitting layer according to one embodiment of the invention; and

FIG. 3 is a view showing the energy state of the green emitting layer according to one embodiment of the invention.

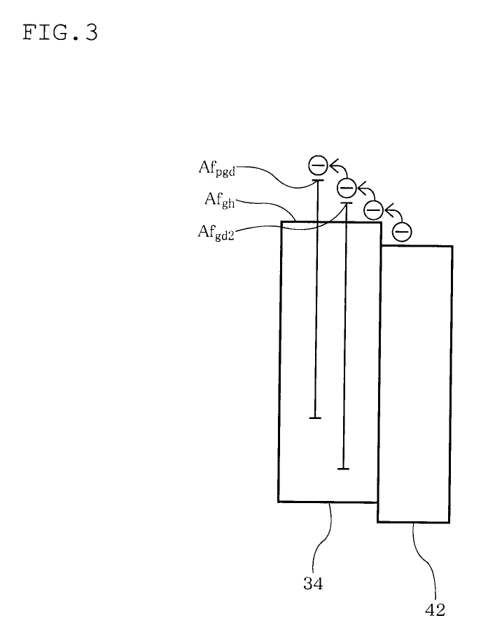

### MODE FOR CARRYING OUT THE INVENTION

The configuration of the organic EL device of the invention will be explained with reference to the drawings.

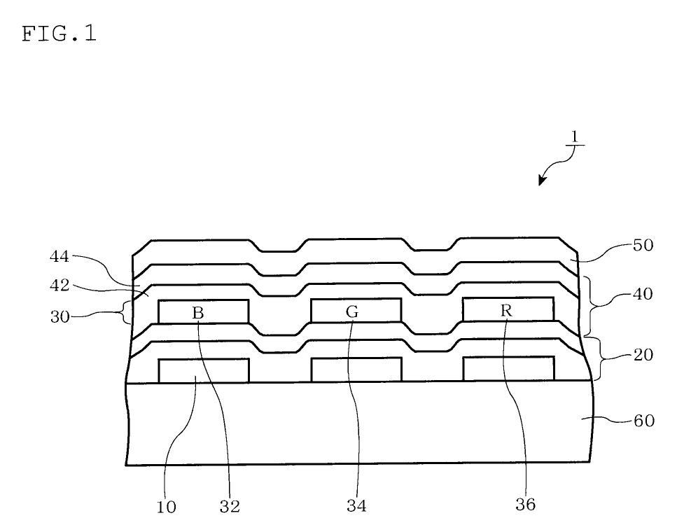

FIG. 1 is a view showing an organic EL device according to one embodiment of the invention.

An organic EL device 1 comprises, between an anode 10 and a cathode 50 which are opposite on a substrate 60, a hole-transporting region 20, an emitting layer and an electron-transporting region 40 in a sequential order from the anode 10.

The emitting layer is formed of a blue emitting layer 32, a green emitting layer 34 and a red emitting layer 36. The blue emitting layer 32 contains a host BH and a fluorescent dopant FBD, the green emitting layer 34 contains a host GH and a phosphorescent dopant PGD, and preferably, the red emitting layer 36 contains a host RH and a phosphorescent dopant PRD.

Further, within the electron-transporting region 40, a common electron-transporting layer 42 is provided in such a manner that it is adjacent to the blue emitting layer 32, the green emitting layer 34 and the red emitting layer 36. Preferably, within the electron-transporting region 40, an electron-injecting layer 44 is provided between the electron-transporting layer 42 and the cathode 50, more preferably the electron-injection layer 44 is provided such that it is adjacent to the electron-transporting layer 42.

In the hole-transporting region 20, a hole-transporting layer, or both a hole-transporting layer and a hole-injecting layer may be provided.

The method for fabricating the organic EL device 1 is explained hereinbelow. The anode 10 is stacked on the substrate 60, followed by patterning. As the material for the anode 10, a metal film as a reflective film is used in the case of a front-emission type device. ITO, IZO or the like is used as a transparent electrode in the case of a back emission-type device. Thereafter, as the hole-transporting region 20, the hole-injecting layer is stacked over the entire surface of the substrate, and the hole-transporting layer is stacked thereon.

The emitting layers are formed such that each emitting layer corresponds to the position of the anode. When the vacuum vapor deposition method is used, the blue emitting layer 32, the green emitting layer 34 and the red emitting layer 36 are finely patterned by means of a shadow mask.

Subsequently, the electron-transporting region 40 is stacked over the entire surface of the blue emitting layer 32, the green emitting layer 34 and the red emitting layer 36.

Then, the cathode is stacked, whereby an organic EL device is fabricated.

As the substrate, a glass substrate, a TFT substrate or the like may be used.

In this embodiment, the hole-transporting region 20 is commonly provided as the hole-injecting layer and the hole-transporting layer using a common material. It is also possible to provide the hole-transporting region 20 by subjecting different materials to patterning in correspondence with the blue emitting layer 32, the green emitting layer 34 and the red emitting layer 36. As the hole-transporting region, a single hole-transporting layer or a singe hole-injecting layer may be used. Three or more layers formed of a combination of the hole-injecting layer and the hole-transporting layer may be stacked. When the hole-transporting region is formed of a plurality of layers, part of the layers are provided as a common layer, and the remaining layers may be provided in correspondence with the blue emitting layer 32, the green emitting layer 34 and the red emitting layer 36 by finely patterning different materials.

The emitting layer of the invention contains a blue pixel, a green pixel and a red pixel. The blue pixel, the green pixel and the red pixel are formed of the blue emitting layer, the green emitting layer and the red emitting layer, respectively. A voltage is separately applied to each pixel. Therefore, in the organic EL device 1 in FIG. 1, the blue emitting layer 32, the green emitting layer 34 and the red emitting layer 36 do not always emit light simultaneously, and it is possible to allow three emitting layers 32, 34 and 36 to emit light selectively.

The organic EL device of the invention is a device in which, in the above-mentioned blue emitting layer 32, the phenomenon stated in Non-Patent Document 1, i.e. singlet excitons are formed by collision and fusion of two triplet excitons (hereinafter referred to as the “Triplet-Triplet-Fusion (TTF) phenomenon”). First, an explanation is given below on the TTF phenomenon.

Holes and electrons injected from an anode and a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of a conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with each other with an increase in the density thereof, whereby a reaction shown by the following formula occurs. In the formula, ¹A represents the ground state and ¹A* represents the lowest excited singlet excitons.

3A*+³A*→(4/9)¹A+(1/9)¹A*+(13/9)³A*

That is, 5³A*→4¹A+¹A*, and it is expected that, among triplet excitons initially generated, which account for 75%, one fifth thereof, that is, 20%, is changed to singlet excitons. Therefore, the amount of singlet excitons which contribute to emission is 40%, which is a value obtained by adding 15% ((75%×(1/5)=15%) to 25%, which is the amount ratio of initially generated singlet excitons. At this time, the ratio of luminous intensity derived from TTF (TTF ratio) relative to the total luminous intensity is 15/40, that is, 37.5%. Assuming that singlet excitons are generated by collision of initially-generated triplet excitons which account for 75% (that is, one siglet exciton is generated from two triplet excitons), a significantly high internal quantum efficiency of 62.5% is obtained which is a value obtained by adding 37.5% ((75%×(1/2)=37.5%) to 25%, which is the amount ratio of initially generated singlet excitons. At this time, the TTF ratio is 60% (37.5/62.5).

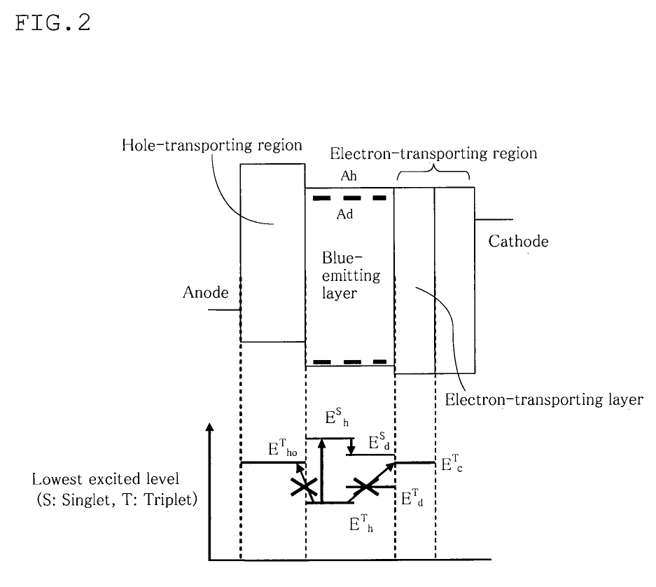

FIG. 2 is a schematic view showing one example of the energy level of the blue emitting layer of the organic EL device shown in FIG. 1.

The upper view in FIG. 2 shows the device configuration and the HOMO and LUMO energy levels of each layer (here, the LUMO energy level and the HOMO energy level may be called as an affinity (Af) and an ionization potential (Ip), respectively). The lower view is a schematic view showing the lowest excited singlet energy level and the lowest excited triplet energy level of each layer. In the invention, the triplet energy is referred to as a difference between energy in the lowest triplet exited state and energy in the ground state. The singlet energy (often referred to as an energy gap) is referred to as a difference between energy in the lowest singlet excited state and energy in the ground state.

Holes injected from an anode are then injected to an emitting layer through a hole-transporting region. Electrons injected from a cathode are then injected to the emitting layer through an electron-transporting region. Thereafter, holes and electrons are recombined in the emitting layer, whereby singlet excitons and triplet excitons are generated. There are two manners as for the occurrence of recombination. Specifically, recombination may occur either on host molecules or on dopant molecules. As shown in the lower view of FIG. 2, if the triplet energy of a host and that of a dopant of the blue emitting layer are taken as E^{T}ₕ and E^{T}_{d}, respectively, the relationship E^{T}ₕ<E^{T}_{d} is satisfied. When this relationship is satisfied, triplet excitons generated by recombination on a host do not transfer to a dopant which has a higher triplet energy. Triplet excitons generated by recombination on dopant molecules quickly energy-transfer to host molecules. That is, triplet excitons on a host do not transfer to a dopant and collide with each other efficiently on the host to generate singlet exitons by the TTF phenomenon. Further, since the singlet energy E^{s}_{d} of a dopant is smaller than the singlet energy E^{s}ₕ of a host, singlet excitons generated by the TTF phenomenon energy-transfer from a host to a dopant, thereby contributing fluorescent emission of a dopant. In dopants which are usually used in a fluorescent device, transition from the excited triplet state to the ground state should be inhibited. In such a transition, triplet excitons are not optically energy-deactivated, but are thermally energy-deactivated. By causing the triplet energy of a host and the triplet energy of a dopant to satisfy the above-mentioned relationship, singlet excitons are generated efficiently due to the collision of triplet excitons before they are thermally deactivated, whereby luminous efficiency is improved.

In the invention, the electron-transporting layer has a function of preventing triplet excitons generated in the blue emitting layer to be diffused to the electron-transporting region, allowing triplet excitons to be confined within the blue emitting layer to increase the density of triplet excitons therein, causing the TTF phenomenon to occur efficiently. In order to suppress triplet excitons from being diffused, it is preferred that the triplet energy of the electron-transporting layer E^{T}ₑₗ be larger than E^{T}ₕ. It is further preferred that E^{T}ₑₗ be larger than E^{T}_{d}. Since the electron-transporting layer prevents triplet excitons from being diffused to the electron-transporting region, in the blue emitting layer, triplet excitons of a host become singlet excitons efficiently, and the singlet excitons transfer to a dopant, and are optically energy-deactivated.

Further, as shown in FIG. 2, in the hole-transporting region, the hole-transporting layer is adjacent to the blue emitting layer and the triplet energy of the hole-transporting layer E^{T}ₕₒ is larger than the E^{T}ₕ of the host of the blue emitting layer, the triplet excitons generated in the blue emitting layer are kept within the blue emitting layer, and as a result, a higher luminous efficiency can be obtained.

Further, as shown in FIG. 2, if a host and a dopant are combined such that the relationship between the affinity Ah of the host and the affinity Ad of the dopant satisfies Ah≦Ad, the advantageous effects of the electron-transporting layer provided within the electron-transporting region are exhibited significantly, whereby improvement in efficiency due to the TTF phenomenon can be attained.

In the green emitting layer 34 of the organic EL device of the invention, the difference between the affinity of the host GH and the affinity of the material constituting the electron-transporting layer is 0.4 eV or less.

Normally, the triplet energy of the phosphorescent dopant PGD of the green emitting layer is larger than the triplet energy E^{T}ₑₗ of the material constituting the electron-transporting layer. Therefore, prior to phosphorescent emission, the triplet excitons on the phosphorescent dopant PGD transfer to the material constituting the electron-transporting layer of which the triplet energy is smaller. As a result, luminous efficiency of the green emitting layer is lowered. However, as in the case of the invention, when the difference between the affinity of the host GH and the affinity of the material constituting the electron-transporting layer is allowed to be 0.4 eV or less, the injection properties of electrons from the electron-transporting layer to the green emitting layer is improved. As a result, electrons and holes are recombined in the hole-transporting region side of the emitting layer in a biased manner, that is, electrons and holes are recombined at a distance from the electron-transporting region. As a result, triplet excitons are generated at a distance from the green emitting layer, triplet excitons hardly transfer from the green emitting layer to the electron-transporting layer, whereby lowering in luminous efficiency can be prevented.

In addition, in order to keep the recombination region away from the electron-transporting layer, the hole mobility μh and the electron mobility μe of the host of the emitting layer desirably satisfies the relationship μe/μh>1. μe/μh>5 is most desirable.

As mentioned above, in the invention, emitting layers of three colors are formed in parallel. However, mass productivity is improved since a common material is used as the electron-transporting layer. Further, in the blue emitting layer, the luminous efficiency thereof is improved by utilizing the TTF phenomenon. In the green emitting layer, the luminous efficiency thereof is prevented from lowering by adjusting the affinity. As a result, a high efficiency is attained in both the blue emitting layer and the green emitting layer.

The red emitting layer 36 can be formed such that it contains a host RH and a phosphorescent dopant PRD. If the red emitting layer 36 contains the host RH and the phosphorescent dopant PRD, it is preferred that the difference between the affinity of the host RH and the affinity of the material constituting the electron-transporting layer is 0.4 eV or less. The reason therefor is that, as mentioned above, luminous efficiency is prevented from lowering since the transfer of triplet energy from the red emitting layer to the electron-transporting layer becomes difficult.

Also, it is preferred that the difference between the affinity of the host BH of the blue emitting layer and the affinity of the material constituting the electron-transporting layer be 0.4 eV or less. The reason therefor is that electron injecting properties to the emitting layer are improved by allowing the difference in affinity to be 0.4 eV or less. When the electron injecting properties to the emitting layer are deteriorated, the density of triplet excitons is decreased since the electron-hole recombination in the emitting layer is decreased. If the density of triplet excitons is decreased, the frequency of collision of triplet excitons is reduced, and a TTF phenomenon does not occur efficiently. Further, since electron injection performance is improved, the organic EL device can be driven at a lower voltage.

In the green emitting layer, it is preferred that the host GH have an affinity Af_{gh} of 2.6 eV or more in order to enhance electron flowability and allow the recombination region to be away from the electron-transporting region. The ionization potential Ip_{gd} of the dopant GD of the green emitting layer is preferably 5.2 eV or more in order to improve the probability of recombination. If the affinity Af_{gh} of the host is increased in order to improve electron-injecting properties, the difference between the affinity Af_{gh} and the affinity Af_{gd} of the dopant is increased, and injection of electrons to the dopant becomes difficult, and the probability of recombination on the dopant is lowered. For this reason, it is desirable to allow the affinity Af_{gd} of the dopant to be large, or to allow the ionization potential Ip_{gd} of the dopant to be large.

It is preferred that the green emitting layer contain, in addition to the dopant PGD, a second dopant GD2 having an affinity Af_{gd2} of which the difference with the affinity Af_{gh} of the host GH is 0.4 eV or less. Further, the energy gap of the dopant PGD is desirably smaller than the energy gap of the second dopant GD2.

In the green emitting layer, normally, electrons are transferred from the electron-transporting layer to the host GH in the green emitting layer, and then transferred from the host GH to the dopant PGD. If the difference between the affinity Af_{gh} of the host GH and the affinity Af_{gh} of the dopant is increased and injection properties of electrons to the dopant is lowered, part of electrons may be flown directly in the direction of the anode without transferring from the host GH to the dopant PGD. If the second dopant having an affinity Af_{gd2} of which the difference with the affinity Af_{gh} of the host GH is 0.4 eV or less is contained, electrons flow from the electron-transporting layer to the host GH of the green emitting layer, and then flow to the second dopant GD2 and the dopant PGD, whereby part of electrons can be prevented from flowing to the anode without transferring to the dopant PGD. As a result, a larger number of electrons reach the dopant PGD to improve recombination probability, whereby luminous efficiency can be improved.

The blue emitting layer or the red emitting layer may contain a second dopant having an affinity Af_{gd2} of which the difference with the affinity Af_{gh} of the host of the blue emitting layer or the red emitting layer is 0.4 eV or less. Due to the presence of the second dopant, electrons can be prevented from directly flowing in the anode direction without transferring to the dopant.

In the invention, the materials constituting the hosts and the dopants of the blue emitting layer, the green emitting layer and the red emitting layer and the material constituting the electron-transporting layer can be produced by selecting from known compounds a compound satisfying the above-mentioned conditions which are necessary or preferable for the invention. Although the materials constituting each layer are not limited as long as the conditions required for the invention are satisfied, preferably, they can be selected from the following compounds.

The host of the blue emitting layer is an anthracene derivative and a polycyclic aromatic skeleton-containing compound or the like. An anthracene derivative is preferable. The dopant of the blue emitting layer is a fluoranthene derivative, a styrylarylene derivative, a pyrene derivative, an arylacetylene derivative, a fluoren derivative, a boron complex, a perylene derivative, an oxadiazole derivative and an anthracene derivative or the like. A fluoranthene derivative, a styrylarylene derivative, a pyrene derivative and a boron complexe are preferable, with fluoranthene derivatives and boron complex compounds being more preferable. As for the combination of a host and a dopant, it is preferred that the host be an anthracene derivative and the dopant be a fluoranthene derivative or a boron complex.

Specific examples of the fluoranthene derivatives are given below.

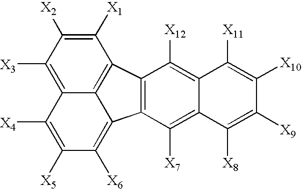

wherein X₁ to X₁₂ are hydrogen or a substituent. Preferably, it is a compound in which X₁ to X₂, X₄ to X₆ and X₈ to X₁₁ are a hydrogen atom and X₃, X₇ and X₁₂ are a substituted or unsubstituted aryl having 5 to 50 atoms that form a ring (hereinafter referred to as ring atoms). More preferably, it is a compound in which X₁ to X₂, X₄ to X₆ and X₈ to X₁₁ are a hydrogen atom, X₇ and X₁₂ are a substituted unsubstituted aryl group having 5 to 50 ring atoms, X₃ is —Ar₁—Ar₂ (Ar₁ is a substituted or unsubstituted arylene group having 5 to 50 ring atoms, and Ar₂ is a substituted or unsubstituted aryl group having 5 to 50 ring atoms). Further preferably, it is a compound in which X₁ to X₂, X₄ to X₆ and X₈ to X₁₁ are a hydrogen atom, X₇ and X₁₂ are a substituted or unsubstituted aryl group having 5 to 50 ring atoms and X₃ is —Ar₁—Ar₂—Ar₃ (wherein Ar₁ and Ar₃ are independently a substituted or unsubstituted arylene group having 5 to 50 ring atoms and Ar₂ is a substituted or unsubstituted aryl group having 5 to 50 ring atoms).

Specific examples of the boron complex compounds are given below.

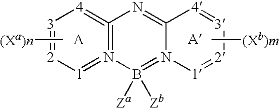

wherein A and A′ are an independent azine ring system corresponding to a six-membered aromatic ring system containing at least one nitrogen; X^{a} and X^{b}, which are independently a substituent, respectively bonds to the ring A or the ring A′ to form a fused ring for the ring A or the ring A′; the fused ring contains an aryl or heteroaryl substituent; m and n are independently 0 to 4; Z^{a} and Z^{b} are independently a halide; and 1, 2, 3, 4, 1′, 2′, 3′ and 4′ are independently a carbon atom or a nitrogen atom.

Desirably, the azine ring is a quinolynyl or isoquinolynyl ring in which each of 1, 2, 3, 4, 1′, 2′, 3′ and 4′ is a carbon atom, m and n are 2 or more and X^{a} and X^{b} are a substituent having 2 or more carbon atoms which bonds to the azine ring to form an aromatic ring. It is preferred that Z^{a} and Z^{b} be a fluorine atom.

Specific examples of anthracene compounds include the following compounds:

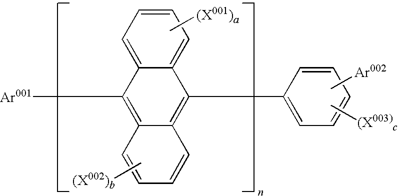

wherein Ar⁰⁰¹ is a substituted or unsubstituted fused aromatic group having 10 to 50 carbon atoms that form a ring (hereinafter referred to as a ring carbon atom); Ar⁰⁰² is a substituted or unsubstituted aromatic group having 6 to 50 ring carbon atoms; X⁰⁰¹ to X⁰⁰³ are independently a substituted or unsubstituted aromatic group having 6 to 50 ring carbon atoms, a substituted or unsubstituted aromatic heterocyclic group having 5 to 50 ring atoms, a substituted or unsubstituted alkyl group having 1 to 50 carbon atom, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 ring atoms, a substituted or unsubstituted arylthio group having 5 to 50 ring atoms, a substituted or unsubstituted alkoxycarbonyl group having 1 to 50 carbon atoms, a carboxyl group, a halogen atom, a cyano group, a nitro group or a hydroxy group. a, b and c each are an integer of 0 to 4. n is an integer of 1 to 3. When n is two or more, the groups in [ ] may be the same or different. n is preferably 1. a, b and c are preferably 0.

The following compounds may be used as the host of the blue emitting layer, for example.

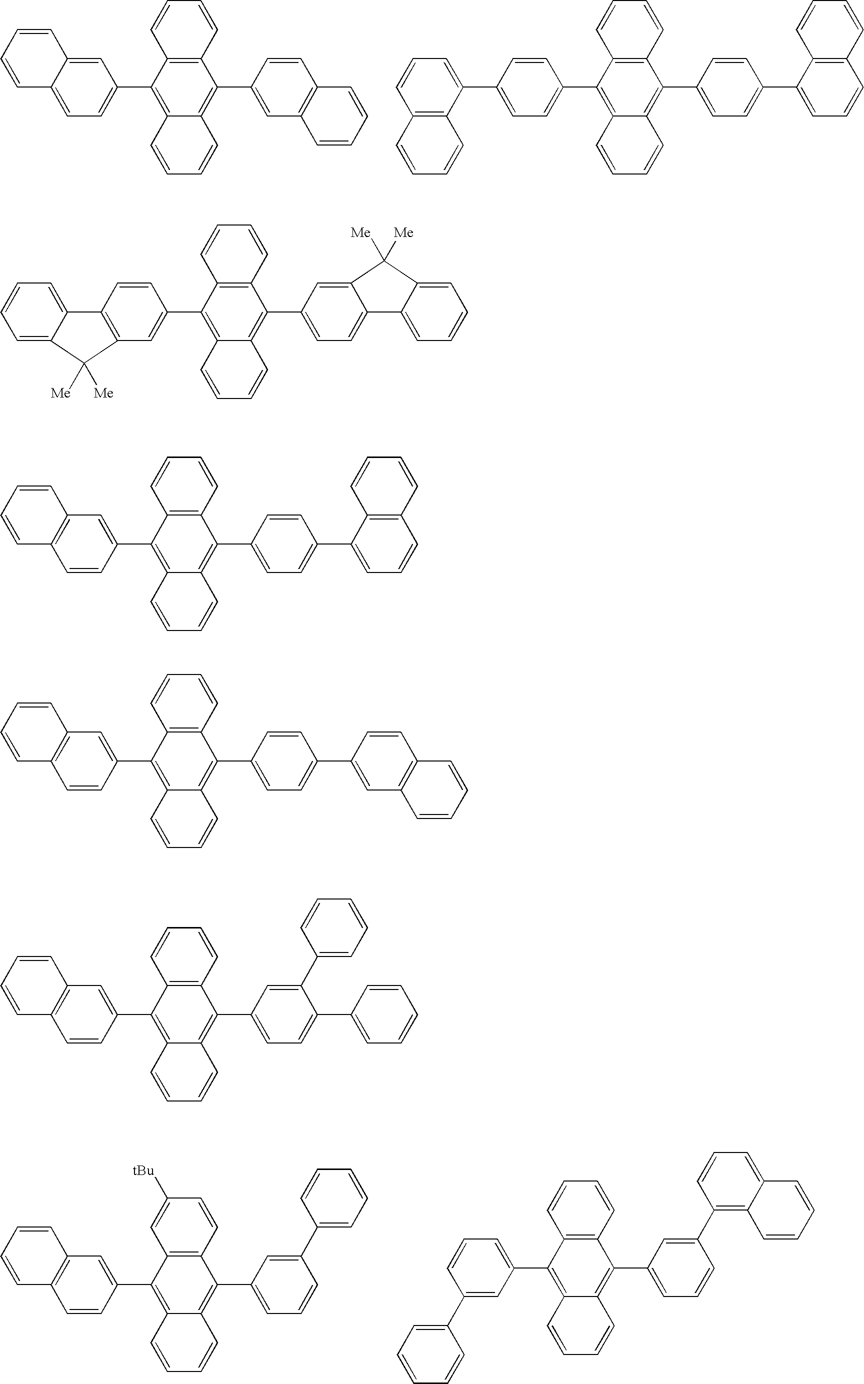

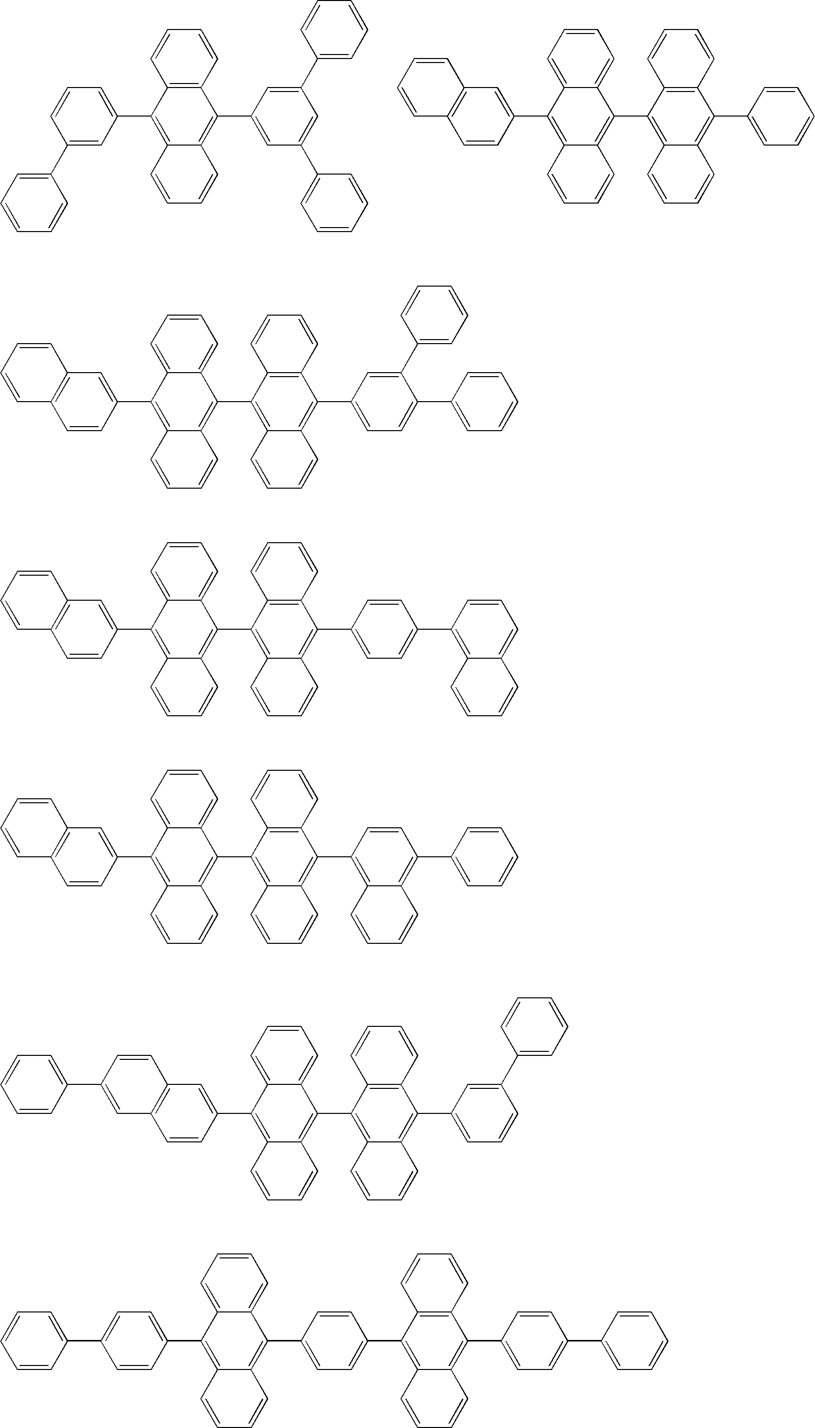

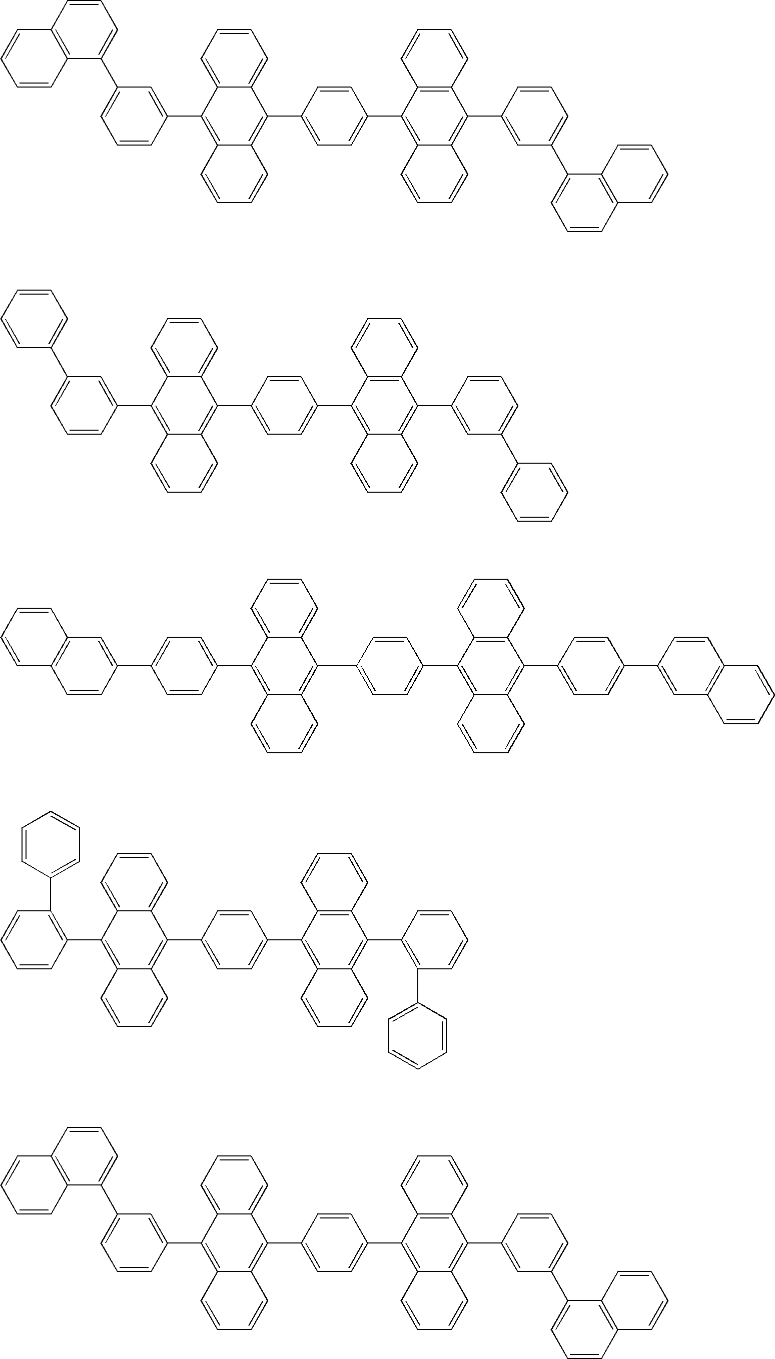

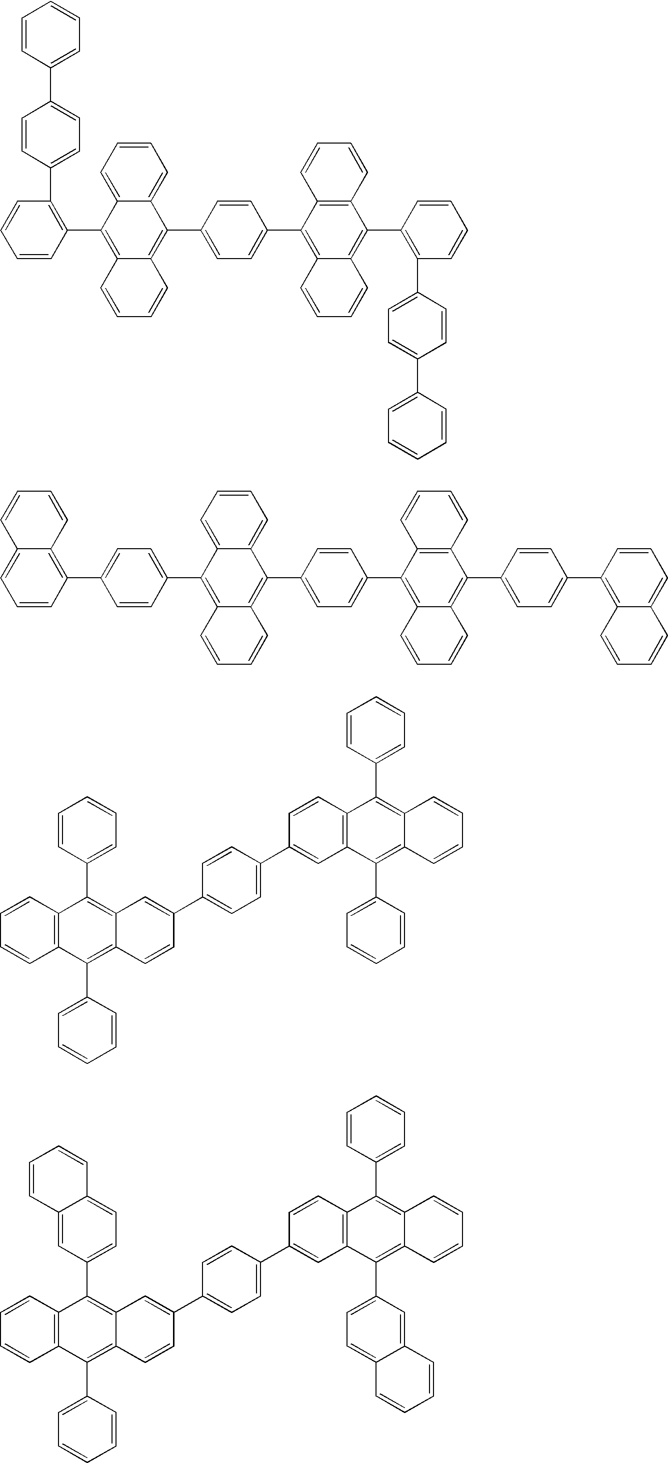

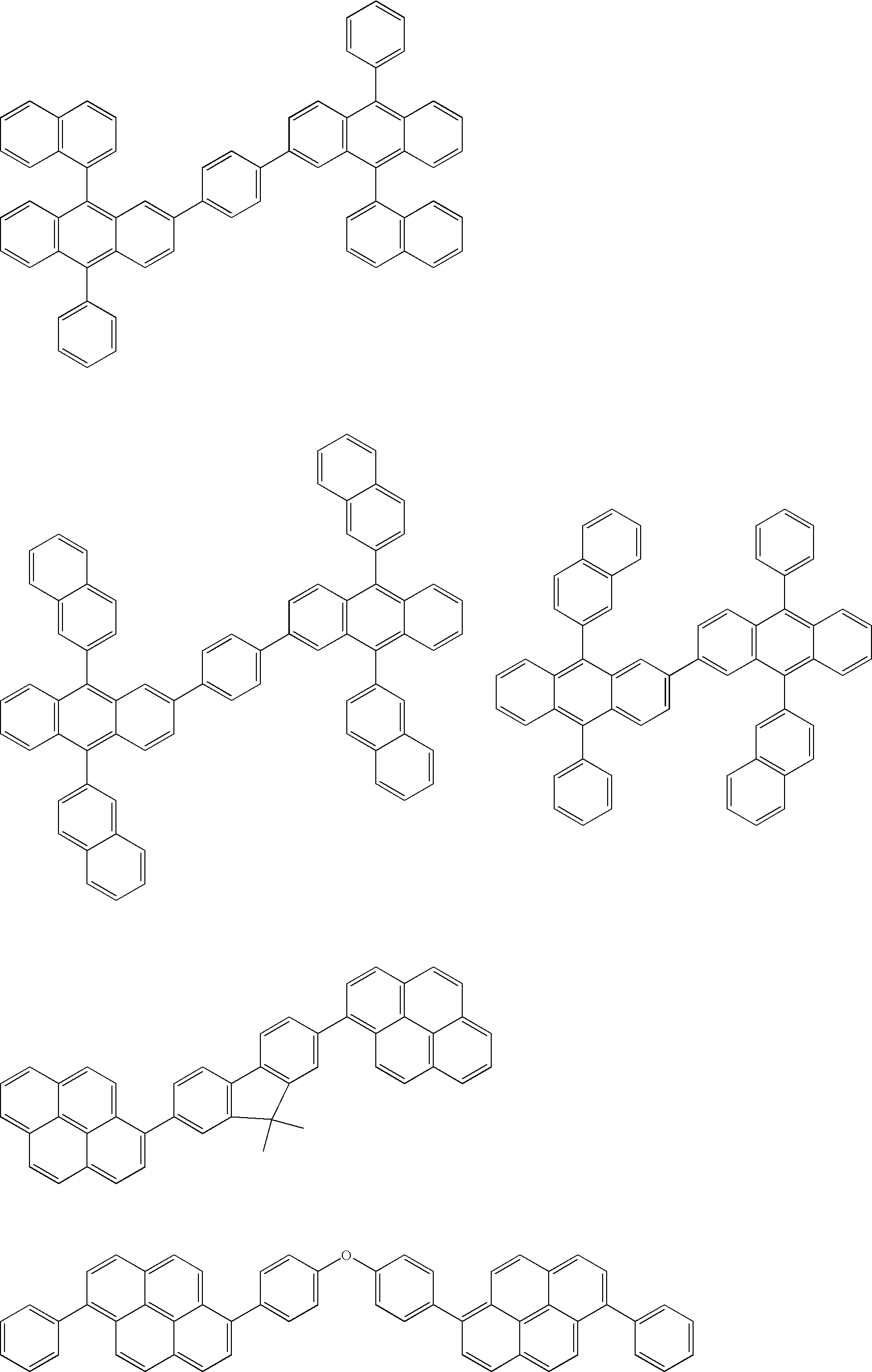

The fluorescent dopant of the blue emitting layer is preferably a compound represented by the following formula.

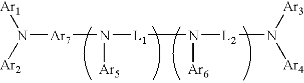

wherein Ar₁ to Ar₆ are independently an aryl group having 6 to 30 carbon atoms and Ar₇ is an arylene group having 6 to 30 carbon atoms. Ar₁ to Ar₇ may be substituted, and as the substituent, an alkoxy group, a dialkylamino group, an alkyl group, a fluoroalkyl group or a silyl group is preferable. m is 0 or 1, and n is 0 or 1. L₁ and L₂ are independently an alkenylene group or a divalent aromatic hydrocarbon group.

As the fluorescent dopant of the blue emitting layer, the following compounds can be used.

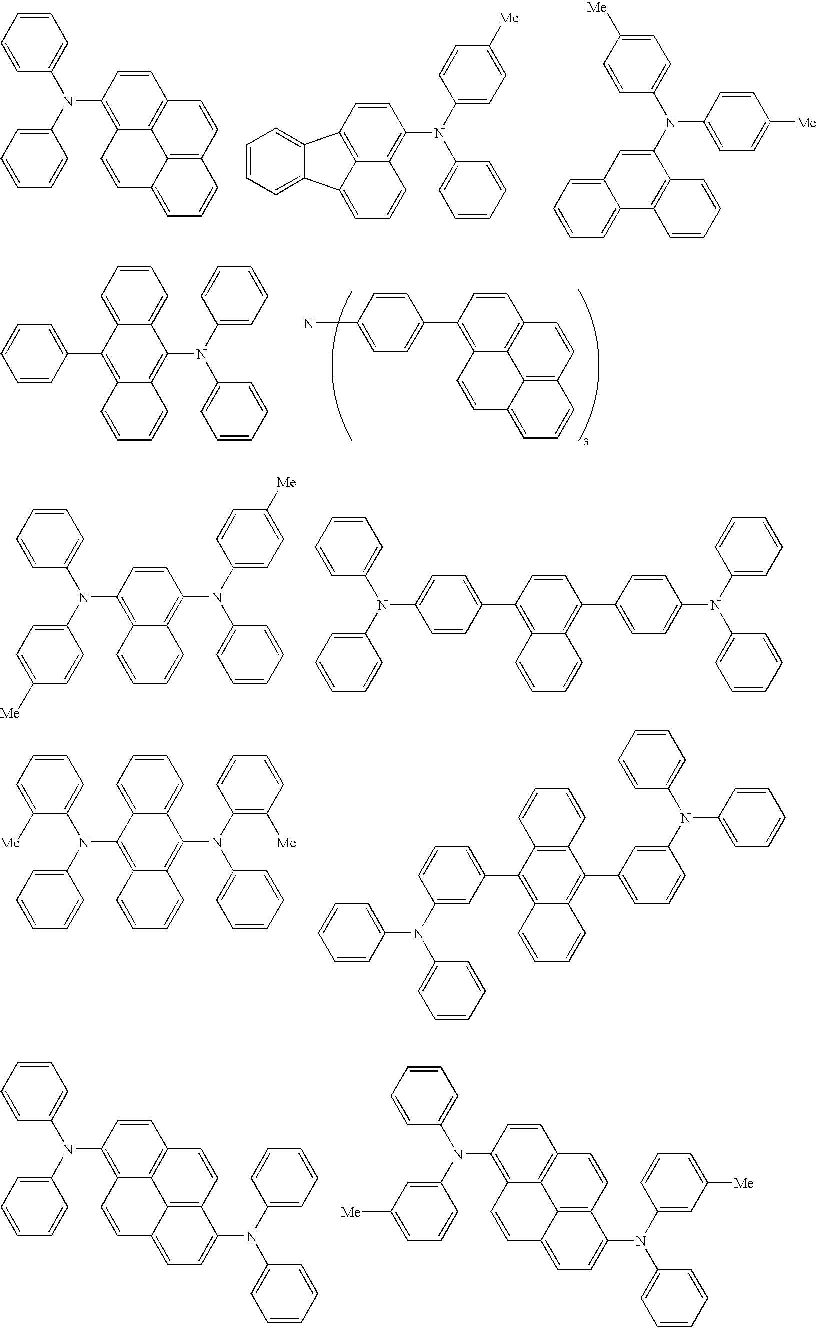

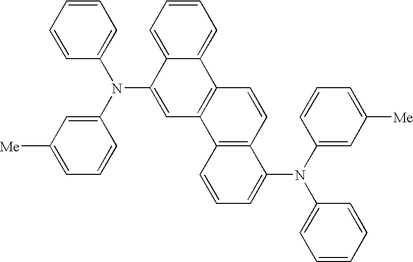

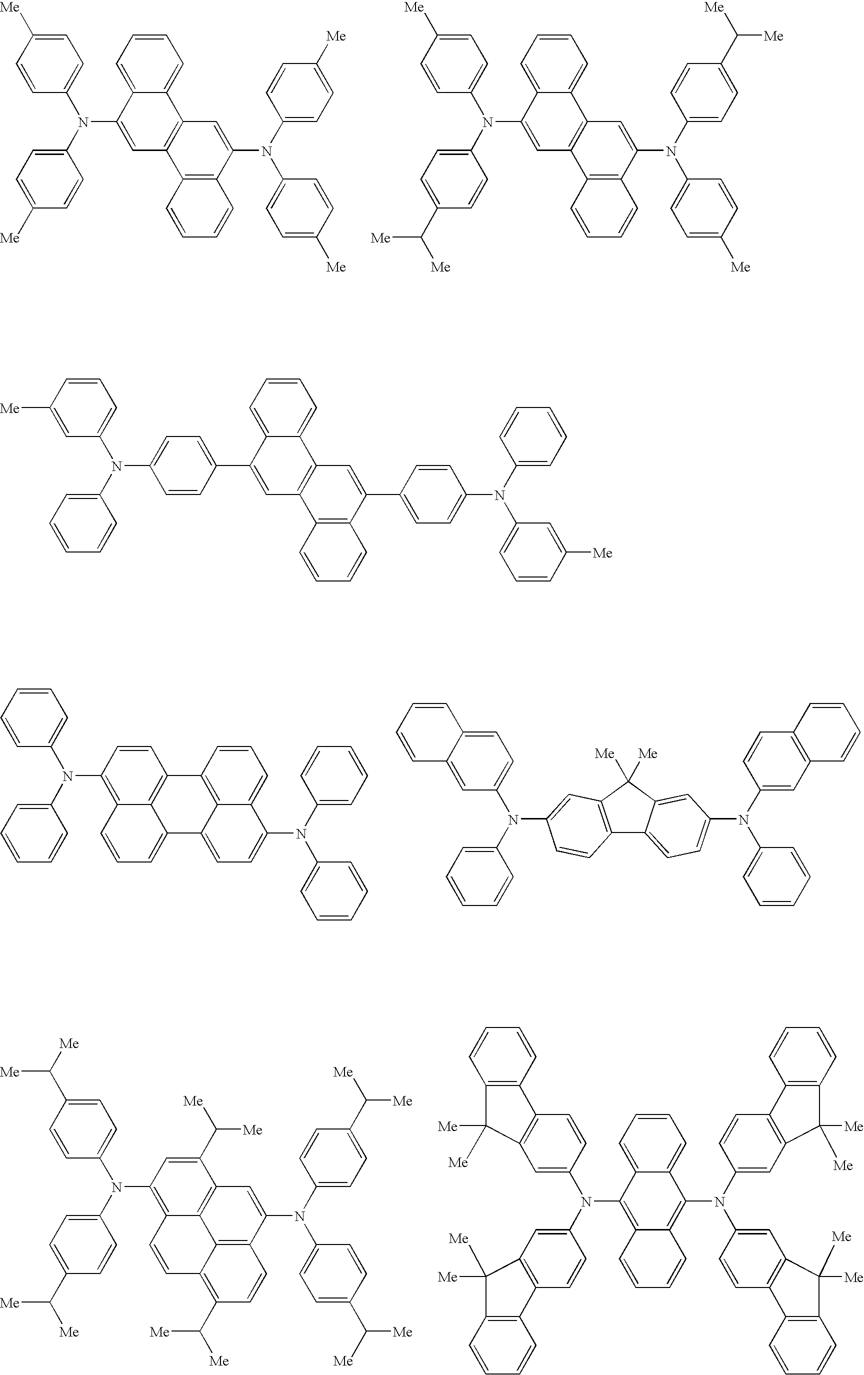

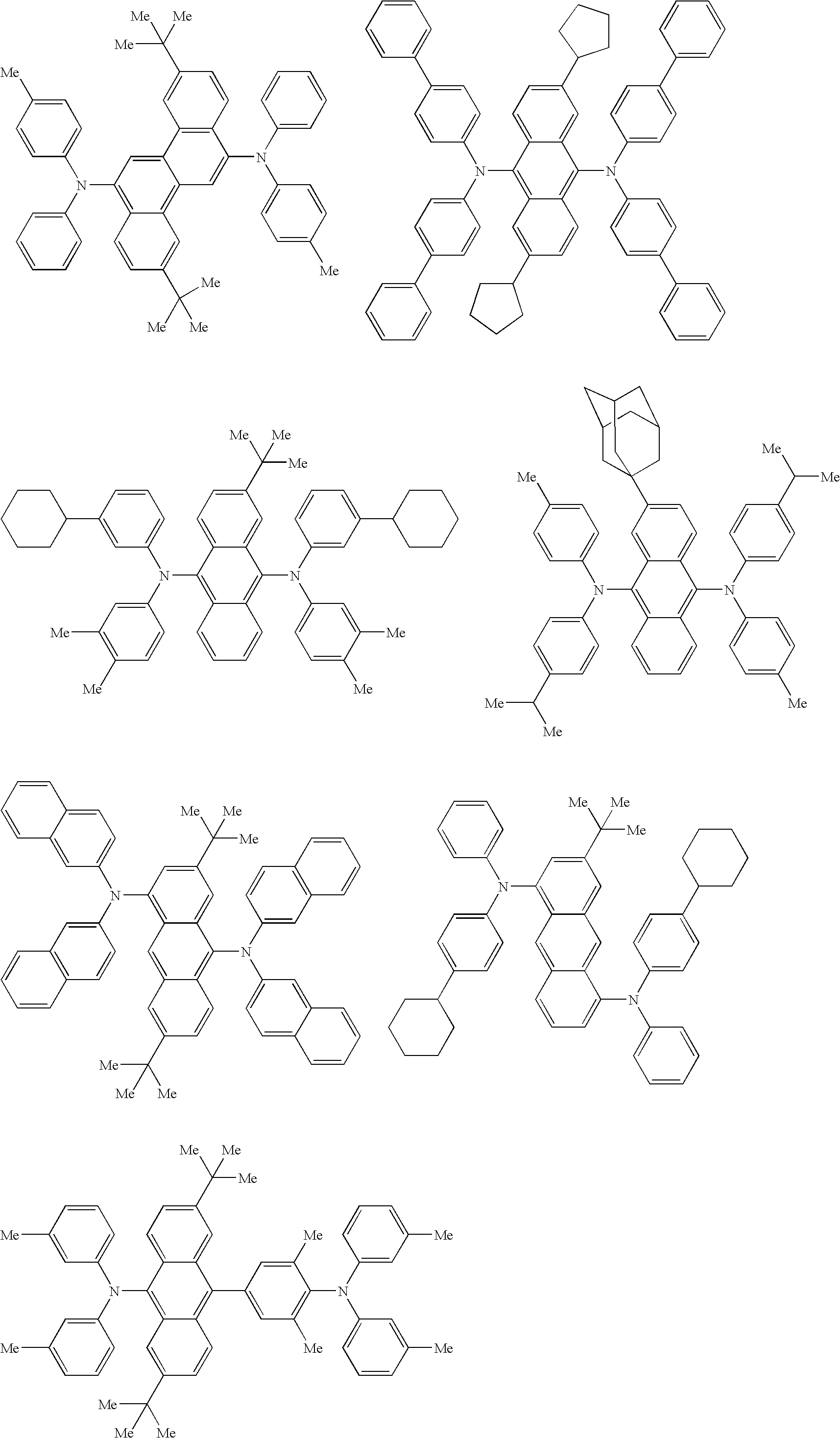

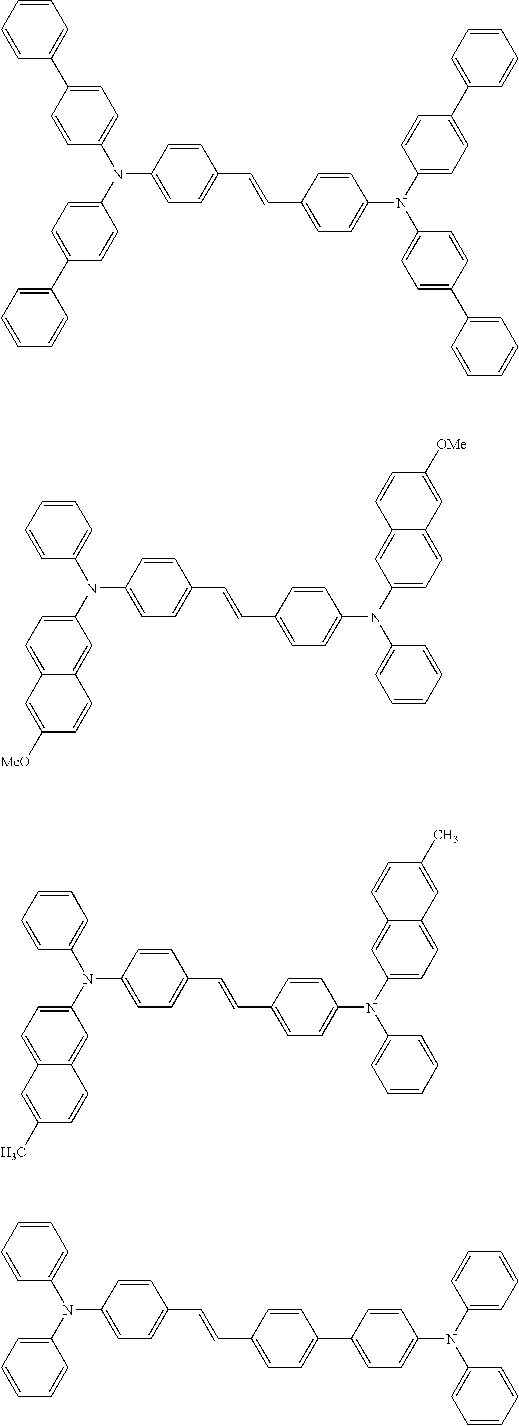

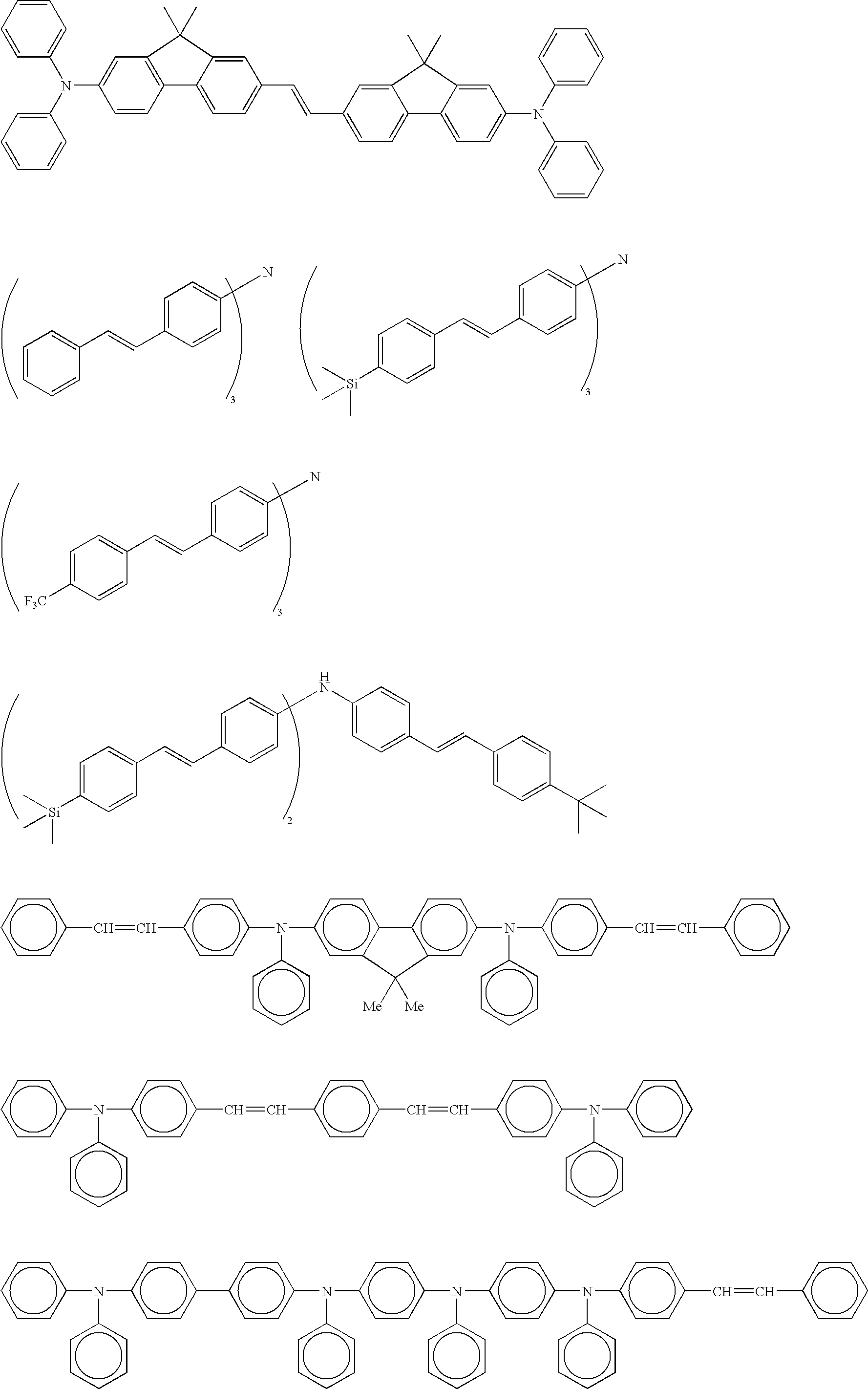

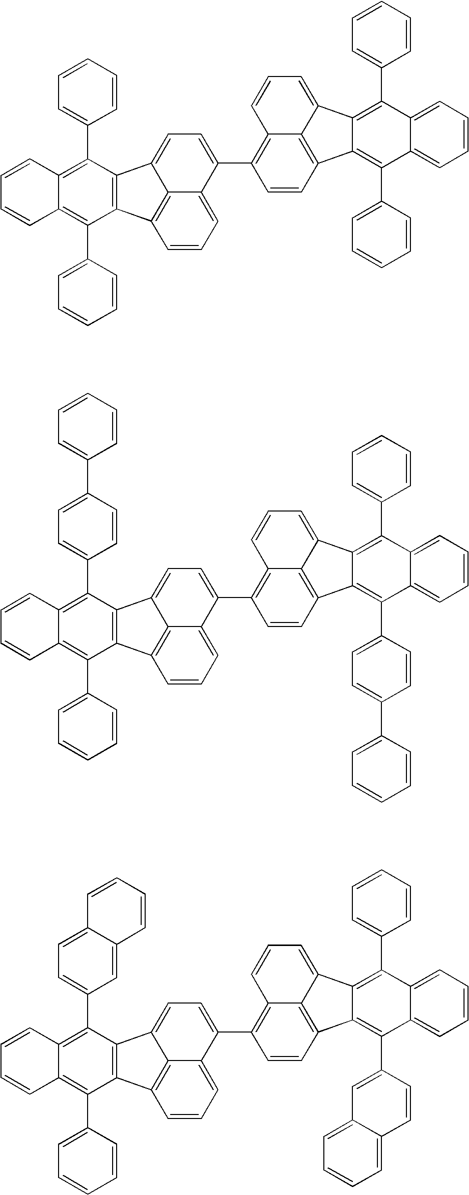

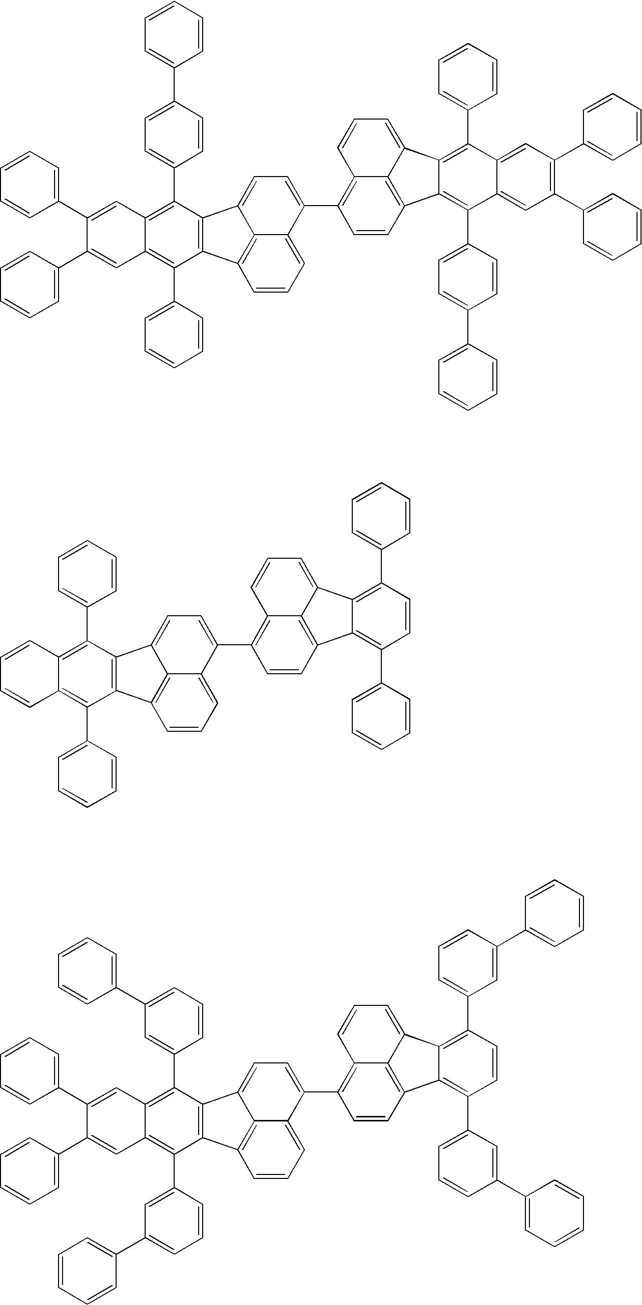

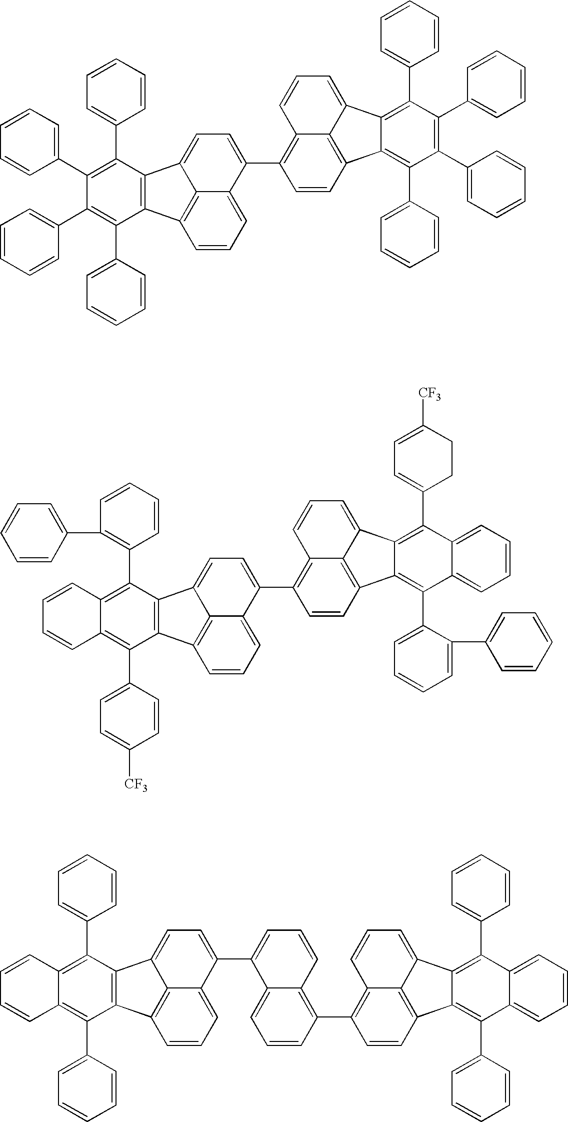

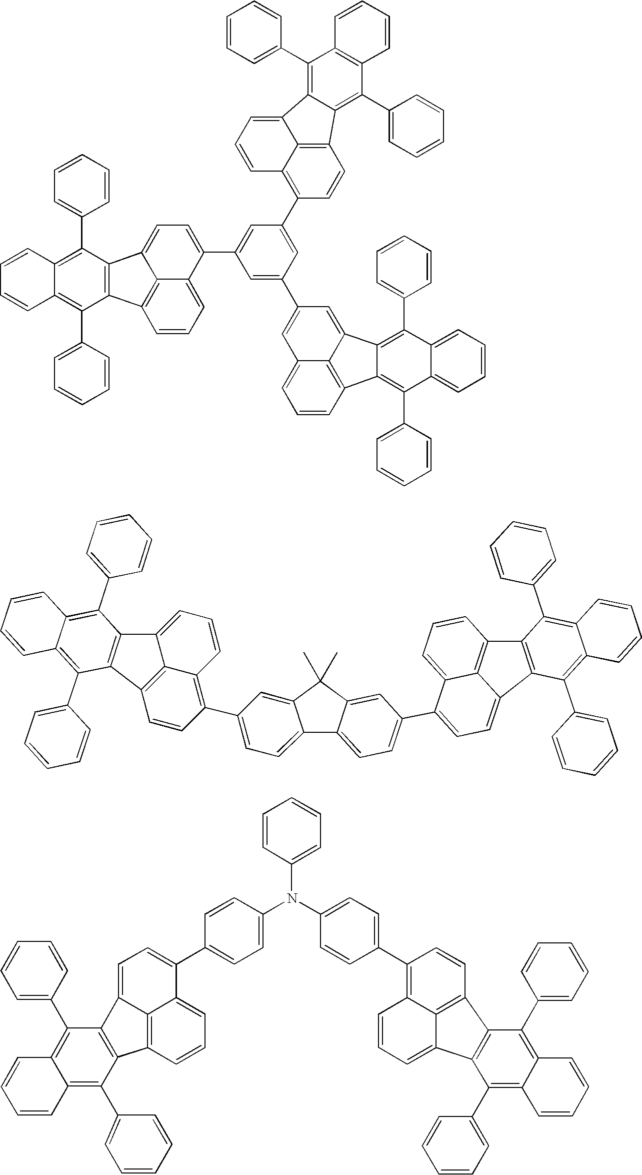

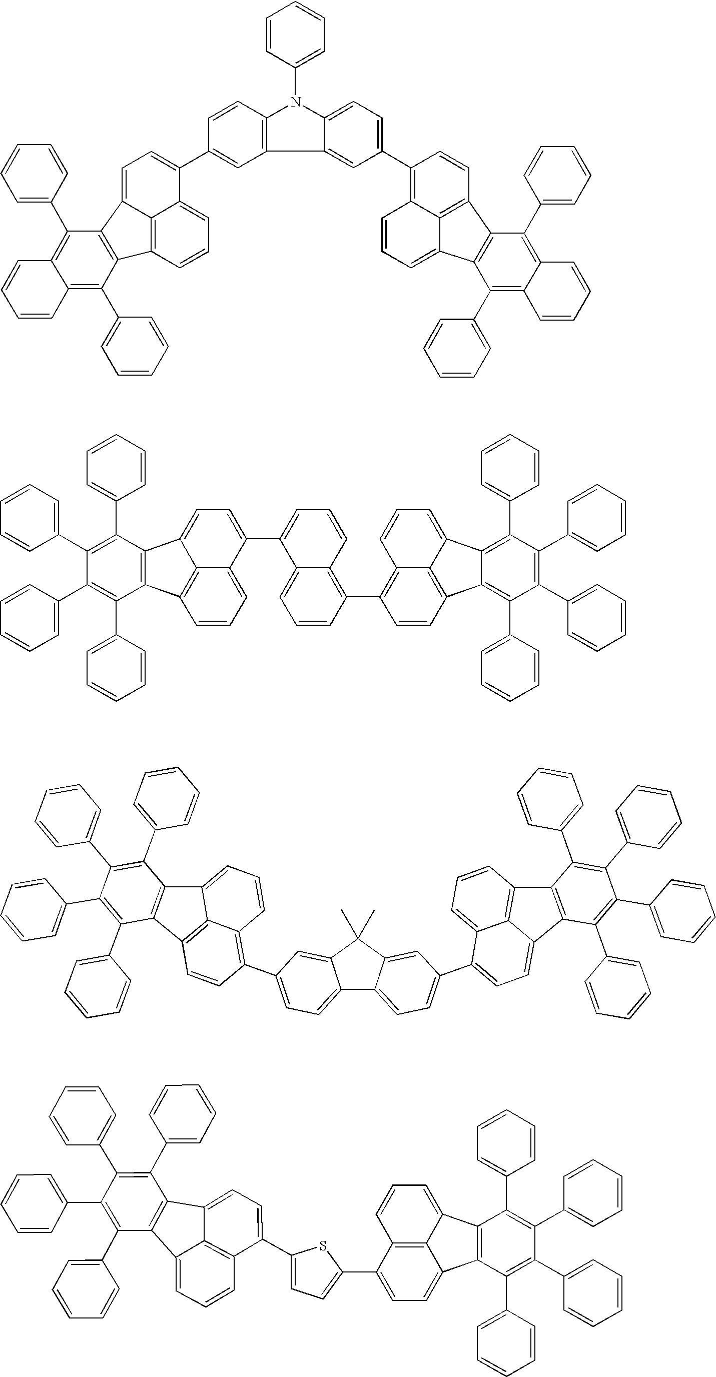

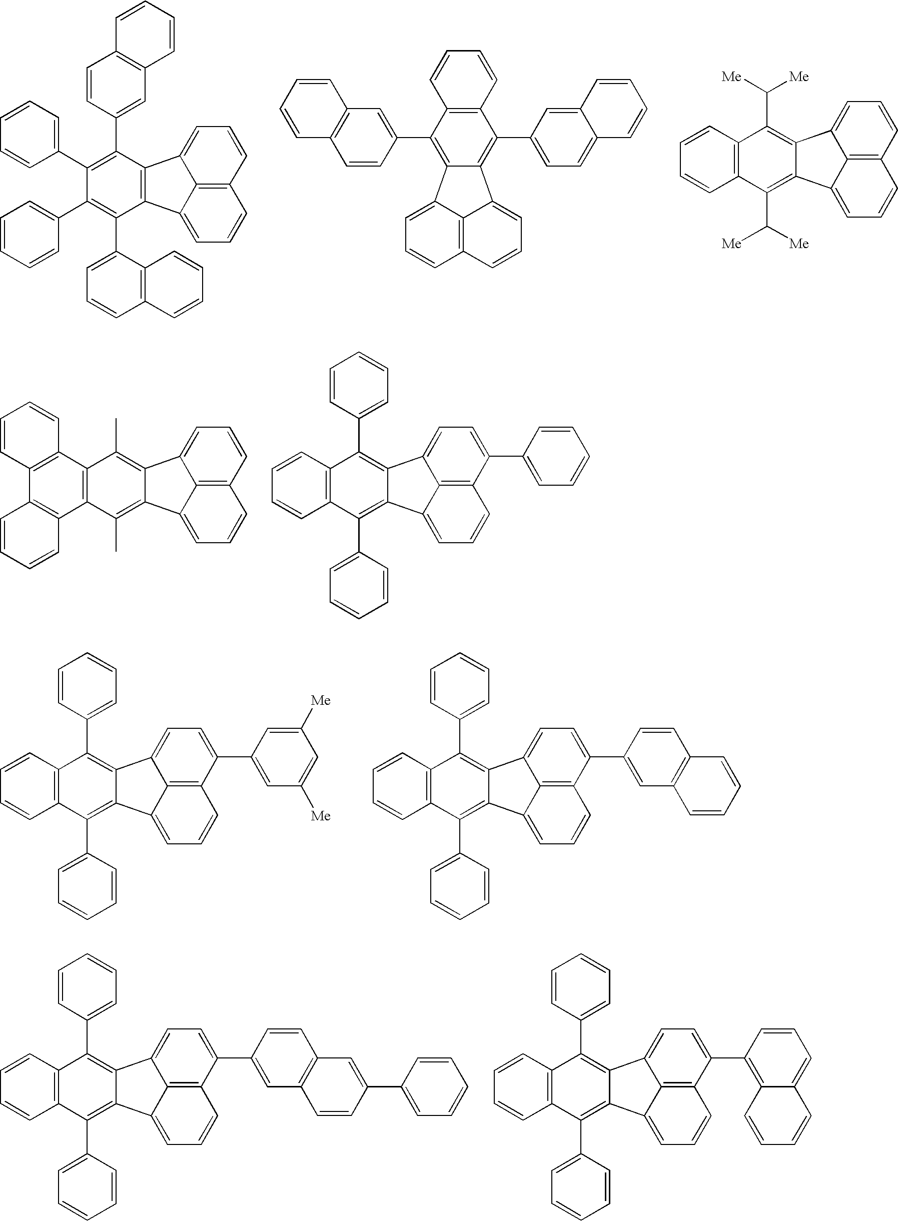

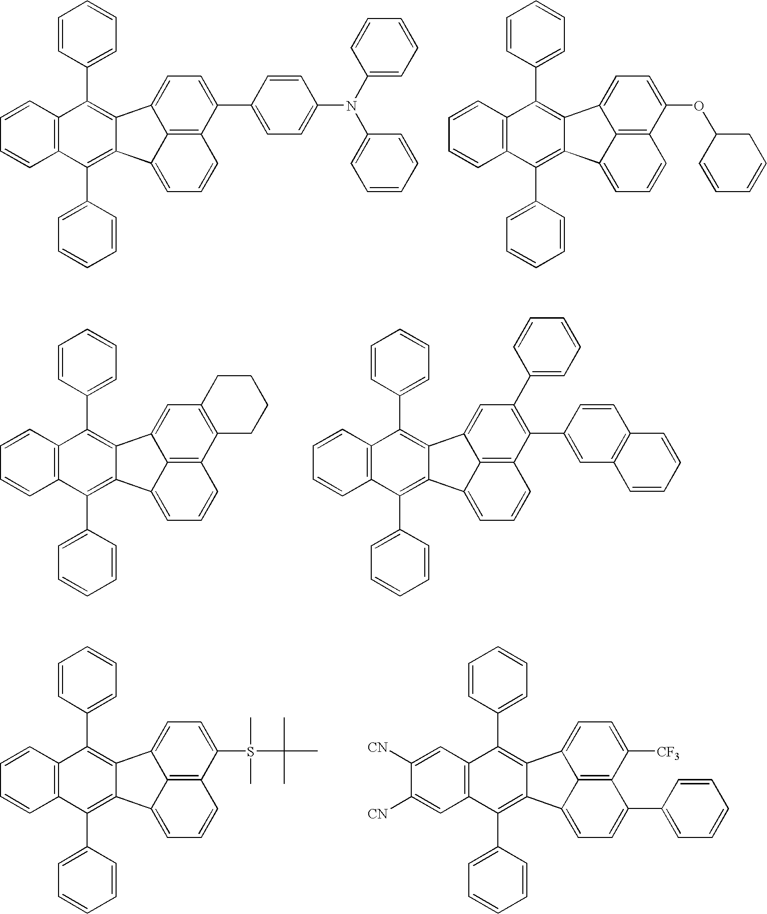

The host of the green emitting layer is preferably a compound represented by the following formula (1) or (2).

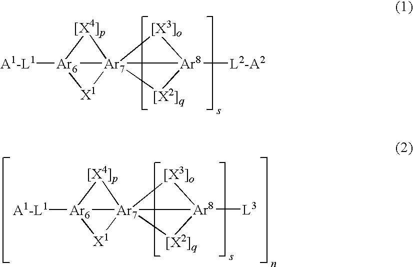

In the formulas (1) and (2), Ar⁶, Ar⁷ and Ar⁸ is independently a substituted or unsubstituted aromatic hydrocarbon group having 6 to 24 ring carbon atoms or a substituted or unsubstituted aromatic heterocyclic group having 3 to 24 ring atoms. Ar⁶, Ar⁷ and Ar⁸ may have one or a plurality of substituents Y, plural Ys may be the same or different, and Y is an alkyl group having 1 to 20 carbon atoms, a substituted or unsubstituted cycloalkyl group having 3 to 20 ring carbon atoms, an alkoxy group having 1 to 20 carbon atoms, an aralkyl group having 7 to 24 carbon atoms, a silyl group having 3 to 20 carbon atoms, a substituted or unsubstituted aromatic hydrocarbon group having 6 to 24 ring carbon atoms or a substituted or unsubstituted aromatic heterocyclic group having 3 to 24 ring atoms which links to Ar⁶, Ar⁷ or Ar⁸ via a carbon-carbon bond.

In the formulas (1) and (2), X¹, X², X³ and X⁴ are independently O, S, N—R¹ or CR²R³. o, p and q are 0 or 1, and s is 1, 2 or 3. R¹, R² and R³ are independently an alkyl group having 1 to 20 carbon atoms, a substituted or unsubstituted cycloalkyl group having 3 to 20 ring carbon atoms, an aralkyl group having 7 to 24 carbon atoms, a silyl group having 3 to 20 carbon atoms, a substituted or unsubstituted aromatic hydrocarbon group having 6 to 24 ring carbon atoms or a substituted or unsubstituted aromatic heterocyclic group having 3 to 24 ring atoms.

In the formulas (1) and (2), L¹ is a single bond, an alkylene group having 1 to 20 carbon atoms, a substituted or unsubstituted cycloalkylene group having 3 to 20 ring carbon atoms, a divalent silyl group having 2 to 20 carbon atoms, a substituted or unsubstituted divalent aromatic hydrocarbon group having 6 to 24 ring carbon atoms or a substituted or unsubstituted divalent aromatic heterocyclic group having 3 to 24 ring atoms which links to Ar⁶ via a carbon-carbon bond.

In the formula (1), L² is a single bond, an alkylene group having 1 to 20 carbon atoms, a substituted or unsubstituted cycloalkylene group having 3 to 20 ring carbon atoms, a divalent silyl group having 2 to 20 carbon atoms, a substituted or unsubstituted divalent aromatic hydrocarbon group having 6 to 24 ring carbon atoms or a substituted or unsubstituted divalent aromatic heterocyclic group having 3 to 24 ring atoms which links to Ar⁸ via a carbon-carbon bond.

In the formula (2), n is 2, 3 or 4, which forms a dimmer, a trimmer or a tetramer with L³ being a linkage group respectively.

In the formula (2), when n is 2, L³ is a single bond, an alkylene group having 1 to 20 carbon atoms, a substituted or unsubstituted cycloalkylene group having 3 to 20 ring carbon atoms, a divalent silyl group having 2 to 20 carbon atoms, a substituted or unsubstituted divalent aromatic hydrocarbon group having 6 to 24 ring carbon atoms or a substituted or unsubstituted divalent aromatic heterocyclic group having 3 to 24 ring atoms which links to Ar⁸ via a carbon-carbon bond. When n is 3, L³ is a trivalent alkane having 1 to 20 carbon atoms, a substituted or unsubstituted trivalent cycloalkane having 3 to 20 ring carbon atoms, a trivalent silyl group having 1 to 20 carbon atoms, a substituted or unsubstituted trivalent aromatic hydrocarbon group having 6 to 24 ring carbon atoms or a substituted or unsubstituted trivalent aromatic heterocyclic group having 3 to 24 ring atoms which links to Ar⁸ via a carbon-carbon bond. When n is 4, L³ is a tetravalent alkane having 1 to 20 carbon atoms, a substituted or unsubstituted tetravalent cycloalkane having 3 to 20 ring carbon atoms, a silicon atom, a substituted or unsubstituted tetravalent aromatic hydrocarbon group having 6 to 24 ring carbon atoms or a substituted or unsubstituted tetravalent aromatic heterocyclic group having 3 to 24 ring atoms which links to Ar⁸ via a carbon-carbon bond.

In the formulas (1) and (2), A¹ is a hydrogen atom, a substituted or unsubstituted cycloalkyl group having 3 to 20 ring carbon atoms, a silyl group having 3 to 20 carbon atoms, a substituted or unsubstituted aromatic hydrocarbon group having 6 to 24 ring carbon atoms or a substituted or unsubstituted aromatic heterocyclic ring group having 3 to 24 ring atoms which links to L¹ via a carbon-carbon bond.

In the formula (1), A² is a hydrogen atom, a substituted or unsubstituted cycloalkyl group having 3 to 20 ring carbon atoms, a silyl group having 3 to 20 carbon atoms, a substituted or unsubstituted aromatic hydrocarbon group having 6 to 24 ring carbon atom or a substituted or unsubstituted aromatic heterocyclic group having 3 to 24 ring atoms which links to L² via a carbon-carbon bond.

The host of the green emitting layer is preferably a compound represented by the following formula (3) or (4).

(Cz-)ₙA (3)

Cz(-A)ₘ (4)

wherein Cz is a substituted or unsubstituted arylcarbazolyl group or a carbazolylalkylene group and A is a group represented by the following formula. n and m are independently an integer of 1 to 3.

(M)ₚ-(L)_{q}-(M′)ᵣ

wherein M and M′ are independently a substituted or unsubstituted nitrogen-containing heteroaromatic ring having 2 to 40 carbon atoms and may be the same or different. L is a single bond, a substituted or unsubstituted arylene group having 6 to 30 carbon atoms, a substituted or unsubstituted cycloalkylene group having 5 to 30 carbon atoms or a substituted or unsubstituted heteroaromatic ring having 2 to 30 carbon atoms. p is an integer of 0 to 2, q is an integer of 1 to 2 and r is an integer of 0 to 2. p+r is 1 or more.

As the host of the green emitting layer, the following compounds can be used, for example.

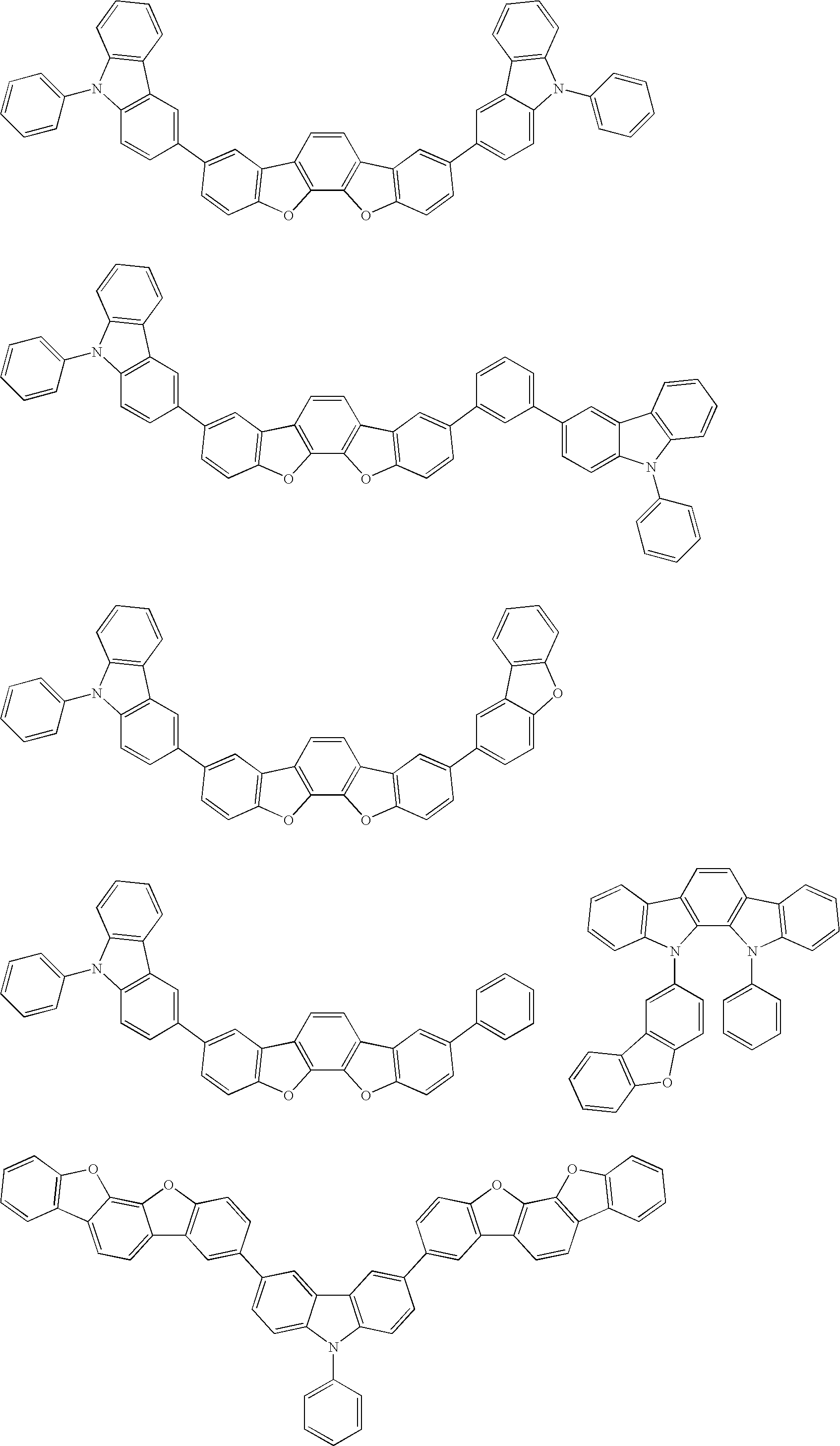

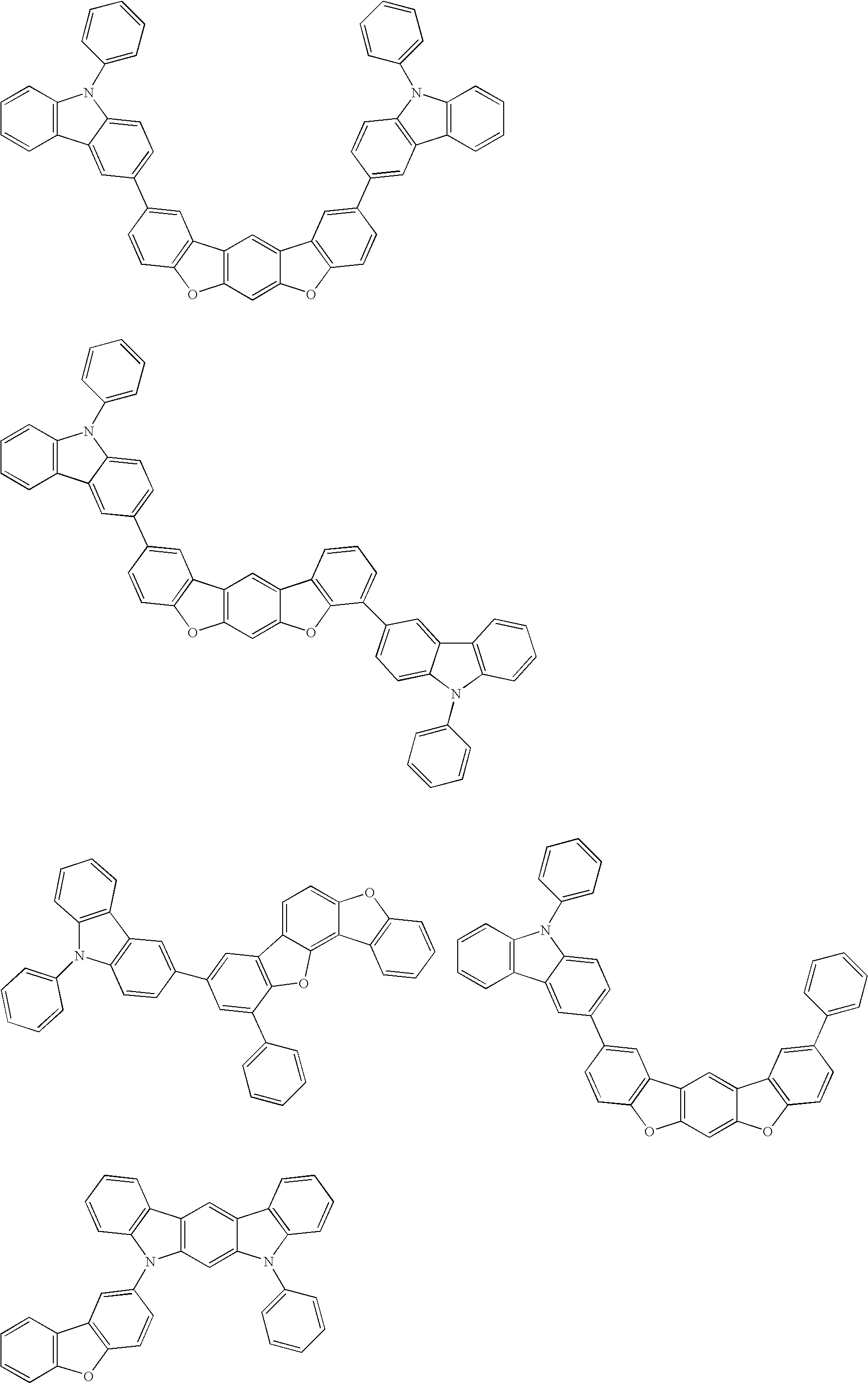

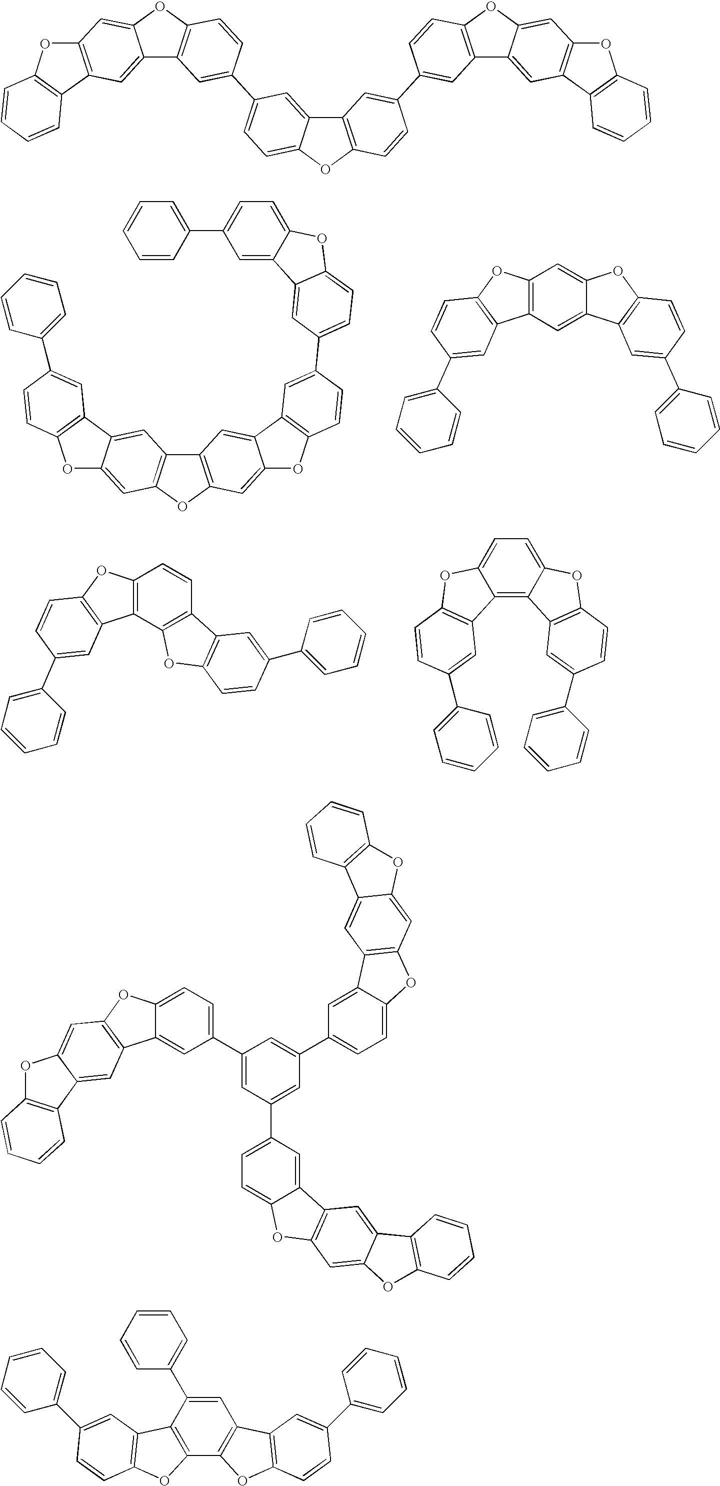

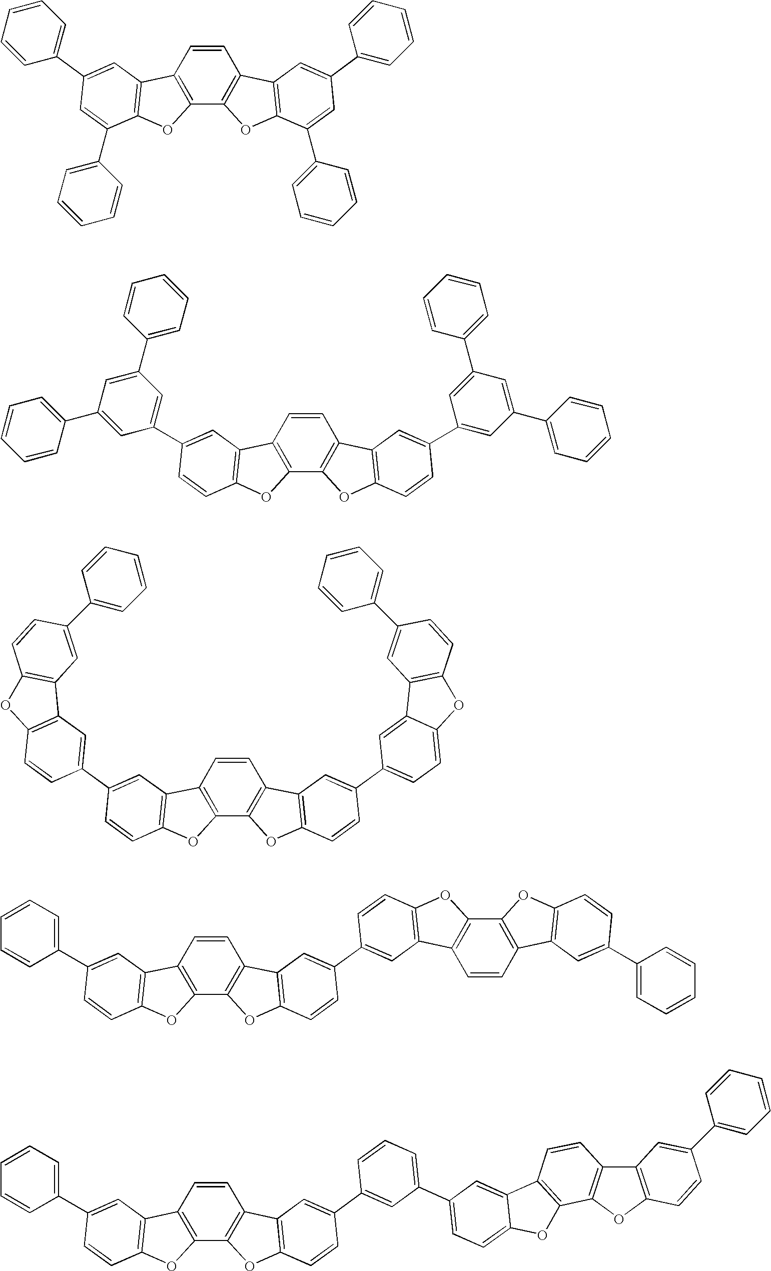

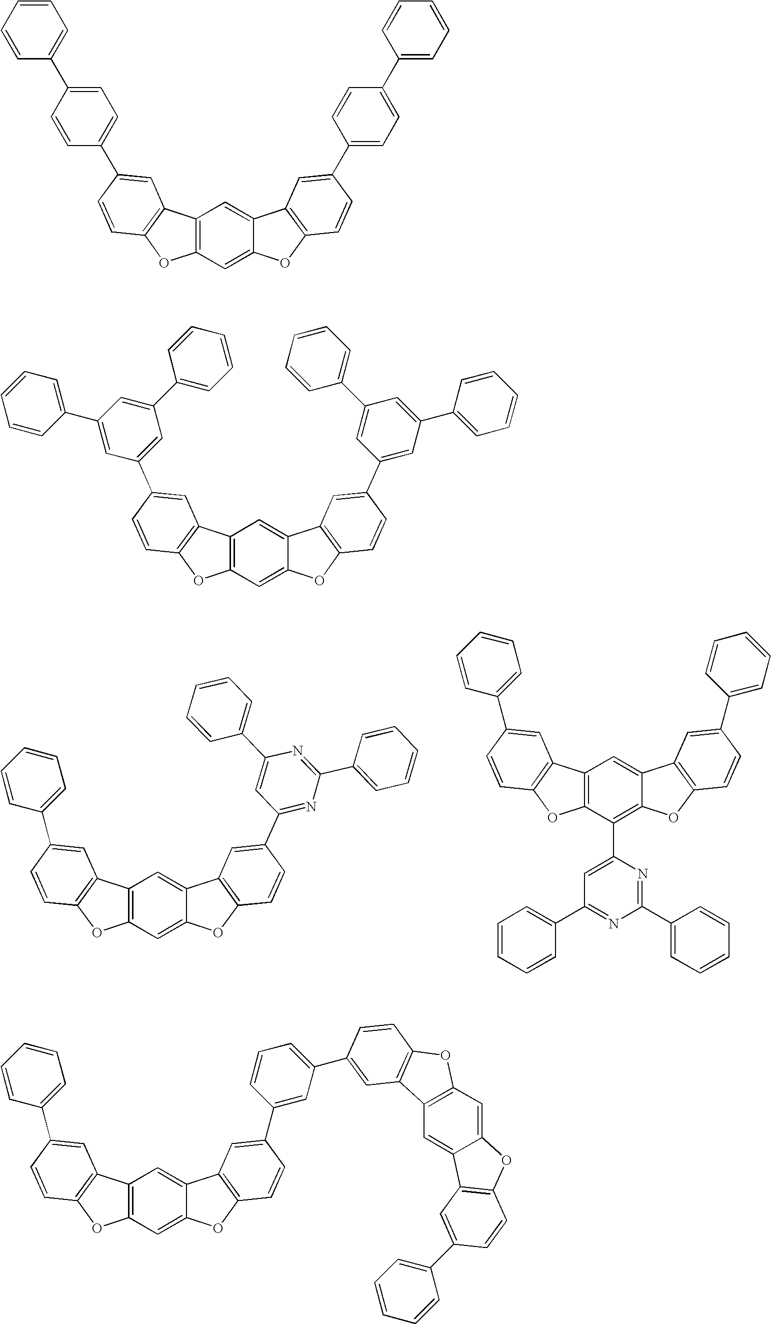

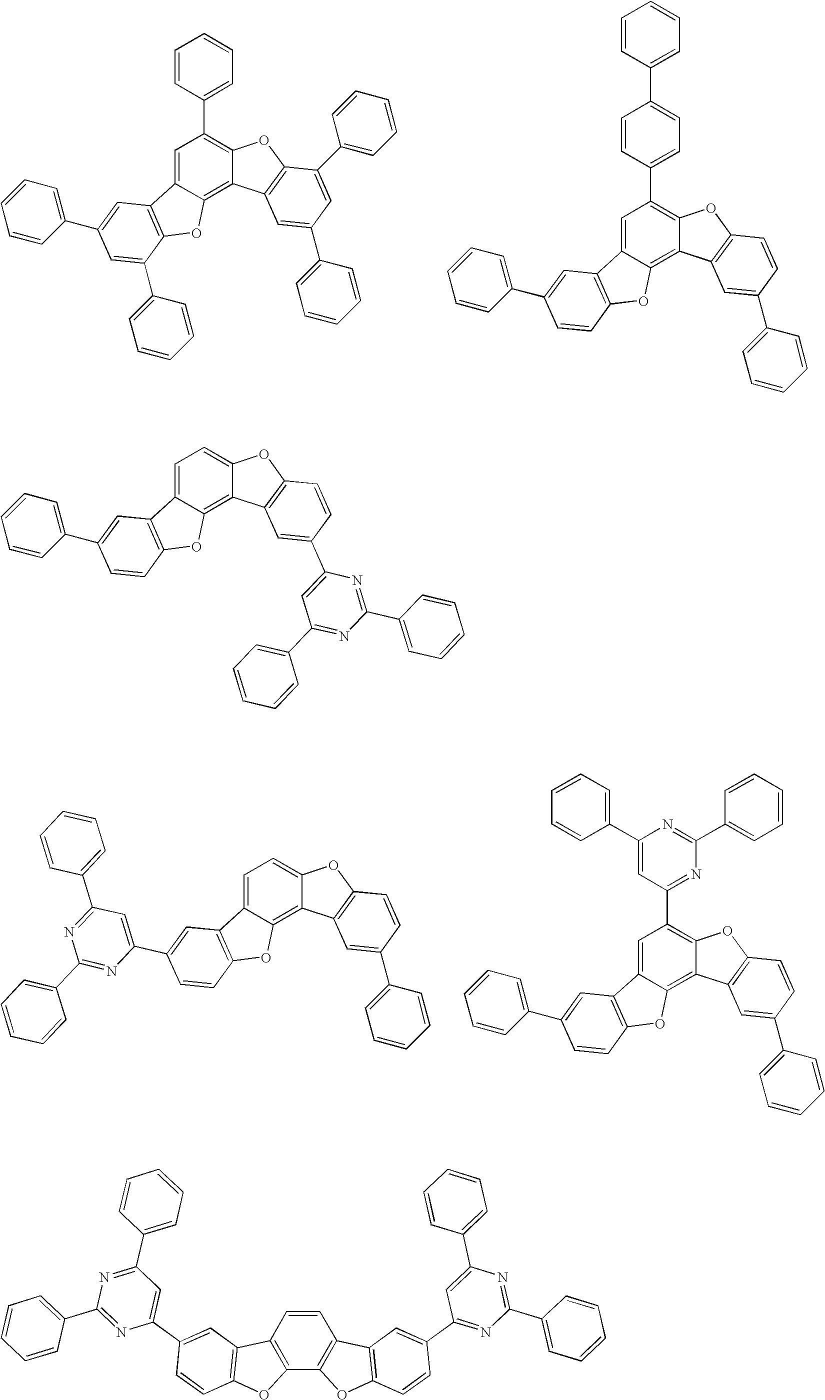

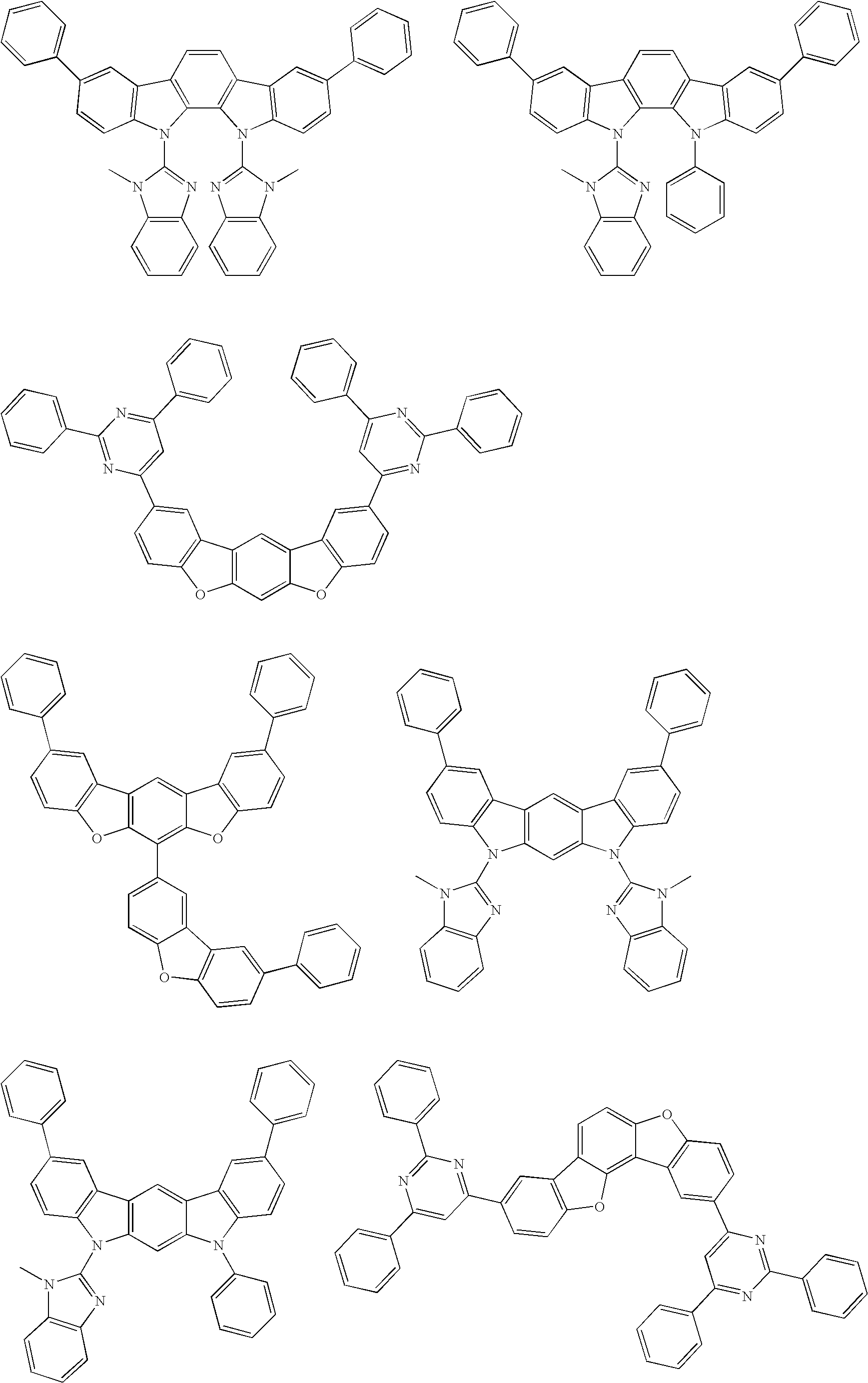

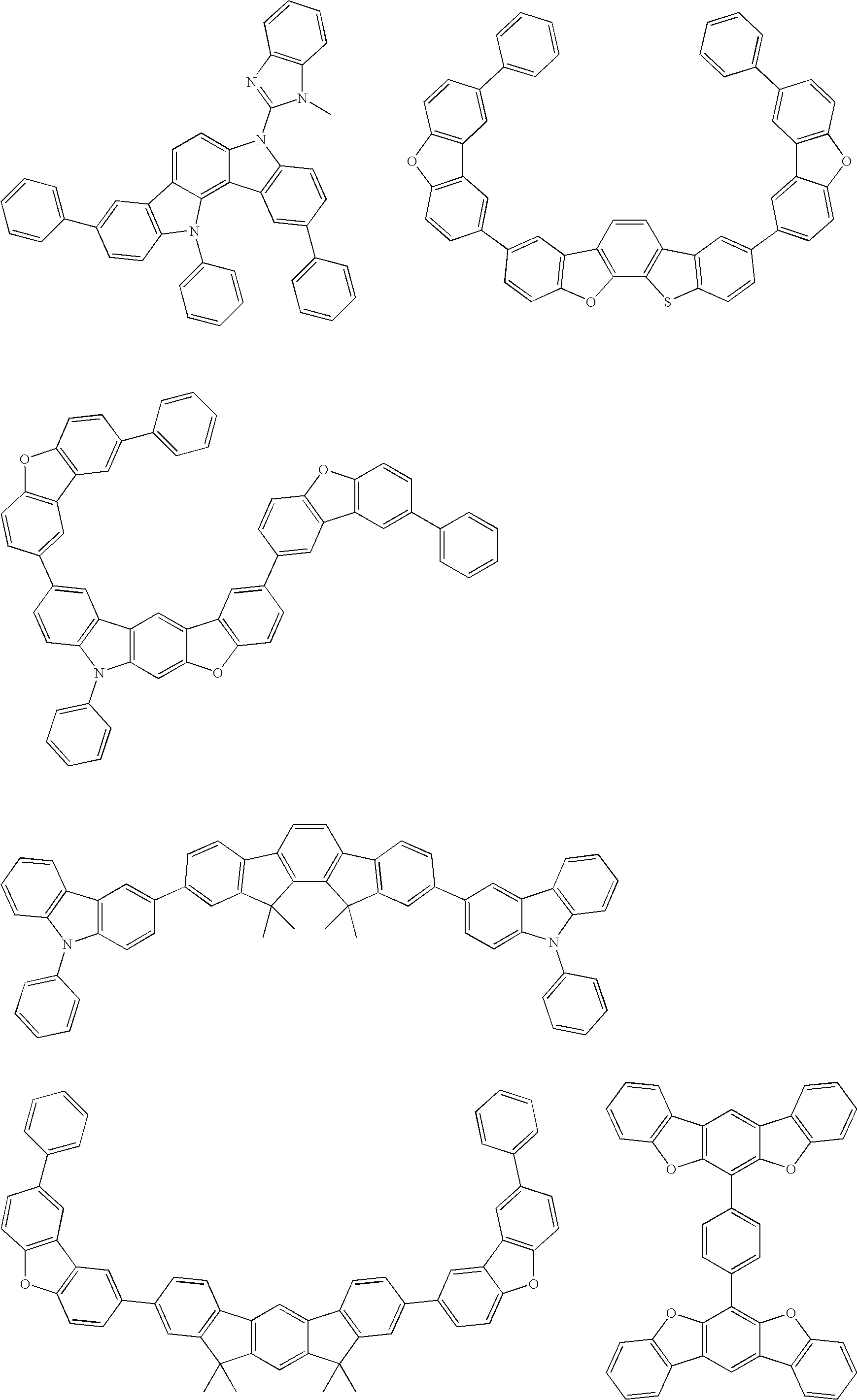

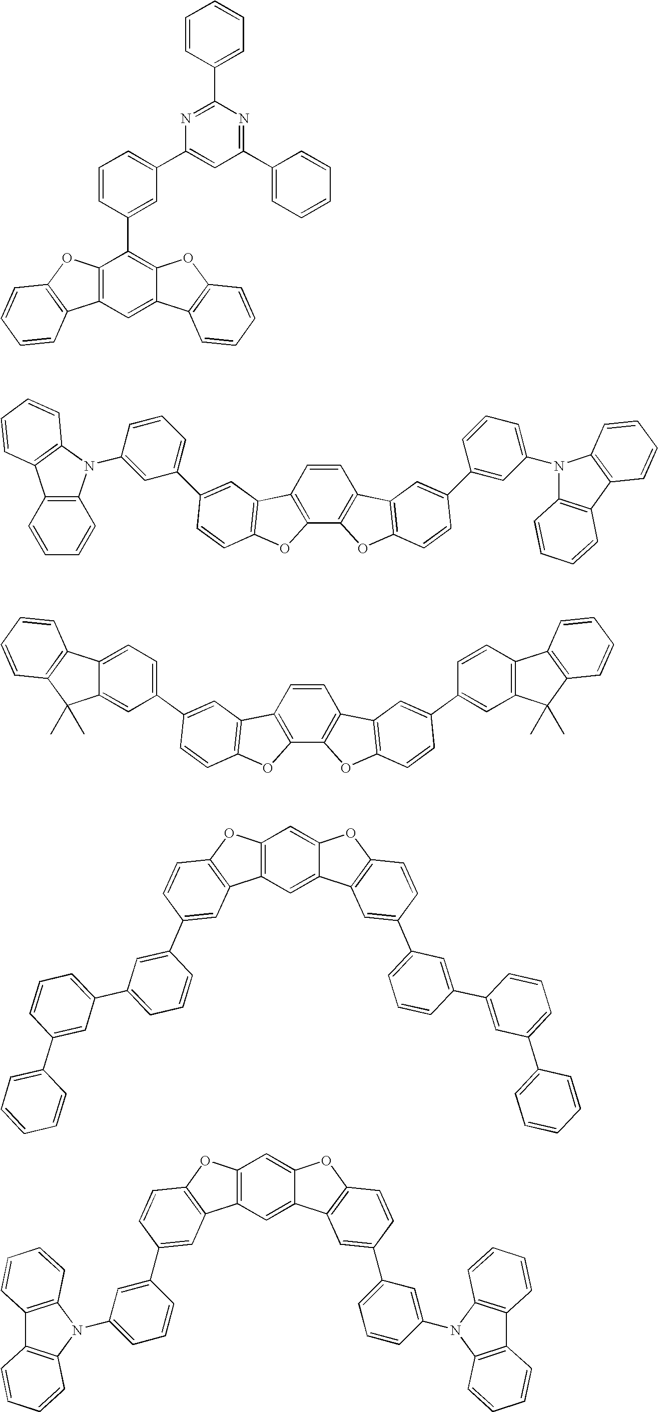

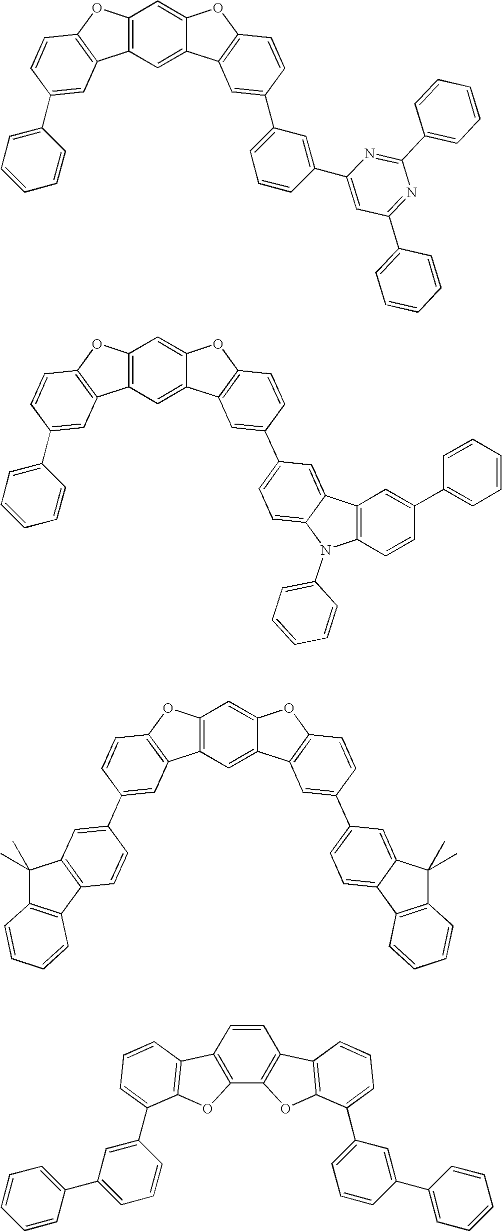

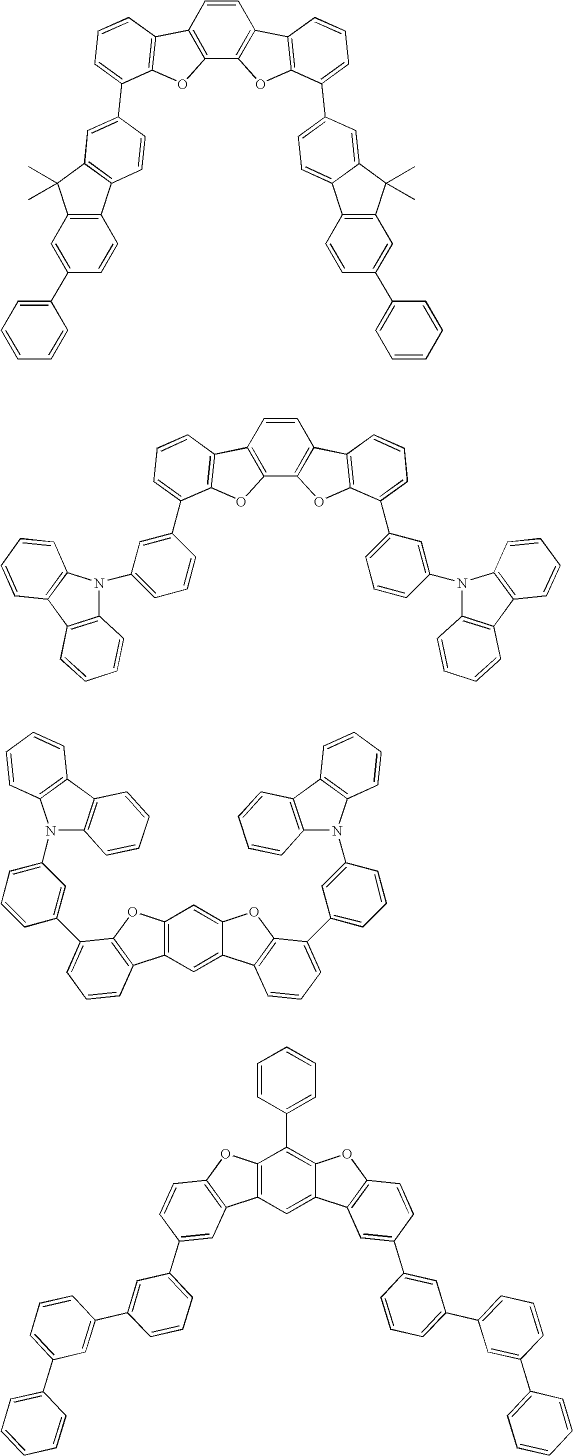

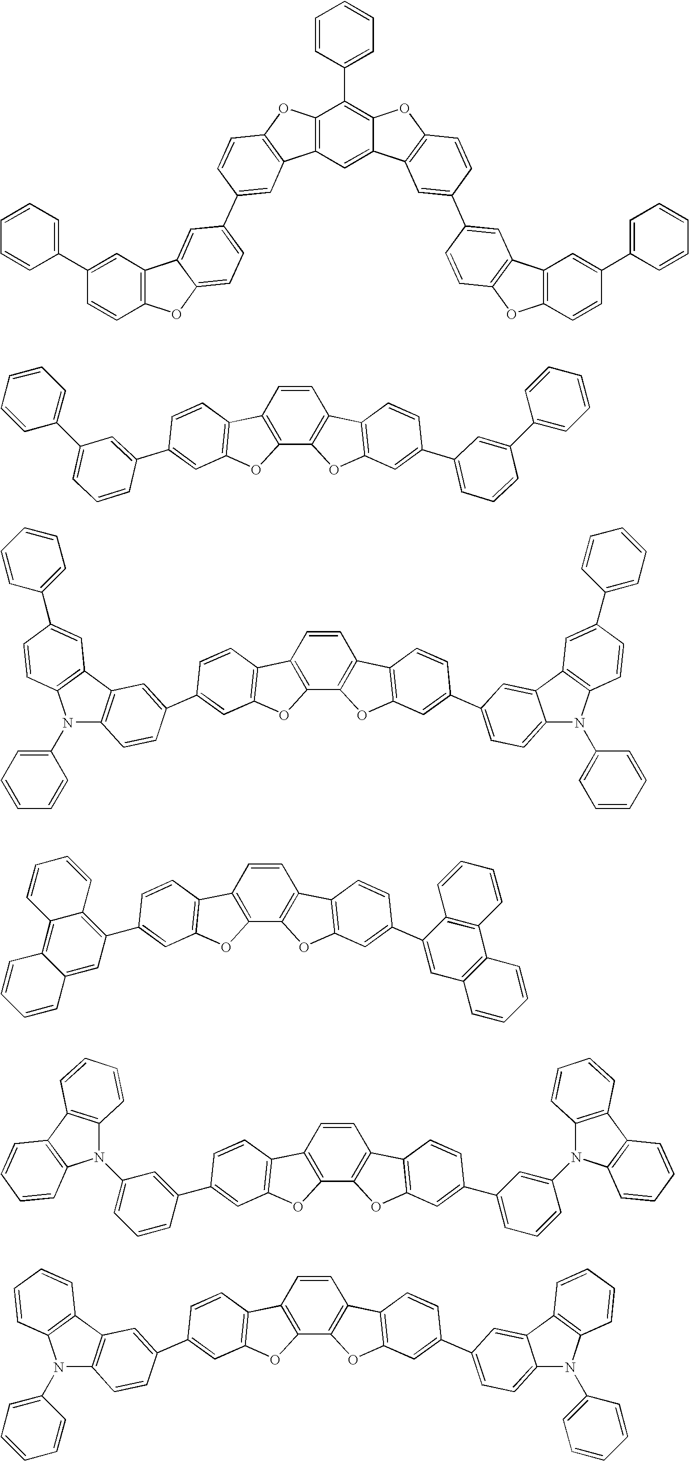

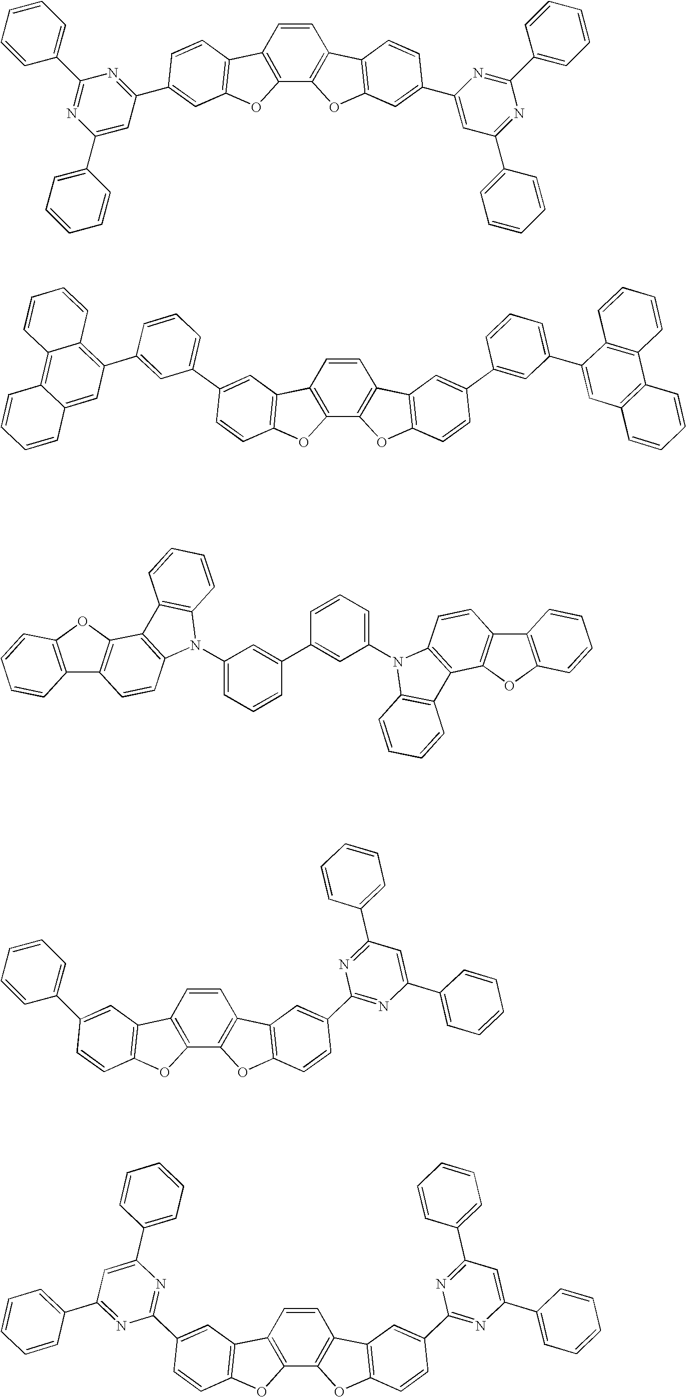

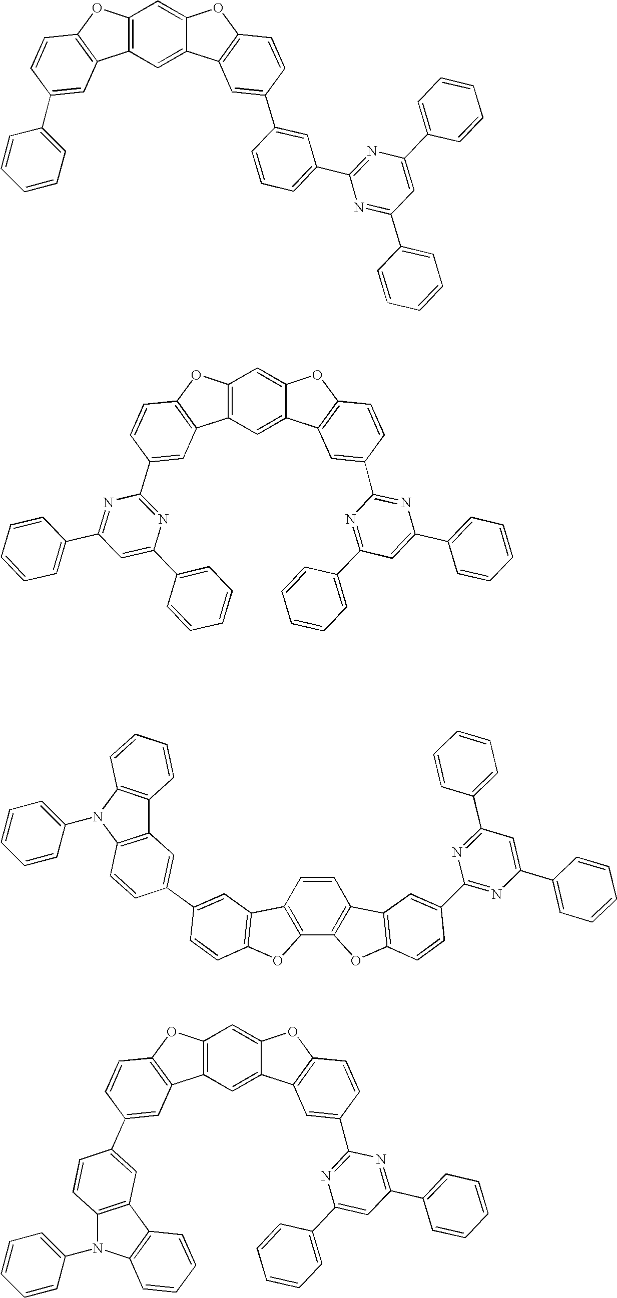

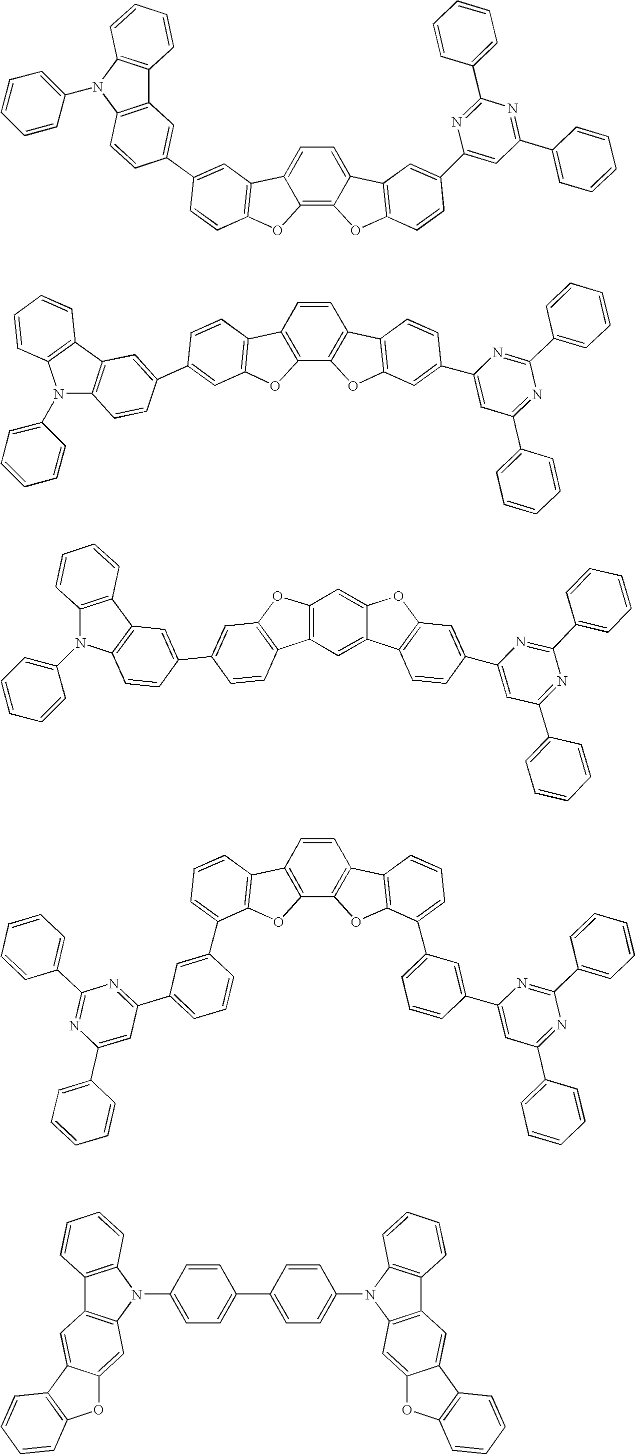

The phosphorescent dopant of the green emitting layer preferably contains a metal complex composed of a metal selected from the group consisting of Ir, Pt, Os, Au, Cu, Re and Ru, and a ligand.

Specific examples of such dopant materials include PQIr (iridium (III) bis(2-phenyl quinolyl-N,C^{2′}) acetylacetonate) and Ir(ppy)₃ (fac-tris(2-phenylpyridine) iridium) and the following compounds.

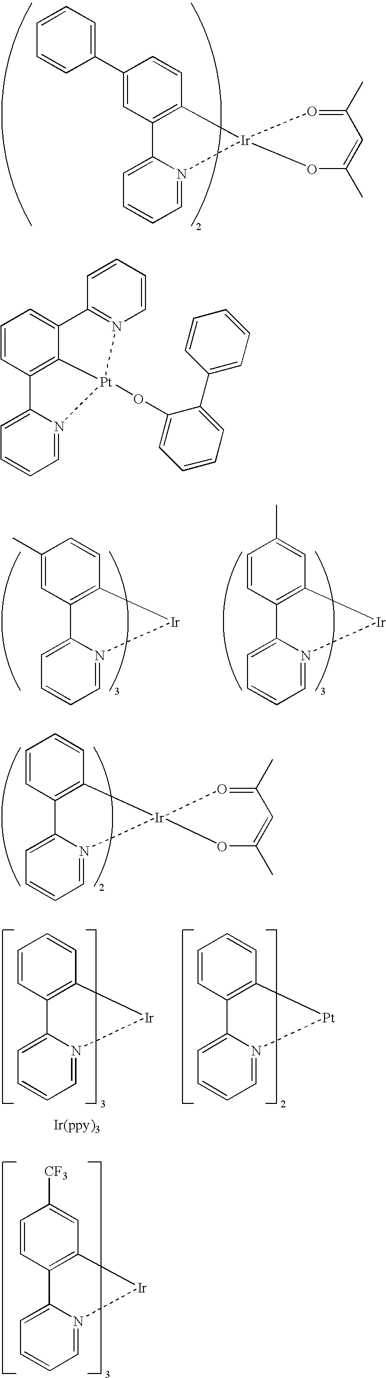

As the second dopant, a material usable as a host material of the green emitting layer can be used. Therefore, the examples of the second dopant of the green emitting layer are the same as those exemplified above as the host of the green emitting layer.

As the second dopant, it is preferable to select a dopant having an affinity Af_{gd2} of which the difference between the affinity Af_{gh} of the host GH is 0.4 eV or less. Further, it is desirable that the energy gap of the dopant PGD be smaller than the energy gap of the second dopant GD2.

The host of the red emitting layer is, for example, at least one compound selected from polycyclic fused aromatic compounds shown by the following formulas (A), (B) and (C).

Ra—Ar¹⁰¹—Rb (A)

Ra—Ar¹⁰¹—Ar¹⁰²—Rb (B)

Ra—Ar¹⁰¹—Ar¹⁰²—Ar¹⁰³—Rb (C)

wherein Ar¹⁰¹, Ar¹⁰², Ar¹⁰³, Ra and Rb are independently a substituted or unsubstituted benzene ring, or a polycyclic fused aromatic skeleton part selected from a substituted or unsubstituted naphthalene ring, a substituted or unsubstituted chrysene ring, a substituted or unsubstituted fluoranthene ring, a substituted or unsubstituted phenanthrene ring, a substituted or unsubstituted benzophenanthrene ring, a substituted or unsubstituted dibenzophenanthrene ring, a substituted or unsubstituted triphenylene ring, a substituted or unsubstituted benzo[a]triphenylene ring, a substituted or unsubstituted benzochrysene ring, a substituted or unsubstituted benzo[b]fluoranthene ring, and a substituted or unsubstituted picene ring; provided that Ar¹⁰¹, Ar¹⁰², Ar¹⁰³, Ra and Rb are not a substituted or unsubstituted benzene ring at the same time.

It is preferred that one or both of the Ra and Rb be a ring selected from a substituted or unsubstituted phenanthrene ring, a substituted or unsubstituted benzo[c]phenanthrene ring and a substituted or unsubstituted fluoranthene ring.

The above-mentioned polycyclic fused aromatic compound contains the polycyclic fused aromatic skeleton part as a group of divalent or more valences in its structure.

The polycyclic fused aromatic skeleton part may have a substituent, and the substituent is a substituted or unsubstituted aryl group or a substituted or unsubstituted heteroaryl group.

In addition, the substituent of the polycyclic fused aromatic compound dose not contain a carbazole skeleton, for example.

As the host of the red emitting layer, the following compounds can be used, for example.

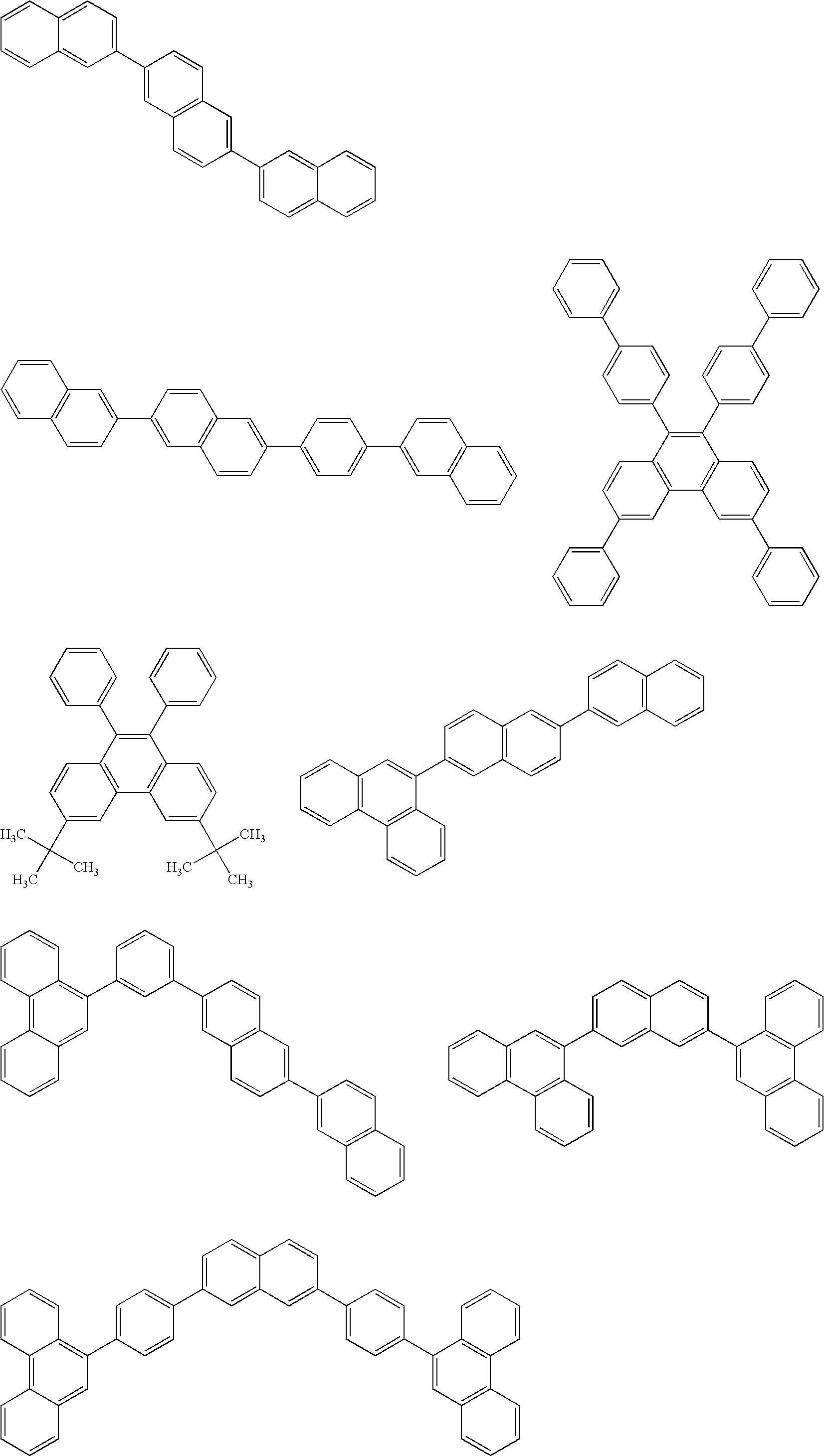

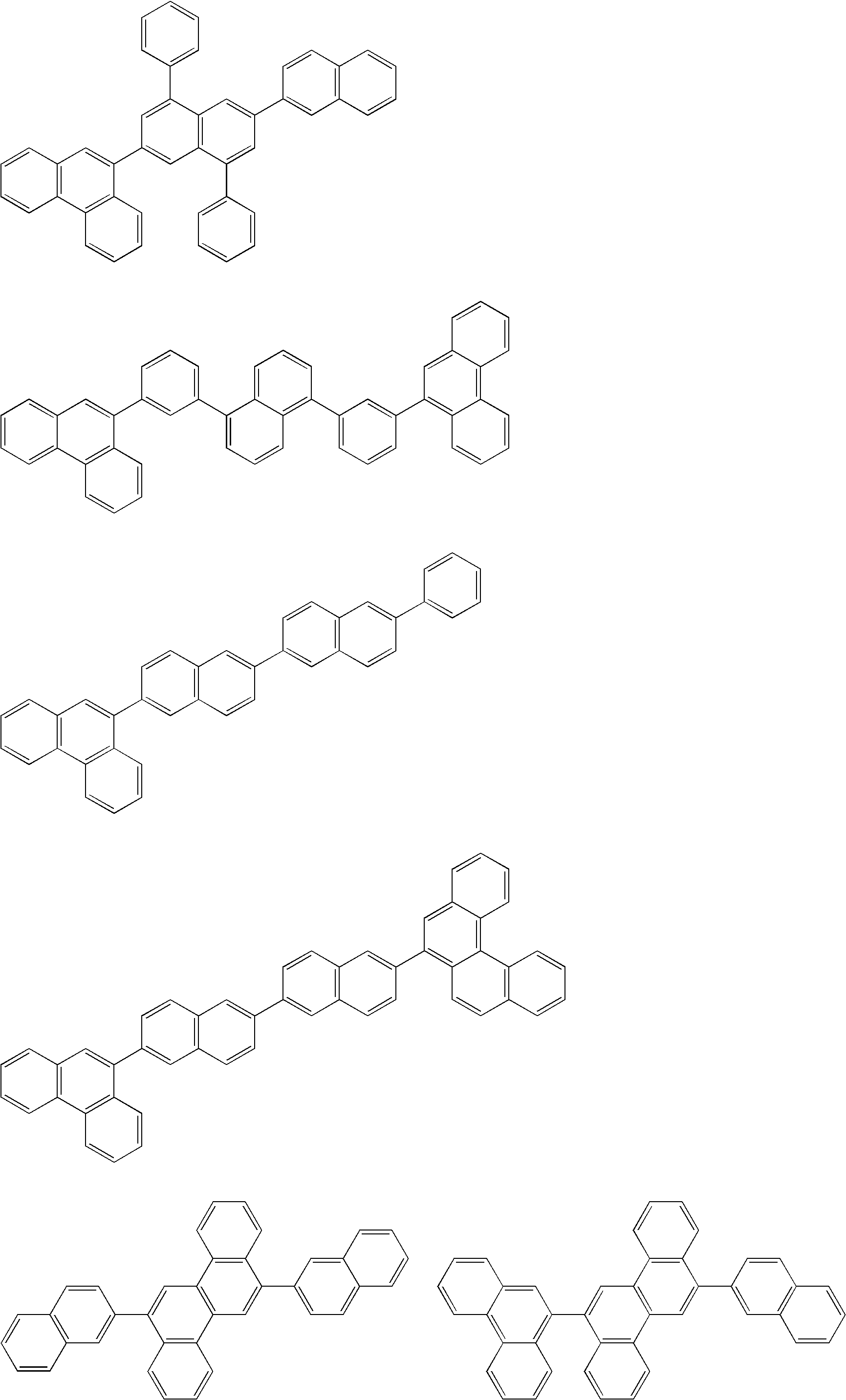

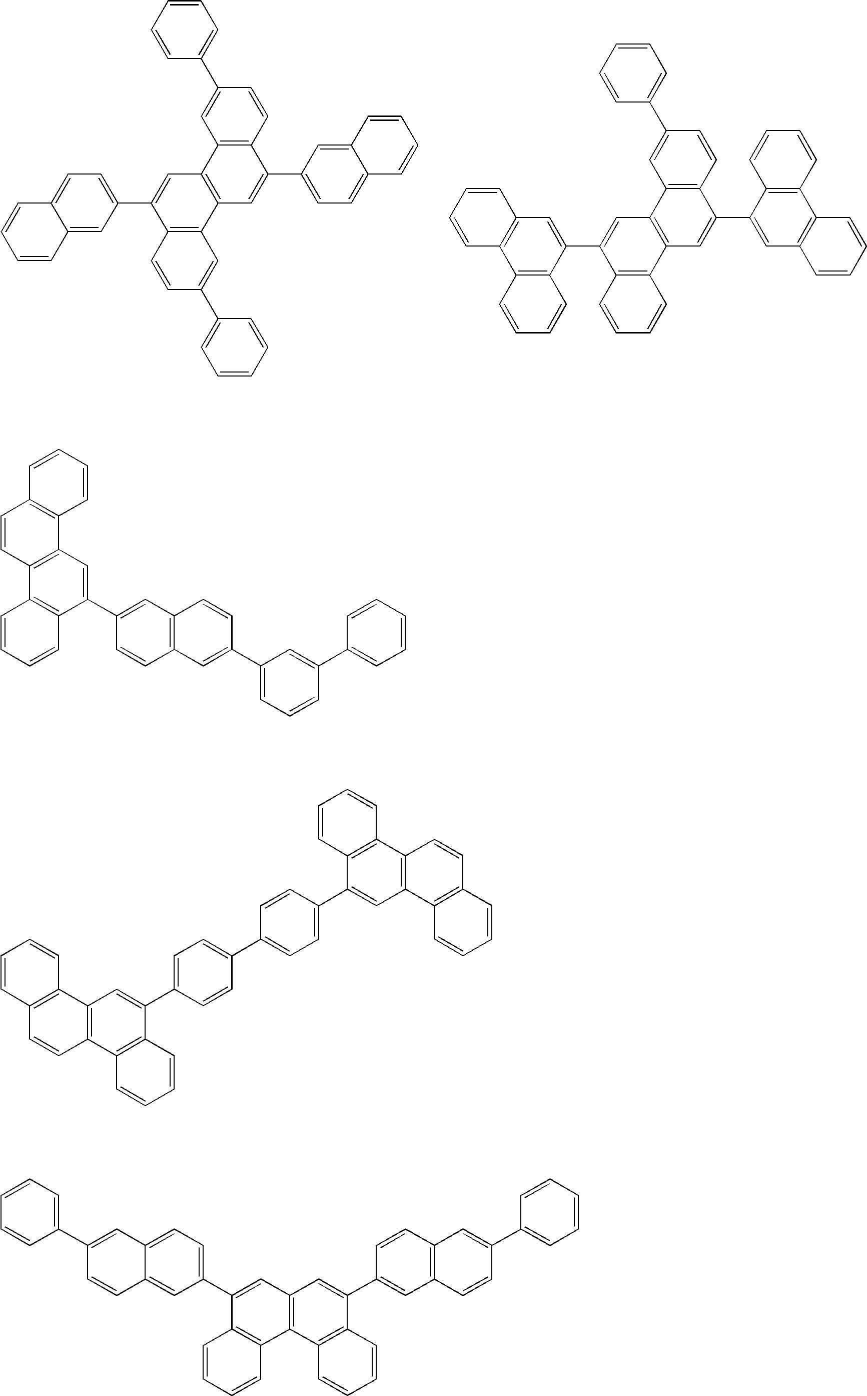

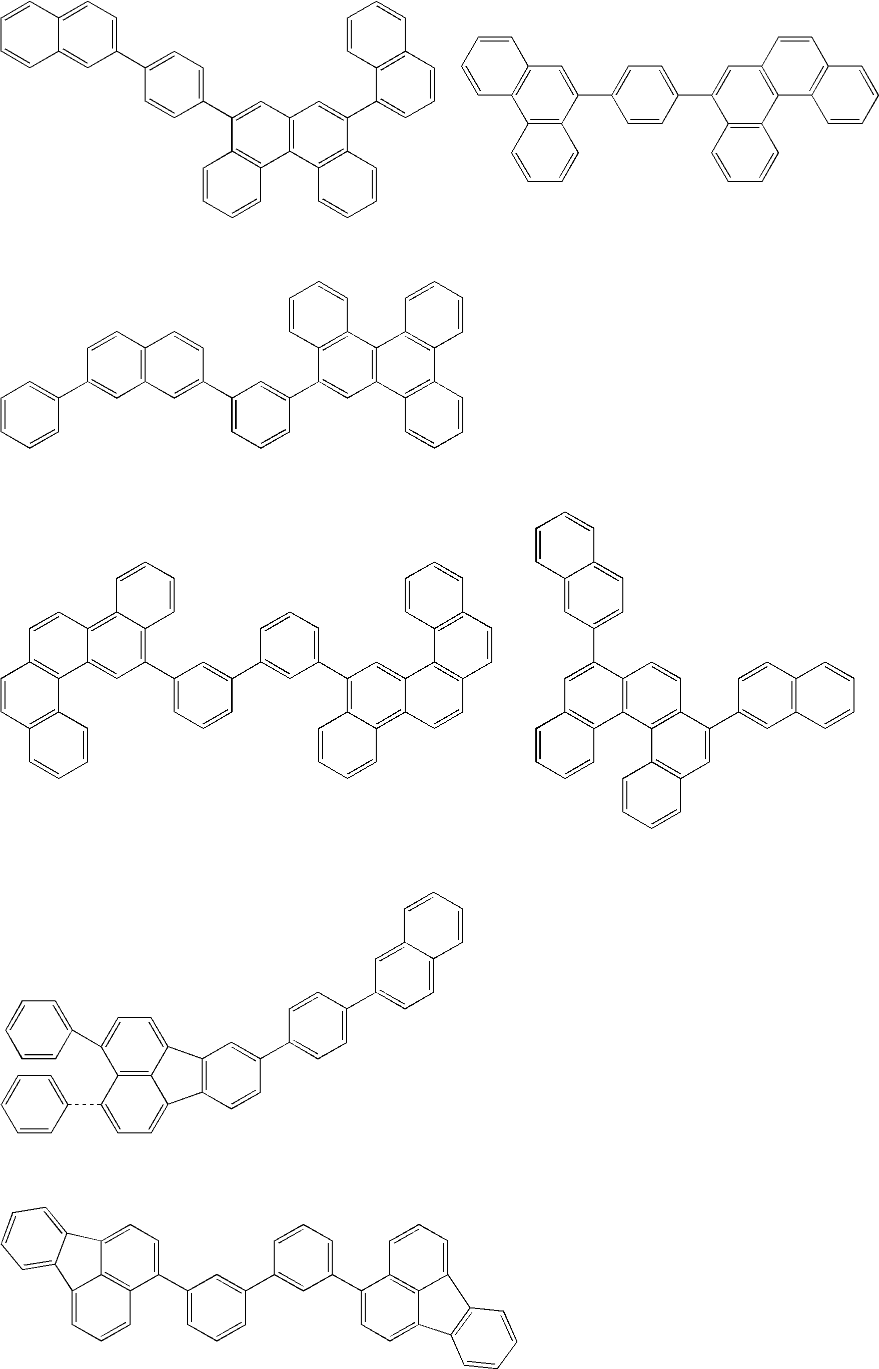

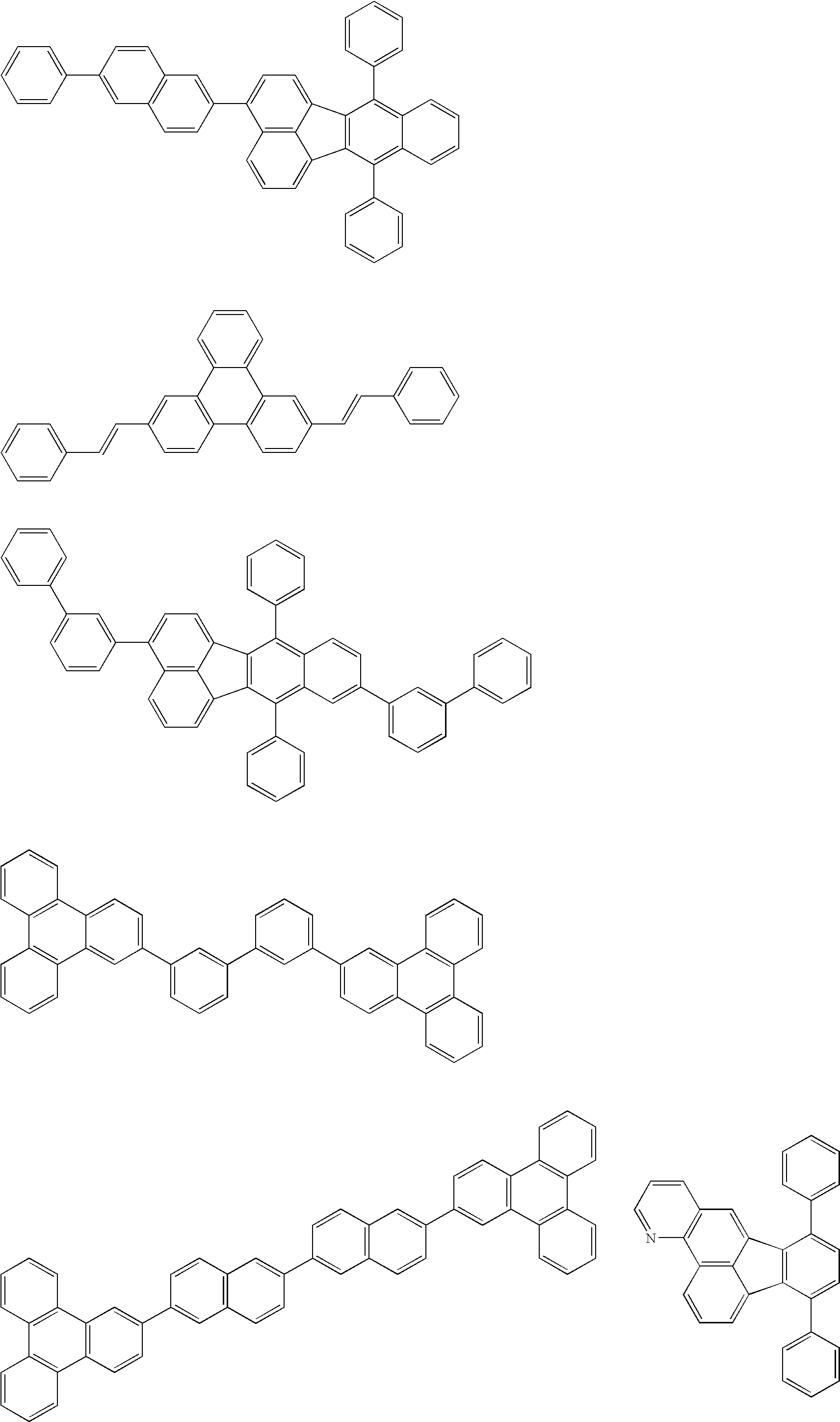

The phosphorescent dopant of the red emitting layer desirably contains a metal complex composed of a metal selected from the group consisting of Ir, Pt, Os, Au, Cu, Re and Ru, and a ligand. Examples thereof include the following:

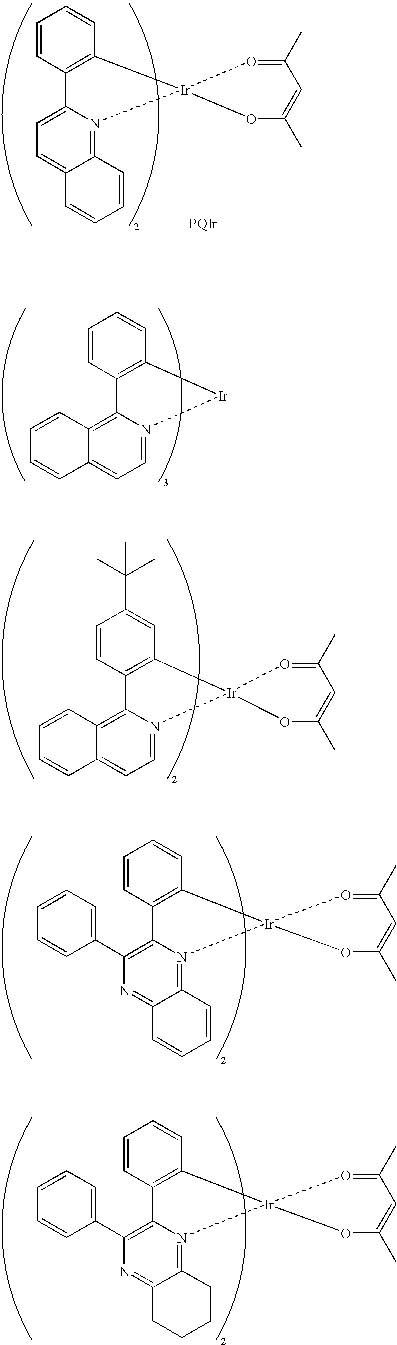

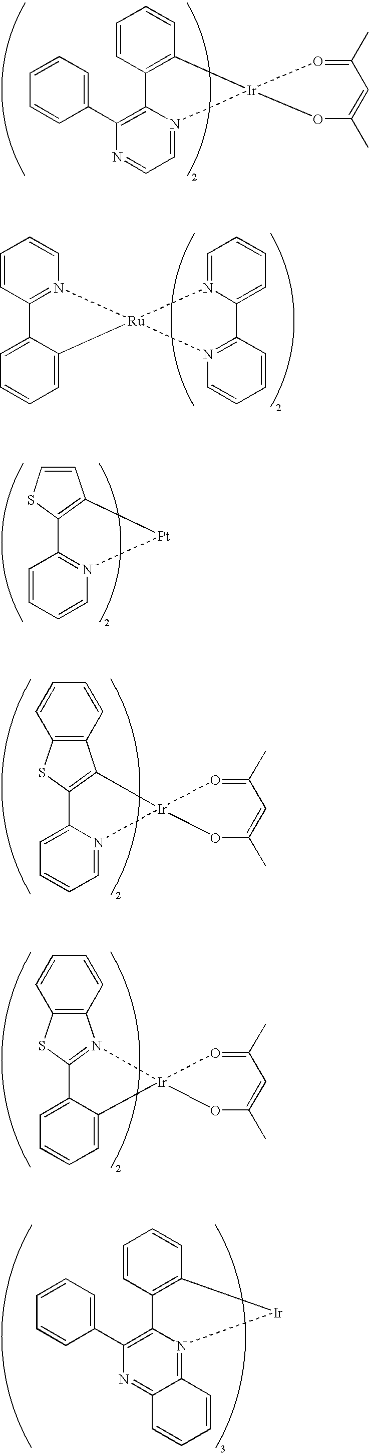

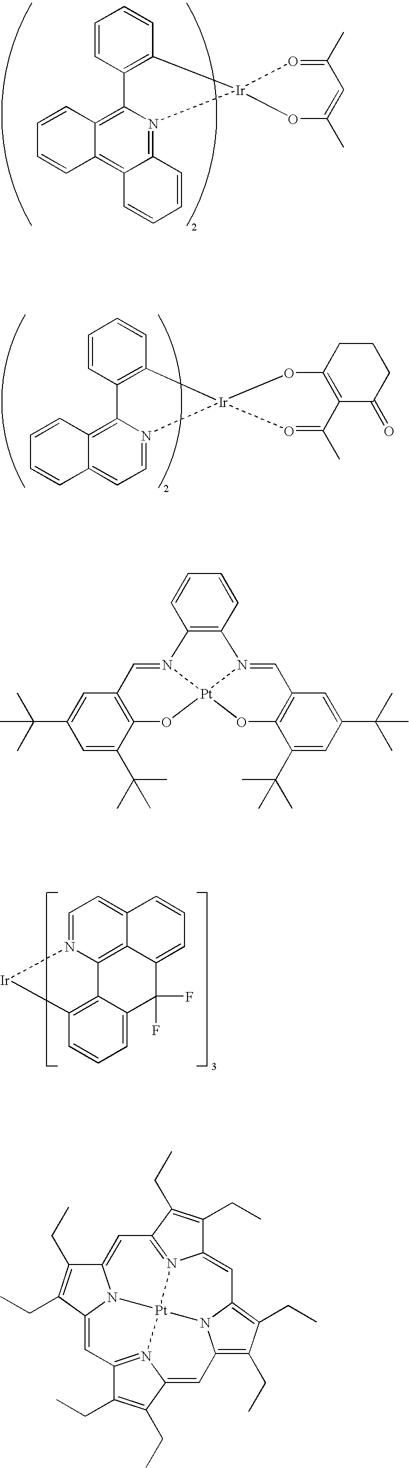

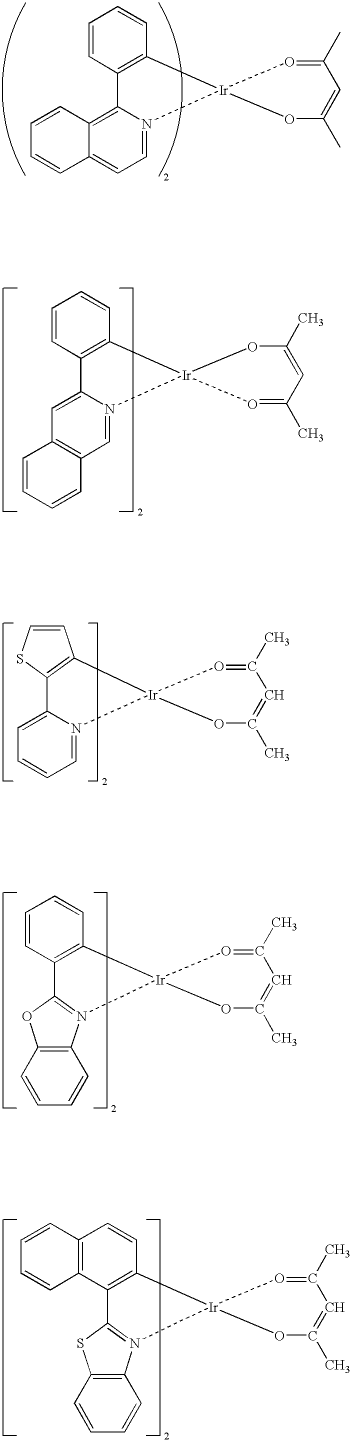

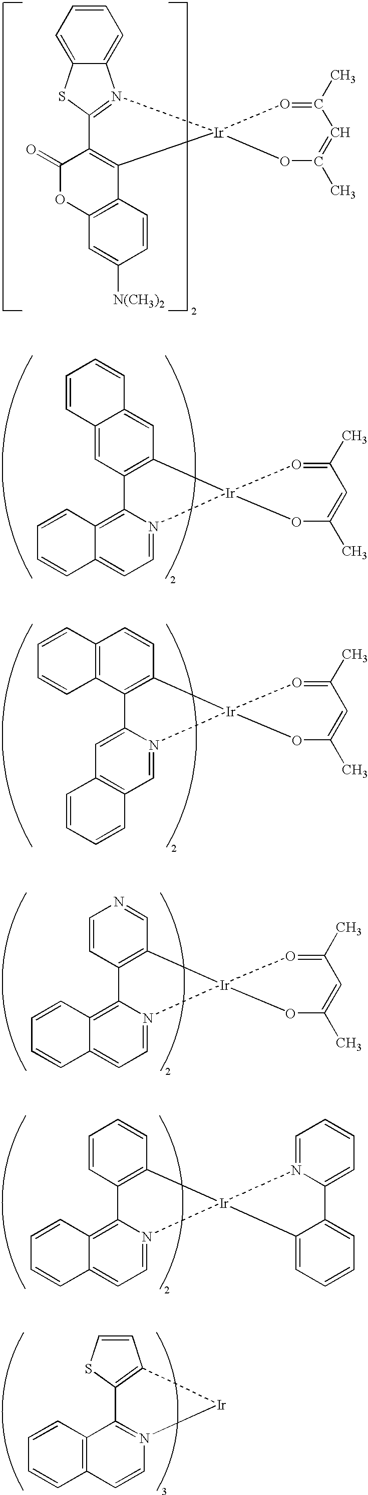

The holes which do not contribute to recombination in the emitting layer may be injected to the electron-transporting layer. Therefore, it is preferred that the material used for the electron-transporting layer be improved in resistance to oxidation.

As for the specific examples of the materials improved in resistance to oxidation, aromatic hydrocarbon compounds, in particular, polycyclic fused aromatic ring compounds are preferable. An organic complex such as BAlq is poor in resistance to oxidation since it has polarity within a molecule.

The electron-transporting region is composed of a stacked structure of one or more electron-transporting layers, or a stacked structure of one or more electron-transporting layers and one or more electron-injecting layers.

The following may be considered as the structure between the emitting layer and the cathode.

Emitting layer/Electron-transporting layer/Cathode

Emitting layer/Electron-transporting layer/Electron-injecting layer/Cathode

Emitting layer/Electron-transporting layer/Electron-transporting layer/Electron-injecting layer/Cathode

The electron-transporting region is provided in such a manner that it is common to the green emitting layer, the blue emitting layer and the red emitting layer. Therefore, the triplet energy of the material constituting the electron-transporting layer adjacent to the emitting layer may be larger than the triplet energy of the host of the blue emitting layer and the difference between the affinity of the host of the green emitting layer and the affinity of the material constituting the electron-transporting layer adjacent to the emitting layer may be 0.4 eV or less.

It is preferred that the difference between the affinity of the host of the red emitting layer and the affinity of the material constituting the electron-transporting layer adjacent to the emitting layer be 0.4 eV or less.

It is preferred that the difference between the affinity of the host of the blue emitting layer and the affinity of the material constituting the electron-transporting layer adjacent to the emitting layer be 0.4 eV or less.

Further, in respect of injection properties of electrons to the emitting layer, it is preferred that the following relationship be satisfied.

−0.3 eV<(affinity of the electron-transporting layer adjacent to the emitting layer)−(affinity of the host of the green emitting layer)<0.4

It is further preferred that the following relationship be satisfied.

−0.2 eV<(affinity of the electron-transporting layer adjacent to the emitting layer)−(affinity of the host of the green emitting layer)<0.4

In respect of the above-mentioned values of the affinity and the triplet energy, as the specific examples of the material constituting the electron-transporting layer, one or more compounds selected from the group consisting of the polycyclic fused aromatic compounds shown by the formulas (10), (20) and (30) given below.
(10) A material represented by the following formula (11) or a dimer thereof represented by the following formula (12)

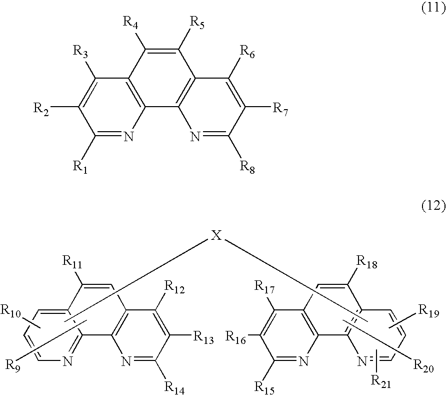

wherein R¹ to R²¹ are a hydrogen atom, a substituted or unsubstituted alkyl group, a substituted or unsubstituted aryl group, a substituted or unsubstituted amino group, a halogen atom, a nitro group, a cyano group or a hydroxyl group. In the above formula, X is a substituted or unsubstituted alkylene group or a substituted or unsubstituted arylene group.
(20) A material represented by the following formula

HAr-L¹-Ar¹—Ar²

wherein HAr is a substituted or unsubstituted nitrogen-containing heterocycle having 3 to 40 carbon atoms; L¹ is a single bond, a substituted or unsubstituted arylene group having 6 to 40 carbon atoms or a substituted or unsubstituted heteroarylene group having 3 to 40 carbon atoms; Ar¹ is a substituted or unsubstituted divalent aromatic hydrocarbon group having 6 to 40 carbon atoms; and Ar² is a substituted or unsubstituted aryl group having 6 to 40 carbon atoms or a substituted or unsubstituted heteroaryl group having 3 to 40 carbon atoms.
(30) Fused polycyclic aromatic compounds represented by the above formulas (A), (B) and (C)

When the compound of formula (20) is used, Ar¹ is preferably an anthracenylene group in view of the affinity of an emitting layer host material. When the compound of formula (10) is used, the compound of formula (12) is preferable in view of heat resistance.

As specific examples of the electron-transporting layer and the electron-injecting layer being not adjacent to the emitting layer, a metal complex of 8-hydroxyquinolinone or a derivative thereof, an oxadiazole derivative or a nitrogen-containing heterocycle derivative is preferable. Specific examples of the metal complex of 8-hydroxyquinolinone or a derivative thereof include a metal chelate oxinoid compound containing a chelate of an oxine (generally 8-quinolinol or 8-hydroxyquinone). Tris(8-quinolinol)aluminum can be used, for example.

Examples of the nitrogen-containing heterocycle derivative include a compound represented by the above formula (20).

It is preferred that the material for the electron-transporting layer have an electron mobility of 10⁻⁶ cm²/Vs or more in an electric field intensity of 0.04 to 0.5 MV/cm. An electron mobility of 10⁻⁴ cm²/Vs or more is further desirable.

As the method for measuring the electron mobility of an organic material, several methods including the Time of Flight method are known. In the invention, however, the electron mobility is determined by the impedance spectroscopy.

An explanation is made on the measurement of the mobility by the impedance spectroscopy. A blocking layer material with a thickness of preferably about 100 nm to 200 nm is held between the anode and the cathode. While applying a bias DC voltage, a small alternate voltage of 100 mV or less is applied, and the value of an alternate current (the absolute value and the phase) which flows at this time is measured. This measurement is performed while changing the frequency of the alternate voltage, and complex impedance (Z) is calculated from a current value and a voltage value. Dependency of the imaginary part (ImM) of the modulus M=iωZ (i: imaginary unit ω: angular frequency) on the frequency is obtained. The inverse of a frequency at which the ImM becomes the maximum is defined as the response time of electrons carried in the blocking layer. The electron mobility is calculated according to the following formula:

Electron mobility=(film thickness of the material for forming the blocking layer)²/(response time·voltage)

Specific examples of a material of which the electron mobility is 10⁻⁶ cm²/Vs or more in an electric field intensity of 0.04 to 0.5 MV/cm include a material having a fluoranthene derivative in the skeleton part of a polycyclic aromatic compound.

As the electron-transporting region, a stacked structure of the above-mentioned electron-transporting material and an alkali metal compound or a material obtained by adding a donor represented by an alkali metal or the like to a material constituting the electron-transporting material may be used.

As the donor, at least one selected from the group consisting of a donor metal, a donor metal compound and a donor metal complex can be used.

As the alkaline metal compound, a halide or an oxide of an alkali metal can be given as a preferable example. A fluoride of an alkali metal is further preferable. For example, LiF can be given as a preferable example.

The donor metal is referred to as a metal having a work function of 3.8 eV or less. Preferred examples thereof include an alkali metal, an alkaline earth metal and a rare earth metal. More preferably, the donor metal is Cs, Li, Na, Sr, K, Mg, Ca, Ba, Yb, Eu and Ce.

The donor metal compound means a compound which contains the above-mentioned donor metal. Preferably, the donor metal compound is a compound containing an alkali metal, an alkaline earth metal or a rare earth metal. More preferably, the donor metal compound is a halide, an oxide, a carbonate or a borate of these metals. For example, the donor metal compound is a compound shown by MOₓ (wherein M is a donor metal, and x is 0.5 to 1.5), MFₓ (x is 1 to 3), or M(CO₃)ₓ (wherein x is 0.5 to 1.5).

The donor metal complex is a complex of the above-mentioned donor metal. Preferably, the donor metal complex is an organic metal complex of an alkali metal, an alkaline earth metal or a rare earth metal. Preferably, the donor metal complex is an organic metal complex shown by the following formula (I):

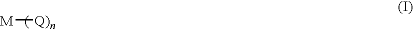

wherein M is a donor metal, Q is a ligand, preferably a carboxylic acid derivative, a diketone derivative or a quinoline derivative, and n is an integer of 1 to 4.

Specific examples of the donor metal complex include a tungsten paddlewheel as stated in JP-A-2005-72012. In addition, a phthalocyanine compound or the like in which the central metal is an alkali metal or an alkaline earth metal, which is stated in JP-A-H11-345687, can be used as the donor metal complex, for example.

The above-mentioned donor may be used either singly or in combination of two or more.

It is preferred that the relationship shown by the affinity Ae of the electron-injecting layer−the affinity Ab of the electron transporting layer<0.2 eV be satisfied. If this relationship is not satisfied, injection of electrons from the electron-injecting layer to the electron-transporting layer is deteriorated. As a result, an increase in driving voltage may occur due to the accumulation of electrons within the electron-transporting region, and energy quenching may occur due to collision of the accumulated electrons and triplet excitons.

As for the members used in the invention, such as the substrate, the anode, the cathode, the hole-injecting layer, the hole-transporting layer or the like, known members stated in PCT/JP2009/053247, PCT/JP2008/073180, U.S. patent application Ser. No. 12/376,326, U.S. patent application Ser. No. 11/766,281, U.S. patent application Ser. No. 12/280,364 or the like can be appropriately selected and used.

### Examples

Materials used in Examples and Comparative Examples and the properties thereof are shown below.

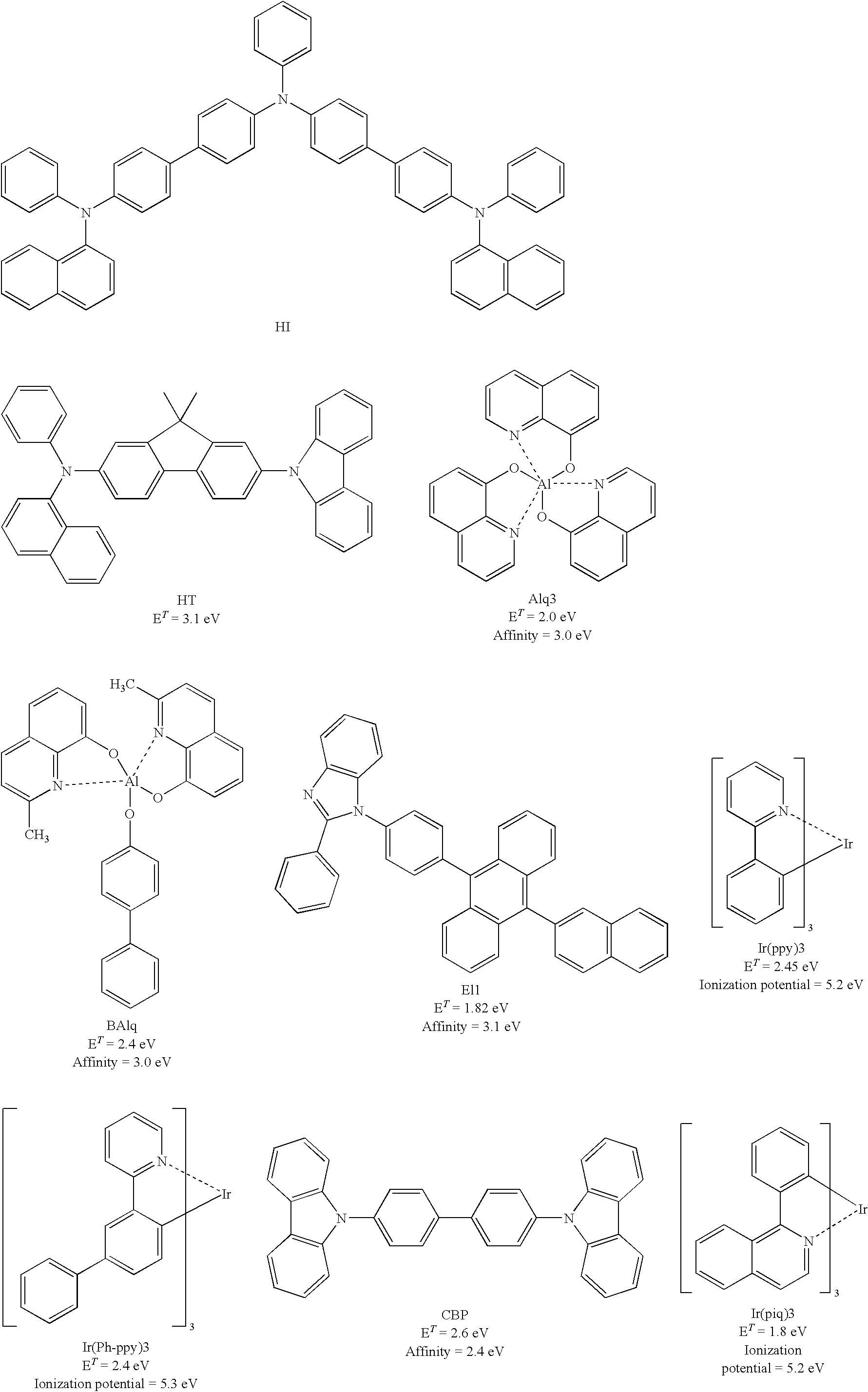

| | | E^{T} (eV) | Affinity (eV) |
|---|---|---|---|
| RH_1 | 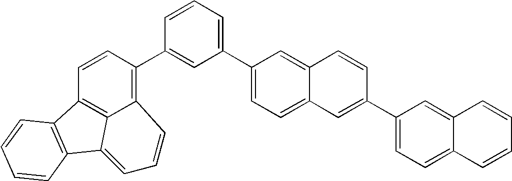 | 2.3 | 3.0 |
| RH_2 | 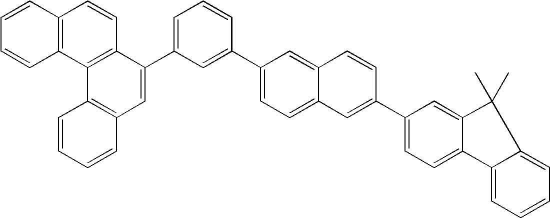 | 2.3 | 2.7 |
| RH_3 | 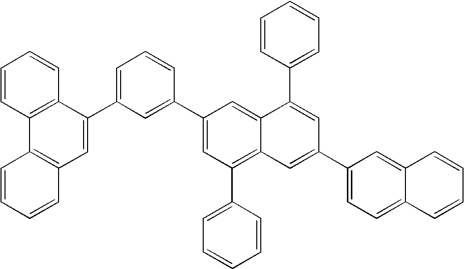 | 2.4 | 2.7 |
| RH_4 | 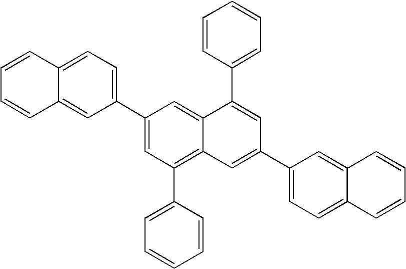 | 2.4 | 2.7 |
| RH_5 | 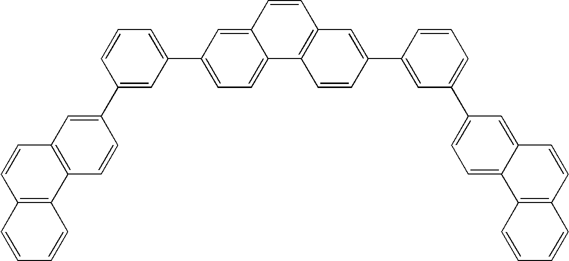 | 2.4 | 2.8 |
| RH_6 | 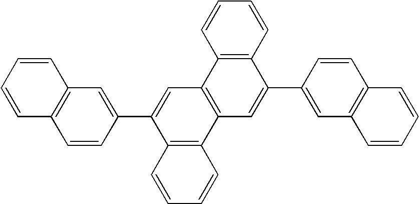 | 2.4 | 2.7 |
| RH_7 | 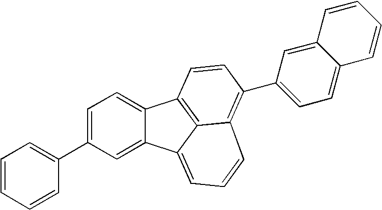 | 2.3 | 2.7 |
| RH_8 | 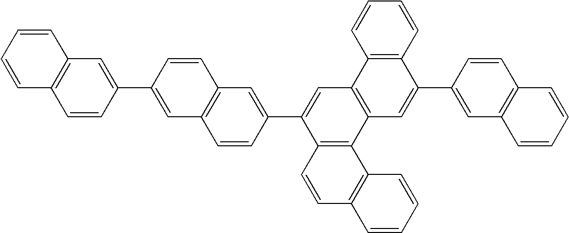 | 2.4 | 2.8 |
| RH_9 | 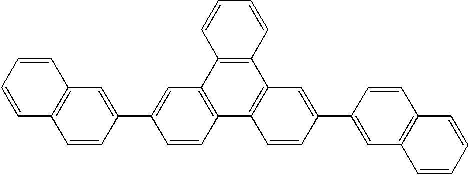 | 2.4 | 2.7 |
| GH_1 | 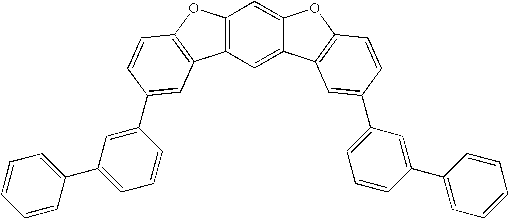 | 3.0 | 2.5 |
| GH_2 | 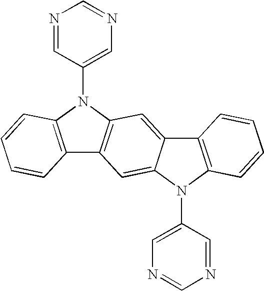 | 2.8 | 2.7 |
| GH_3 | 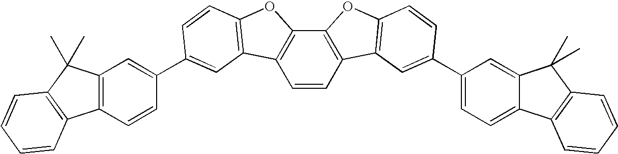 | 2.8 | 2.9 |
| GH_4 | 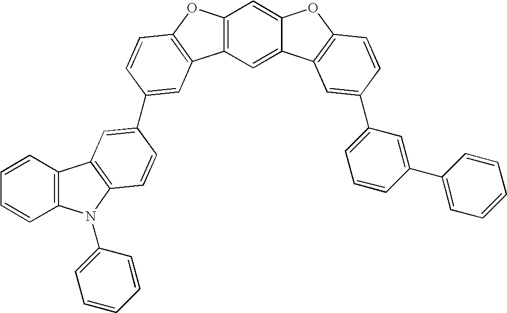 | 2.8 | 2.5 |
| GH_5 | 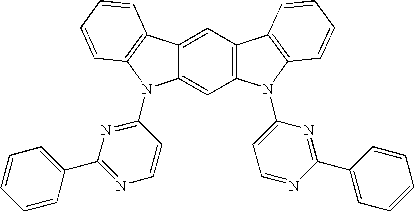 | 2.8 | 2.7 |
| GH_6 | 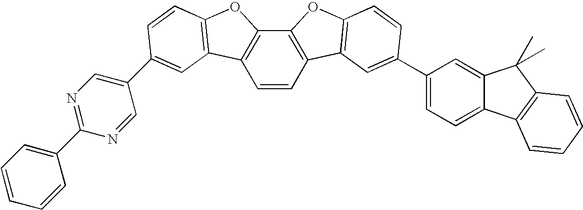 | 2.8 | 2.8 |
| GH_7 | 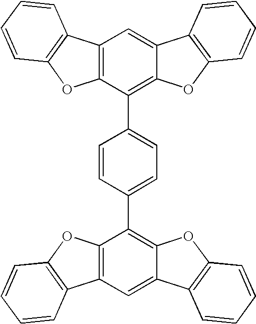 | 2.8 | 2.5 |
| GH_8 | 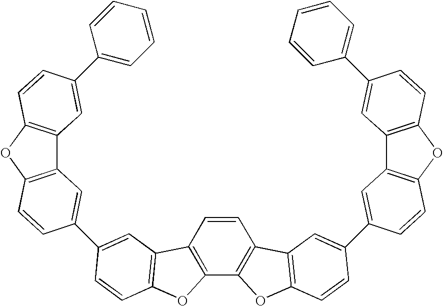 | 2.8 | 2.5 |
| GH_9 | 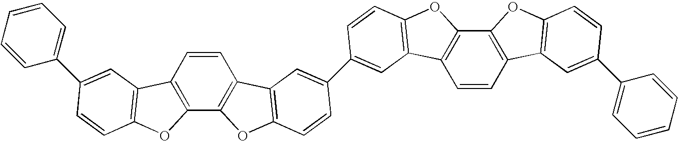 | 2.8 | 2.5 |
| GH_10 | 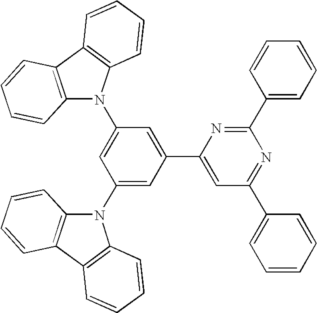 | 2.9 | 2.6 |
| ET_1 | 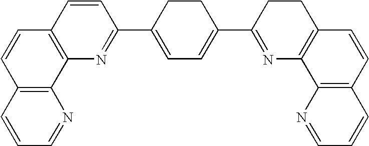 | 2.7 | 2.9 |
| ET_2 | 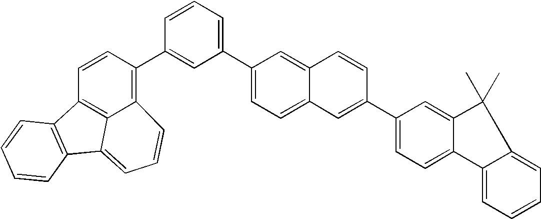 | 2.3 | 2.9 |
| ET_3 | 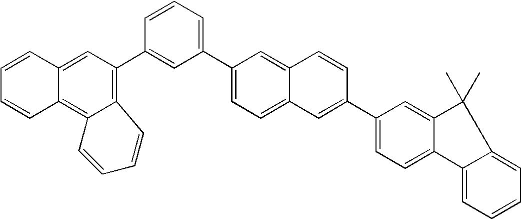 | 2.4 | 2.8 |
| ET_4 | 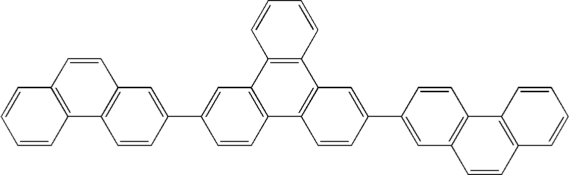 | 2.4 | 2.8 |
| ET_5 | 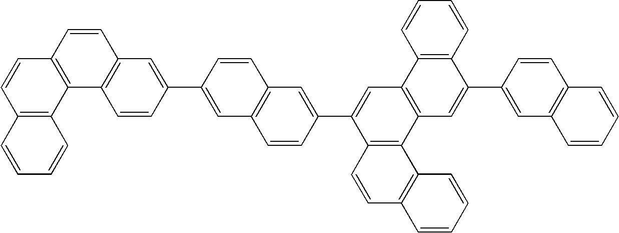 | 2.4 | 2.8 |
| BH_1 | 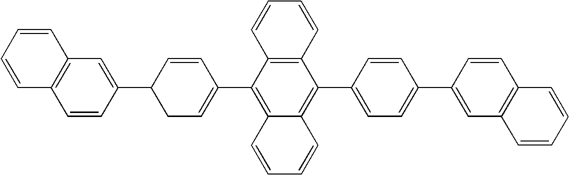 | 1.8 | 3.0 |
| BH_2 | 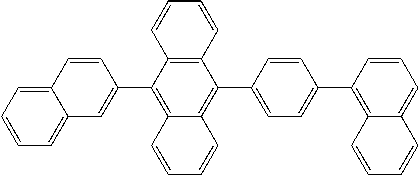 | 1.8 | 3.0 |
| BH_3 | 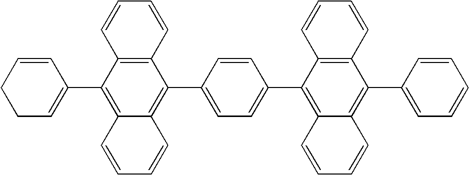 | 1.8 | 3.0 |
| BH_4 | 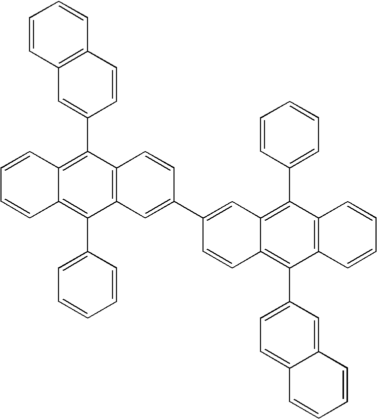 | 1.8 | 3.0 |
| BH_5 | 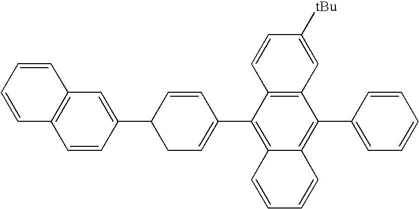 | 1.8 | 3.0 |
| BD_1 | 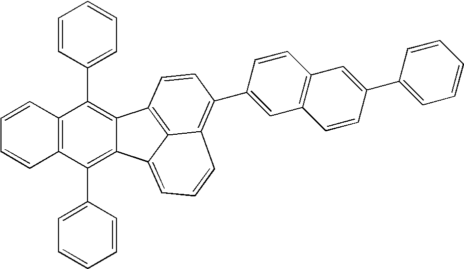 | 2.1 | 3.1 |
| BD_2 | 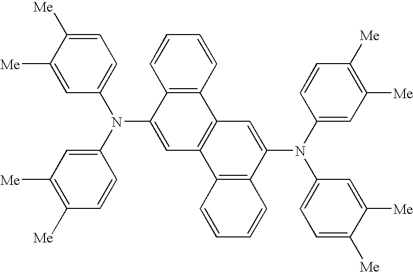 | 2.3 | 2.7 |
| BD_3 | 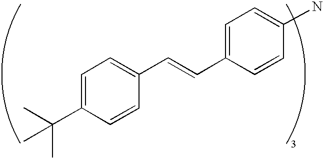 | 2.0 | 2.7 |

Measuring methods of the properties are shown below.

### (1) Triplet Energy (ET)

A commercially available device “F4500” (manufactured by Hitachi, Ltd.) was used for the measurement. The E^{T} conversion expression is the following.

E^{T}(eV)=1239.85/λ_{edge}

When the phosphorescence spectrum is expressed in coordinates of which the vertical axis indicates the phosphorescence intensity and of which the horizontal axis indicates the wavelength, and a tangent is drawn to the rise of the phosphorescence spectrum on the shorter wavelength side, “λ_{edge}” is the wavelength at the intersection of the tangent and the horizontal axis. The unit for “λ_{edge}” is nm.

### (2) Ionization Potential

A photoelectron spectroscopy in air (AC-1, manufactured by Riken Keiki Co., Ltd.) was used for the measurement. Specifically, light was irradiated to a material and the amount of electrons generated by charge separation was measured.

### (3) Affinity

An affinity was calculated by subtracting a measured value of an energy gap from that of an ionization potential. The Energy gap was measured based on an absorption edge of an absorption spectrum in benzene. Specifically, an absorption spectrum was measured with a commercially available ultraviolet-visible spectrophotometer. The energy gap was calculated from the wavelength at which the spectrum began to raise.

### Example 1

The following materials for forming layers were sequentially deposited on a substrate on which a 130 nm thick ITO film to obtain an organic EL device.

Anode: ITO (film thickness; 130 nm)

Hole-injecting layer: HI (film thickness; 50 nm)

Hole-transporting layer: HT (film thickness; 45 nm)

Emitting layer: (film thickness; blue 25 nm, green 50 nm, red 40 nm)
Blue emitting layer BH_{—}1: BD_{—}1 (5 wt %)
Green emitting layer GH_{—}1: Ir(Ph-ppy)3 (10 wt %)
Red emitting layer RH_{—}1: Ir(piq)3 (10 wt %)

Electron-transporting layer (ETL): ET1 (film thickness; 5 nm)

LiF: (film thickness 1 nm)

Cathode: Al (film thickness: 80 nm)

The blue emitting layer, green emitting layer and red emitting layer of the device obtained were caused to emit light by applying a DC of 1 mA/cm² and the luminous efficiency thereof was measured (unit: cd/A). A continuous current test of DC was conducted at the following initial luminance to measure the half life (unit: hour).

Blue: 5,000 cd/m², green: 20,000 cd/m², red: 10,000 cd/m²

The results are shown in Table 1.

### Examples 2 to 5, and Comparative Example 1

A device was obtained and evaluated in the same manner as in Example 1, except that the hosts and dopants of the blue emitting layer, red emitting layer and green emitting layer and the electron-transporting layer shown in Table 1 were used. The results are shown in Table 1.

As shown in Table 1, a second dopant was added to the green emitting layer in Example 5. The concentrations of the second dopant GH_{—}10 and the first dopant Ir(ppy)3 were 20 wt % and 10 wt %, respectively.

### Example 6

The following materials for forming layers were sequentially deposited on a substrate on which a 130 nm thick ITO film to obtain an organic EL device.

The organic EL device obtained was evaluated in the same manner as in Example 1. The results are shown in Table 1.

Anode: ITO (film thickness; 130 nm)

Hole-injecting layer: HI (film thickness; 50 nm)

Hole-transporting layer: HT (film thickness; 45 nm)

Emitting layer: (film thickness; blue 25 nm, green 50 nm, red 40 nm)
Blue emitting layer BH_{—}2: BD_{—}2 (5 wt %)
Green emitting layer GH_{—}1: Ir(Ph-ppy)3 (10 wt %)
Red emitting layer RH_{—}1: Ir(piq)3 (10 wt %)

Electron-transporting layer (ETL): ET2 (film thickness; 5 nm)

Electron-injecting layer (EIL): EI1 (film thickness; 20 nm)

LiF: (film thickness 1 nm)

Cathode: Al (film thickness: 80 nm)

### Examples 7 to 27, and Comparative Example 2

An organic EL device was obtained and evaluated in the same manner as in Example 6, except that the hosts and dopants of the blue emitting layer, red emitting layer and green emitting layer, the electron-transporting layer and the electron-injecting layer shown in Table 1 were used. The results are shown in Table 1.

As shown in Table 1, second dopants were added to the green emitting layers in Examples 10, 15, 16, 21, 22 and 27. The concentrations of the second dopant and the first dopant were 20 wt % and 10 wt %, respectively.

TABLE 1

| | Emitting | Emitting | Electron- | | |
|---|---|---|---|---|---|
| | layer | layer | transporting | Effi- | |
| | host | dopant | region | ciency | Life |
| Example 1 | BH_1 | BD_1 | ET1 | 7.92 | 1000 |
| | RH_1 | Ir(piq)3 | ET1 | 10.3 | 2000 |
| | GH_1 | Ir(Ph-ppy)3 | ET1 | 57.9 | 700 |
| Example 2 | BH_1 | BD_2 | ET1 | 8.5 | 800 |
| | RH_5 | Ir(piq)3 | ET1 | 10.9 | 1900 |
| | GH_5 | Ir(Ph-ppy)3 | ET1 | 50.3 | 400 |
| Example 3 | BH_1 | BD_1 | ET1 | 7.92 | 1000 |
| | RH_1 | Ir(piq)3 | ET1 | 10.3 | 2000 |
| | GH_1 | Ir(ppy)3 | ET1 | 48.4 | 300 |
| Example 4 | BH_1 | BD_2 | ET1 | 8.5 | 800 |
| | RH_5 | Ir(piq)3 | ET1 | 10.9 | 1900 |
| | GH_5 | Ir(ppy)3 | ET1 | 47.2 | 300 |
| Example 5 | BH_1 | BD_2 | ET1 | 8.5 | 800 |
| | RH_5 | Ir(piq)3 | ET1 | 10.9 | 1900 |
| | GH_5 | GH_10:Ir(ppy)3 | ET1 | 58.1 | 600 |
| Example 6 | BH_2 | BD_1 | ET2/EI1 | 11.04 | 2000 |
| | RH_1 | Ir(piq)3 | ET2/EI1 | 11.2 | 3000 |
| | GH_1 | Ir(ppy)3 | ET2/EI1 | 50.7 | 400 |
| Example 7 | BH_2 | BD_2 | ET2/EI1 | 11.8 | 1500 |
| | RH_6 | Ir(piq)3 | ET2/EI1 | 9.5 | 1200 |
| | GH_6 | Ir(ppy)3 | ET2/EI1 | 42.9 | 200 |
| Example 8 | BH_2 | BD_2 | ET2/EI1 | 11.8 | 1500 |
| | RH_6 | Ir(piq)3 | ET2/EI1 | 9.5 | 1200 |
| | GH_1 | Ir(Ph-ppy)3 | ET2/EI1 | 60.5 | 1000 |
| Example 9 | BH_2 | BD_2 | ET2/EI1 | 11.8 | 1500 |
| | RH_1 | Ir(piq)3 | ET2/EI1 | 11.2 | 3000 |
| | GH_6 | Ir(Ph-ppy)3 | ET2/EI1 | 50.2 | 400 |
| Example | BH_2 | BD_2 | ET2/EI1 | 11.8 | 1500 |
| 10 | RH_1 | Ir(piq)3 | ET2/EI1 | 11.2 | 3000 |
| | GH_6 | GH_10:Ir(ppy)3 | ET2/EI1 | 53.1 | 400 |
| Example | BH_3 | BD_1 | ET3/EI1 | 10.3 | 1500 |
| 11 | RH_2 | Ir(piq)3 | ET3/EI1 | 10.5 | 2200 |
| | GH_2 | Ir(ppy)3 | ET3/EI1 | 45.1 | 300 |
| Example | BH_3 | BD_2 | ET3/EI1 | 9.2 | 1200 |
| 12 | RH_7 | Ir(piq)3 | ET3/EI1 | 10.2 | 1800 |
| | GH_7 | Ir(ppy)3 | ET3/EI1 | 45.5 | 300 |
| Example | BH_3 | BD_1 | ET3/EI1 | 10.3 | 1500 |
| 13 | RH_2 | Ir(piq)3 | ET3/EI1 | 10.5 | 2200 |
| | GH_2 | Ir(Ph-ppy)3 | ET3/EI1 | 48.2 | 500 |
| Example | BH_3 | BD_2 | ET3/EI1 | 9.2 | 1200 |
| 14 | RH_7 | Ir(piq)3 | ET3/EI1 | 10.2 | 1800 |
| | GH_7 | Ir(Ph-ppy)3 | ET3/EI1 | 51.2 | 500 |
| Example | BH_3 | BD_1 | ET3/EI1 | 10.3 | 1500 |
| 15 | RH_2 | Ir(piq)3 | ET3/EI1 | 10.5 | 2200 |
| | GH_2 | GH_10:Ir(ppy)3 | ET3/EI1 | 44.1 | 400 |
| Example | BH_3 | BD_2 | ET3/EI1 | 9.2 | 1200 |
| 16 | RH_7 | Ir(piq)3 | ET3/EI1 | 10.2 | 1800 |
| | GH_6 | GH_1:Ir(ppy)3 | ET3/EI1 | 52.8 | 500 |
| Example | BH_4 | BD_1 | ET4/EI1 | 10.8 | 1000 |
| 17 | RH_3 | Ir(piq)3 | ET4/EI1 | 9.8 | 3000 |
| | GH_3 | Ir(ppy)3 | ET4/EI1 | 42.1 | 200 |
| Example | BH_4 | BD_3 | ET4/EI1 | 9.1 | 1000 |
| 18 | RH_8 | Ir(piq)3 | ET4/EI1 | 10.5 | 1900 |
| | GH_8 | Ir(ppy)3 | ET4/EI1 | 42.3 | 500 |
| Example | BH_4 | BD_1 | ET4/EI1 | 10.8 | 1000 |
| 19 | RH_3 | Ir(piq)3 | ET4/EI1 | 9.8 | 3000 |
| | GH_3 | Ir(Ph-ppy)3 | ET4/EI1 | 50.1 | 500 |
| Example | BH_4 | BD_3 | ET4/EI1 | 9.1 | 1000 |
| 20 | RH_8 | Ir(piq)3 | ET4/EI1 | 10.5 | 1900 |
| | GH_8 | Ir(Ph-ppy)3 | ET4/EI1 | 48.8 | 600 |
| Example | BH_4 | BD_3 | ET4/EI1 | 9.1 | 1000 |
| 21 | RH_8 | Ir(piq)3 | ET4/EI1 | 10.5 | 1900 |
| | GH_3 | GH_10:Ir(ppy)3 | ET4/EI1 | 63.1 | 800 |
| Example | BH_4 | BD_1 | ET4/EI1 | 10.8 | 1000 |
| 22 | RH_3 | Ir(piq)3 | ET4/EI1 | 9.8 | 3000 |
| | GH_6 | GH_4:Ir(ppy)3 | ET4/EI1 | 53.9 | 500 |
| Example | BH_5 | BD_1 | ET5/EI1 | 10.2 | 1200 |
| 23 | RH_4 | Ir(piq)3 | ET5/EI1 | 104 | 2800 |
| | GH_4 | Ir(ppy)3 | ET5/EI1 | 46.4 | 200 |
| Example | BH_5 | BD_3 | ET5/EI1 | 9.4 | 1100 |
| 24 | RH_9 | Ir(piq)3 | ET5/EI1 | 10.1 | 2200 |
| | GH_9 | Ir(ppy)3 | ET5/EI1 | 48.1 | 300 |
| Example | BH_5 | BD_1 | ET5/EI1 | 10.2 | 1200 |
| 25 | RH_4 | Ir(piq)3 | ET5/EI1 | 10.4 | 2800 |
| | GH_4 | Ir(Ph-ppy)3 | ET5/EI1 | 49.8 | 400 |
| Example | BH_5 | BD_3 | ET5/EI1 | 9.4 | 1100 |
| 26 | RH_9 | Ir(piq)3 | ET5/EI1 | 10.1 | 2200 |
| | GH_9 | Ir(Ph-ppy)3 | ET5/EI1 | 49.7 | 400 |
| Example | BH_5 | BD_1 | ET5/EI1 | 10.2 | 1200 |
| 27 | RH_4 | Ir(piq)3 | ET5/EI1 | 10.4 | 2800 |
| | GH_6 | PGH_8:Ir(ppy)3 | ET5/EI1 | 58.8 | 400 |
| Com. | BH_1 | BD_1 | Alq3 | 4.6 | 600 |
| Ex. 1 | CBP | Ir(piq)3 | Alq3 | 4.2 | 300 |
| | CBP | Ir(ppy)3 | Alq3 | 15.1 | 3 |
| Com. | BH_1 | BD_1 | BAlq/Alq3 | 4.3 | 500 |
| Ex. 2 | CBP | Ir(piq)3 | BAlq/Alq3 | 8.5 | 1000 |
| | CBP | Ir(ppy)3 | BAlq/Alq3 | 40.3 | 50 |

### INDUSTRIAL APPLICABILITY

The organic EL device of the invention can be used in display panels for large-sized TVs, illumination panels or the like.

The documents described in the specification are incorporated herein by reference in its entirety.

What is claimed is:

1. An organic electroluminescence device comprising opposite anode and cathode, and a hole-transporting region, an emitting layer and an electron-transporting region in sequential order from the anode between the anode and the cathode,
wherein the emitting layer is formed of a red emitting layer, a green emitting layer, and blue emitting layer;
the blue emitting layer contains a host BH and a fluorescent dopant FBD;
the triplet energy E^{T}_{fbd} of the fluorescent dopant FBD is larger than the triplet energy E^{T}_{bh} of the host BH;
the green emitting layer contains a host GH and a phosphorescent dopant PGD;
a common electron-transporting layer is provided adjacent to the red emitting layer, the green emitting layer and the blue emitting layer within the electron-transporting region;
the triplet energy E^{T}ₑₗ of a material constituting the electron-transporting layer is larger than E^{T}_{bh}; and
the difference between the affinity of the host GH and the affinity of the material constituting the electron-transporting layer is 0.4 eV or less.

2. The organic electroluminescence device according to claim 1, wherein the red emitting layer contains a host RH and a phosphorescent dopant PRD; and
the difference between the affinity of the host RH and the affinity of the material constituting the electron-transporting layer is 0.4 eV or less.

3. The organic electroluminescence device according to claim 1, wherein the difference between the affinity of the host BH and the affinity of the material constituting the electron-transporting layer is 0.4 eV or less.

4. The organic electroluminescence device according to claim 1, wherein the electron mobility of the material constituting the electron-transporting layer is 10⁻⁶ cm²/Vs or more in an electric field intensity of 0.04 to 0.5 MV/cm.

5. The organic electroluminescence device according to claim 1, wherein an electron-injecting layer is provided between the electron-transporting layer and the cathode within the electron-transporting region.

6. The organic electroluminescence device according to claim 1, wherein the affinity Af_{gh} of the host GH is 2.6 eV or more.

7. The organic electroluminescence device according to claim 1, wherein the ionization potential Ip_{gd} of the dopant GD is 5.2 eV or more.

8. The organic electroluminescence device according to claim 1, wherein at least one of the blue emitting layer, the green emitting layer and the red emitting layer contains a second dopant.

9. The organic electroluminescence device according to claim 8, wherein the green emitting layer contains a second dopant GD2.

10. The organic electroluminescence device according to claim 9, wherein the different between the affinity Af_{gd2} of the second dopant GD2 and the affinity Af_{gh} of the host GH is 0.4 eV or less.

11. The organic electroluminescence device according to claim 1, wherein the electron-transporting region is consists of the electron-transporting layer, and the electron-transporting layer is doped with a donor.
